(19) United States
(12) Patent Application Publication
(10) Pub. No.: US 2024/0395940 A1
(43) Pub. Date: Nov. 28, 2024

(54) SEMICONDUCTOR DEVICE, MEMORY DEVICE, AND METHOD FOR MANUFACTURING SEMICONDUCTOR DEVICE

(71) Applicant: Semiconductor Energy Laboratory Co., Ltd., Atsugi-shi (JP)

(72) Inventors: Shunpei YAMAZAKI, Setagaya (JP); Fumito ISAKA, Zama (JP); Yuichi SATO, Isehara (JP); Toshikazu OHNO, Atsugi (JP); Hitoshi KUNITAKE, Machida (JP); Tsutomu MURAKAWA, Isehara (JP)

(21) Appl. No.: 18/664,493

(22) Filed: May 15, 2024

(30) Foreign Application Priority Data
May 25, 2023 (JP) 2023-086420
Jan. 17, 2024 (JP) 2024-005509
Mar. 1, 2024 (JP) 2024-030892

(51) Int. Cl. H01L 29/786; H01L 29/66; H10B 12/00

(52) U.S. Cl. CPC H01L 29/7869; H01L 29/6675; H10B 12/05; H10B 12/33

(57) ABSTRACT

A transistor with high electrical characteristics is provided. A transistor with a high on-state current is provided. A transistor with small parasitic capacitance is provided. A transistor, a semiconductor device, or a memory device which can be miniaturized or highly integrated is provided. The transistor includes a first conductive layer, a second conductive layer, a semiconductor layer, a gate insulating layer over the semiconductor layer, and a gate electrode over the gate insulating layer. A first insulating layer is between the first conductive layer and the second conductive layer. The second conductive layer is over the first insulating layer. The first insulating layer and the second conductive layer include an opening portion reaching the first conductive layer. The semiconductor layer is in contact with a sidewall of the opening portion. The semiconductor layer includes a first oxide layer and a second oxide layer. The first oxide layer includes a first region and a second region. The second oxide layer is between the first region and the second region.

### BACKGROUND OF THE INVENTION

### 1. Field of the Invention

One embodiment of the present invention relates to a semiconductor device, a memory device, a display device, and an electronic device. One embodiment of the present invention also relates to a method for manufacturing the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, semiconductor devices have been developed to be used mainly for an LSI, a CPU, a memory, and the like. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a material of a semiconductor thin film that can be used in a transistor. As another material, an oxide semiconductor has been attracting attention.

A transistor using an oxide semiconductor is known to have an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

### REFERENCES

### Patent Documents

[Patent Document 1] Japanese Published Patent Application No. 2012-257187
   [Patent Document 2] Japanese Published Patent Application No. 2011-151383
   [Patent Document 3] PCT International Publication No. 2021/053473
   [Patent Document 4] Japanese Published Patent Application No. 2013-211537

### Non-Patent Document

[Non-Patent Document 1] M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

An object of one embodiment of the present invention is to provide a transistor with high electrical characteristics. Another object of one embodiment of the present invention is to provide a transistor with a high on-state current. Another object of one embodiment of the present invention is to provide a transistor with small parasitic capacitance. Another object of one embodiment of the present invention is to provide a transistor, a semiconductor device, or a memory device which can be miniaturized or highly integrated. Another object of one embodiment of the present invention is to provide a display device with a high resolution or a high aperture ratio. Another object of one embodiment of the present invention is to provide a highly reliable transistor, semiconductor device, display device, or memory device. Another object of one embodiment of the present invention is to provide a semiconductor device, display device, or memory device with low power consumption. Another object of one embodiment of the present invention is to provide a memory device with high operating speed. Another object of one embodiment of the present invention is to provide a method for manufacturing the above-described transistor, semiconductor device, display device, or memory device.

Note that the description of these objects does not preclude the existence of other objects. One embodiment of the present invention does not necessarily achieve all of these objects. Other objects can be derived from the description of the specification, the drawings, and the claims.

One embodiment of the present invention is a semiconductor device including a transistor over a first insulating layer and a second insulating layer; the transistor includes, over the first insulating layer, a first conductive layer, a second conductive layer, a semiconductor layer, a gate insulating layer, and a gate electrode; the second insulating layer is between the first conductive layer and the second conductive layer; the second conductive layer is over the second insulating layer; the second insulating layer and the second conductive layer include an opening portion reaching the first conductive layer; the semiconductor layer is in contact with a side surface of the second insulating layer in the opening portion and a side surface of the second conductive layer in the opening portion; the gate insulating layer is over the semiconductor layer; the gate electrode includes a region overlapping with the semiconductor layer with the gate insulating layer therebetween in the opening portion; the semiconductor layer includes a first oxide layer and a second oxide layer; the first oxide layer includes a first region and a second region; the first region and the second region each include a plurality of crystal parts; and the second oxide layer is between the first region and the second region.

In the above-described structure, the plurality of crystal parts preferably has c-axis alignment.

In the above-described structure, the second oxide layer preferably includes a crystal part having the same crystal structure as the plurality of crystal parts.

In the above-described structure, the second oxide layer preferably includes a crystal part connected with one of the plurality of crystal parts.

In the above-described structure, it is preferable that a boundary not be observed between the first oxide layer and the second oxide layer in a cross-sectional TEM image.

In the above-described structure, the first conductive layer preferably includes a depressed portion overlapping with the opening portion, and the semiconductor layer preferably includes a region embedded in the depressed portion.

In the above-described structure, it is preferable that the opening portion include an eighth region having a sidewall with a tapered shape and a ninth region having a steeper sidewall than the eighth region, that the eighth region include an upper edge of the opening portion, that the ninth region be below the eighth region, that the eighth region include the side surface of the second conductive layer, and that the ninth region include the side surface of the second insulating layer.

In the above-described structure, an angle formed between the sidewall of the eighth region and a top surface of the first insulating layer is preferably greater than or equal to 20 degrees and less than or equal to 75 degrees, and an angle formed between the sidewall of the ninth region and the top surface of the first insulating layer is preferably greater than 75 degrees and less than or equal to 90 degrees.

One embodiment of the present invention is a method for manufacturing a semiconductor device, including the steps of: forming a first insulating layer over a first conductive layer; forming a second conductive layer over the first insulating layer; removing part of the second conductive layer and part of the first insulating layer to form a first opening portion reaching the first conductive layer and expose a top surface of the first conductive layer; and forming a semiconductor layer in contact with each of the top surface of the first conductive layer, a side surface of the first insulating layer in the first opening portion, a side surface of the second conductive layer in the first opening portion, and a top surface of the second conductive layer. The semiconductor layer is formed through a first step of forming a first oxide layer, a second step of forming a second oxide layer, and a third step of performing heat treatment, the first oxide layer is formed by a sputtering method, the second oxide layer is formed by an atomic layer deposition method, a second insulating layer is formed so as to be in contact with a top surface of the semiconductor layer and a top surface of the first insulating layer, and a third conductive layer is formed over the second insulating layer.

One embodiment of the present invention is a memory device including a first insulating layer, a capacitor, and a transistor over the capacitor. The transistor includes a first conductive layer, a second conductive layer, a semiconductor layer, a gate insulating layer, and a gate electrode. The capacitor includes a third conductive layer, a second insulating layer over the third conductive layer, and the first conductive layer over the second insulating layer. The first insulating layer is between the first conductive layer and the second conductive layer. The second conductive layer is over the first insulating layer. The first insulating layer and the second conductive layer include an opening portion reaching the first conductive layer. The semiconductor layer is in contact with a side surface of the first insulating layer in the opening portion and a side surface of the second conductive layer in the opening portion. The gate insulating layer is over the semiconductor layer. The gate electrode includes a region overlapping with the semiconductor layer with the gate insulating layer therebetween in the opening portion. The semiconductor layer includes a metal oxide. I_{d}-V_{gs} characteristics of the transistor are measured at a drain-source voltage higher than or equal to 0.05 V and lower than or equal to 1 V, where I_{d} is a drain current and V_{gs} is a gate-source voltage. In the I_{d}-V_{gs} characteristics, V_{gs} is higher than 0 V and lower than 0.5 V when I_{d} is 1×10⁻¹² [A].

In the above-described embodiment, the metal oxide is preferably an In-M-Zn oxide, and the element M is preferably one or more elements selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

In the above-described embodiment, a retention time of the memory device is preferably longer than or equal to 0.64 seconds.

In the above-described embodiment, when the gate of the transistor is set at 0 V, the source of the transistor is set at 0 V, and a voltage higher than or equal to 0.05 V and lower than or equal to 1 V is applied to the drain of the transistor, an amount of accumulated charges flowing through the transistor for 0.64 seconds is preferably less than or equal to 3×10⁻¹⁵ [F]×0.1 [V].

In the above-described embodiment, the memory device preferably has a write time shorter than or equal to 15 ns.

In the above-described embodiment, the memory device preferably has a read time shorter than or equal to 15 ns.

In the above-described embodiment, it is preferable that a circuit including a first load connected to the gate of the transistor and a second load connected to the drain of the transistor be used to calculate the write time, that the first load include 256 first circuits, that each of the plurality of first circuits include a first resistor and a second capacitor, that the second load include 32 second circuits, that each of the plurality of second circuits include a second resistor and a third capacitor, that a plurality of the first resistors included in the first circuits be serially connected, that a plurality of the second resistors included in the second circuit be serially connected, that a resistance value of the first resistor be greater than or equal to 1Ω and less than or equal to 100Ω, that a resistance value of the second resistor be greater than or equal to 1Ω and less than or equal to 100Ω, that a capacitance value of the second capacitor be greater than or equal to 1 aF and less than or equal to 0.5 fF, and that a capacitance value of the third capacitor be greater than or equal to 1 aF and less than or equal to 0.5 fF.

In the above-described embodiment, it is preferable that a circuit including a first load connected to the gate of the transistor and a second load connected to the drain of the transistor be used to calculate the read time, that the first load include 256 first circuits, that each of the plurality of first circuits include a first resistor and a second capacitor, that the second load include 32 second circuits, that each of the plurality of second circuits include a second resistor and a third capacitor, that a plurality of the first resistors included in the first circuits be serially connected, that a plurality of the second resistors included in the second circuit be serially connected, that a resistance value of the first resistor be greater than or equal to 1Ω and less than or equal to 100Ω, that a resistance value of the second resistor be greater than or equal to 1Ω and less than or equal to 100Ω, that a capacitance value of the second capacitor be greater than or equal to 1 aF and less than or equal to 0.5 fF, and that a capacitance value of the third capacitor be greater than or equal to 1 aF and less than or equal to 0.5 fF.

With one embodiment of the present invention, a transistor with high electrical characteristics can be provided. With one embodiment of the present invention, a transistor with a high on-state current can be provided. With one embodiment of the present invention, a transistor with small parasitic capacitance can be provided. With one embodiment of the present invention, a transistor, a semiconductor device, or a memory device which can be miniaturized or highly integrated can be provided. With one embodiment of the present invention, a display device with a high resolution or a high aperture ratio can be provided. With one embodiment of the present invention, a highly reliable transistor, semiconductor device, display device, or memory device can be provided. With one embodiment of the present invention, a semiconductor device, display device, or memory device with low power consumption can be provided. With one embodiment of the present invention, a memory device with high operating speed can be provided. With one embodiment of the present invention, a method for manufacturing the above-described transistor, semiconductor device, display device, or memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a plan view illustrating an example of a semiconductor device and FIGS. 1B and 1C are cross-sectional views illustrating the example of the semiconductor device;

FIG. 2A is a plan view illustrating an example of a semiconductor device and FIGS. 2B and 2C are cross-sectional views illustrating the example of the semiconductor device;

FIG. 3A is a plan view illustrating an example of a semiconductor device and FIGS. 3B to 3D are cross-sectional views illustrating examples of the semiconductor device;

FIG. 4A is a plan view illustrating an example of a semiconductor device and FIGS. 4B and 4C are cross-sectional views illustrating the example of the semiconductor device;

FIGS. 5A to 5C are cross-sectional views illustrating examples of a semiconductor device;

FIGS. 6A to 6D are cross-sectional views illustrating examples of a semiconductor device;

FIGS. 7A and 7B are cross-sectional views illustrating an example of a semiconductor device;

FIGS. 8A and 8B are cross-sectional views illustrating an example of a semiconductor device;

FIGS. 9A and 9B are cross-sectional views illustrating an example of a semiconductor device;

FIGS. 10A and 10B are cross-sectional views each illustrating an example of a semiconductor device;

FIGS. 11A to 11D illustrate cross sections of oxide semiconductors;

FIGS. 12A to 12C are cross-sectional views illustrating an example of a method for manufacturing a semiconductor device;

FIG. 13A is a plan view illustrating an example of a memory device and FIGS. 13B and 13C are cross-sectional views illustrating the example of the memory device;

FIG. 14A is a plan view illustrating an example of a memory device and FIGS. 14B and 14C are cross-sectional views illustrating the example of the memory device;

FIG. 15A is a plan view illustrating an example of a memory device and FIG. 15B is a cross-sectional view illustrating the example of the memory device;

FIG. 16 is a cross-sectional view illustrating an example of a memory device;

FIG. 17 is a cross-sectional view illustrating an example of a memory device;

FIG. 18 is a block diagram illustrating a structure example of a semiconductor device;

FIGS. 19A to 19H illustrate circuit structure examples of memory cells;

FIGS. 20A and 20B are perspective views illustrating structure examples of a semiconductor device;

FIG. 21 is a block diagram illustrating a CPU;

FIGS. 22A and 22B are perspective views of a semiconductor device;

FIGS. 23A and 23B are each a perspective view of a semiconductor device;

FIGS. 24A and 24B each illustrate a hierarchy of various kinds of memory devices;

FIGS. 25A and 25B are perspective views illustrating an example of a display device;

FIG. 26 is a cross-sectional view illustrating an example of a display device;

FIG. 27 is a cross-sectional view illustrating an example of a display device;

FIGS. 28A to 28C illustrate structure examples of a display device;

FIGS. 29A and 29B illustrate examples of an electronic component;

FIGS. 30A to 30C illustrate an example of a large computer, FIG. 30D illustrates an example of space equipment, and FIG. 30E illustrates an example of a storage system that can be used for a data center;

FIGS. 31A to 31F illustrate examples of electronic devices;

FIGS. 32A to 32G illustrate examples of electronic devices;

FIGS. 33A to 33F illustrate examples of electronic devices;

FIGS. 34A and 34B show I_{d}-V_{g} characteristics;

FIGS. 35A and 35B show I_{d}-V_{d} characteristics;

FIG. 36 is a circuit diagram which is used for circuit simulation;

FIGS. 37A and 37B are timing charts showing the operation of a circuit;

FIGS. 38A to 38C are cross-sectional TEM images in Example 3;

FIGS. 39A to 39C show crystal orientations in Example 3;

FIG. 40 shows I_{d}-V_{gs} characteristics;

FIGS. 41A to 41C are timing charts showing the operation of a circuit;

FIGS. 42A and 42B show results of circuit simulation;

FIG. 43 is a cross-sectional TEM image in Example 5;

FIG. 44 is a cross-sectional TEM image in Example 5;

FIG. 45 is a circuit diagram in Example 6; and

FIG. 46 shows results of measuring the current of a transistor.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, a switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. In this specification and the like, a transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen in a film can be analyzed by secondary ion mass spectrometry (SIMS) or X-ray photoelectron spectroscopy (XPS), for example. Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 60° and less than or equal to 120°.

In this specification and the like, the term “electrically connected” includes the case where components are connected to each other through an object having any electric function. There is no particular limitation on an “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vₜₕ, and the off state of a p-channel transistor means that V_{gs} is higher than Vₜₕ.

Note that “normally-on characteristics” in this specification and the like mean a state where a channel exists and a current flows through a transistor even when no voltage is applied to a gate. Furthermore, “normally-off characteristics” means a state where a current does not flow through a transistor when no potential or a ground potential is applied to a gate.

Note that in this specification and the like, a top surface shape of a component means the outline of the component in a plan view. A plan view means a view to observe the component from a normal direction of a surface where the component is formed or from a normal direction of a surface of a support (e.g., a substrate) where the component is formed.

In this specification and the like, the expression “having substantially the same top surface shapes” means that the outlines of stacked layers at least partly overlap with each other. For example, the case of patterning or partly patterning an upper layer and a lower layer with the use of the same mask pattern is included. The expression “having substantially the same top surface shapes” also sometimes includes the case where the outlines do not completely overlap with each other; for instance, the edge of the upper layer may be positioned on the inner side or the outer side of the edge of the lower layer. In the case where the top surface shapes are the same or substantially the same, it can be said that the end portions are aligned or substantially aligned with each other or the side end portions are aligned or substantially aligned with each other.

In this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers of light-emitting elements (also referred to as light-emitting devices) having different emission wavelengths are separately formed may be referred to as a side-by-side (SBS) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, the term “island shape” refers to a state where two or more layers formed using the same material in the same step are physically separated from each other. For example, “island-shaped EL layer” means a state where the EL layer and its adjacent EL layer are physically separated from each other.

In this specification and the like, step disconnection refers to a phenomenon in which a layer, a film, or an electrode is split because of the shape of its formation surface (e.g., a step).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention is described.

The semiconductor device of one embodiment of the present invention includes a first conductive layer, a second conductive layer, a third conductive layer, an oxide semiconductor layer, a first insulating layer, and a second insulating layer.

The first insulating layer is positioned over the first conductive layer, and the second conductive layer is positioned over the first insulating layer. The first insulating layer and the second conductive layer include an opening portion reaching the first conductive layer. The oxide semiconductor layer is in contact with at least a top surface of the first conductive layer, a side surface of the first insulating layer, and a side surface of the second conductive layer in the opening portion. The second insulating layer is positioned over the oxide semiconductor layer in the opening portion. The third conductive layer overlaps with the oxide semiconductor layer with the second insulating layer positioned therebetween in the opening portion. Note that the opening portion is also referred to as an opening.

The first conductive layer functions as one of a source electrode and a drain electrode of a transistor. The second conductive layer functions as the other of the source electrode and the drain electrode of the transistor. The third conductive layer functions as a gate electrode of the transistor, and the second insulating layer functions as a gate insulating layer.

Note that in this specification and the like, a simple expression “in a cross-sectional view” is replaced with a specific expression “in a cross-sectional view from the same direction” in some cases. For example, in the case where the relation between a plurality of components is described, a relation in a cross-sectional view from the same direction is described. In this case, the relation between the plurality of components can be described using one cross-sectional view.

In the transistor of one embodiment of the present invention, the source electrode and the drain electrode are positioned at different heights, so that a current flows in the semiconductor layer in the height direction. In other words, the channel length direction includes a height (vertical) component, so that the transistor of one embodiment of the present invention can also be referred to as a vertical field effect transistor (VFET), a vertical transistor, a vertical-channel transistor, or the like.

In the transistor of one embodiment of the present invention, the source electrode, the semiconductor layer, and the drain electrode can be provided to overlap with each other. Thus, the area occupied by the transistor can be significantly smaller than the area occupied by what is called a planar transistor in which a planar semiconductor layer is provided.

In this specification and the like, the expression “an end portion is aligned with another end portion” means that at least outlines of stacked layers partly overlap with each other in a plan view. For example, the case of processing or partly processing an upper layer and a lower layer with the use of the same mask pattern is included. The expression “an end portion is aligned with another end portion” also includes the case where the outlines do not completely overlap with each other; for instance, the outline of the upper layer may be positioned inside or outside the outline of the lower layer.

In general, it is sometimes difficult to clearly differentiate “completely aligned” from “substantially aligned”. Thus, in this specification and the like, the expression “aligned” includes both “completely aligned” and “substantially aligned”, in some cases.

### Structure Example 1 of Semiconductor Device

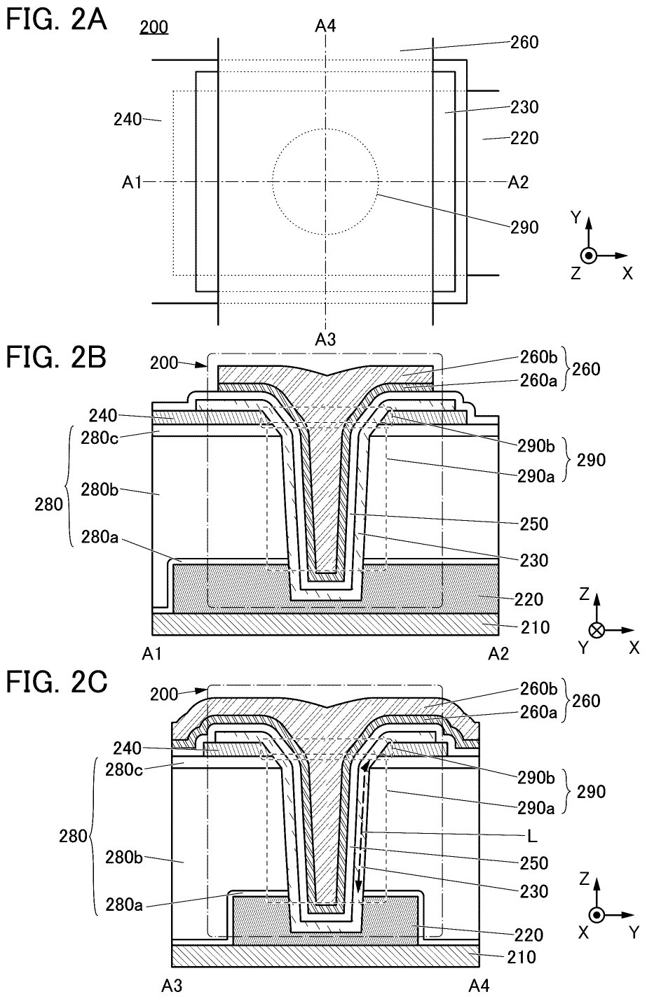

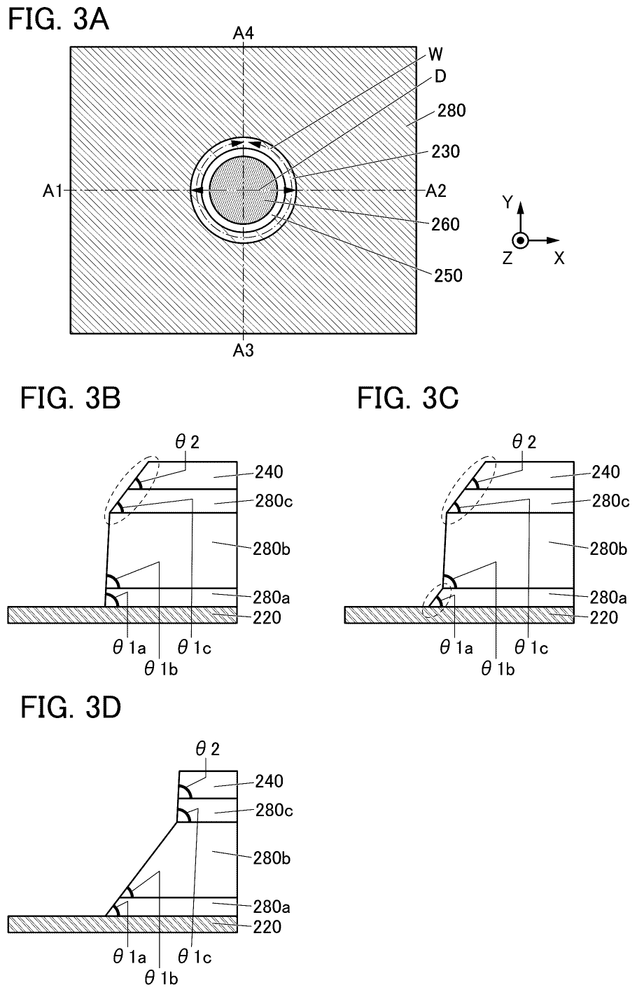

Structures of the semiconductor device of one embodiment of the present invention are described with reference to FIGS. 2A to 2C, FIGS. 3A to 3D, FIGS. 4A to 4C, FIGS. 5A to 5C, and FIGS. 6A to 6D. FIG. 2A is a plan view of the semiconductor device including a transistor 200. FIG. 2B is a cross-sectional view taken along a dashed-dotted line A1-A2 in FIG. 2A. FIG. 2C is a cross-sectional view taken along a dashed-dotted line A3-A4 in FIG. 2A. FIG. 3A is a cross-sectional view along the XY plane including an insulating layer 280. Note that for simplification, some components are not illustrated in the plan view of FIG. 2A. Some components may be omitted also in the following plan views.

The semiconductor device illustrated in FIGS. 2A to 2C and FIG. 3A includes an insulating layer 210 over a substrate (not illustrated), the transistor 200 over the insulating layer 210, and the insulating layer 280 over the insulating layer 210. The insulating layer 210 and the insulating layer 280 function as interlayer films.

The transistor 200 includes a conductive layer 220, a conductive layer 240 over the insulating layer 280, an oxide semiconductor layer 230, an insulating layer 250 over the oxide semiconductor layer 230, and a conductive layer 260 over the insulating layer 250. The conductive layer 220 and the conductive layer 240 are positioned at different heights.

In the transistor 200, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode.

A region of the oxide semiconductor layer 230 that is in contact with the conductive layer 220 and the conductive layer 240 preferably functions as a low-resistance region.

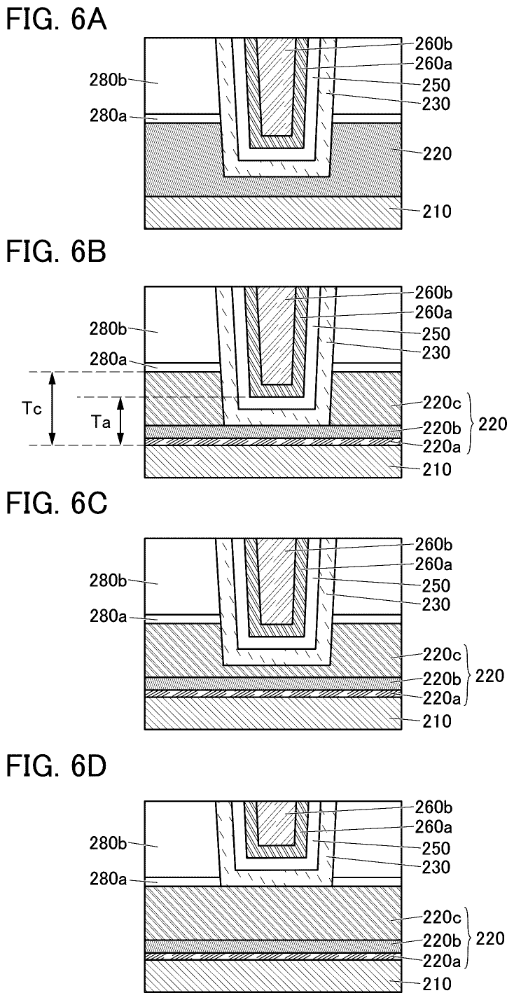

As illustrated in FIGS. 2B and 2C, an opening portion 290 reaching the conductive layer 220 is provided in the insulating layer 280 and the conductive layer 240. Here, in the structure illustrated in FIG. 6D described later, the bottom of the opening portion 290 is, for example, the top surface of the conductive layer 220. In the case where a depressed portion overlapping with the opening portion 290 is provided in the conductive layer 220 as illustrated in FIGS. 2B and 2C, the opening portion 290 and the depressed portion of the conductive layer 220 form a continuous opening portion in some cases. In such a case, for example, the top surface of the conductive layer 220 in a region overlapping with the opening portion 290 is the bottom of the continuous opening portion. A sidewall of the opening portion 290 is a side surface of the insulating layer 280 and a side surface of the conductive layer 240. The opening portion 290 includes an opening portion of the insulating layer 280 and an opening portion of the conductive layer 240. In other words, the opening portion of the insulating layer 280 in a region overlapping with the conductive layer 220 is part of the opening portion 290, and the opening portion of the conductive layer 240 in a region overlapping with the conductive layer 220 is another part of the opening portion 290. Note that the part of the opening portion 290 provided in the insulating layer 280 is referred to as an opening portion 290a, and the part of the opening portion 290 provided in the conductive layer 240 is referred to as an opening portion 290b.

At least part of the components of the transistor 200 is provided inside the opening portion 290. Specifically, at least part of each of the oxide semiconductor layer 230, the insulating layer 250, and the conductive layer 260 is positioned inside the opening portion 290. The oxide semiconductor layer 230 is in contact with the top surface of the conductive layer 220, the side surface of the insulating layer 280, and the side surface of the conductive layer 240 in the opening portion 290.

The insulating layer 280 includes an insulating layer 280a, an insulating layer 280b over the insulating layer 280a, and an insulating layer 280c over the insulating layer 280b. The insulating layer 280a includes a region in contact with the top surface of the insulating layer 210, a region in contact with a side surface of the conductive layer 220, and a region in contact with the top surface of the conductive layer 220. The insulating layer 280c includes a region in contact with the bottom surface of the conductive layer 240.

The oxide semiconductor layer 230 is provided inside the opening portion 290 of the insulating layer 280. The transistor 200 has a structure in which a current flows in the vertical direction since one of a source electrode and a drain electrode (here, the conductive layer 220) is positioned below and the other of the source electrode and the drain electrode (here, the conductive layer 240) is positioned above. That is, a channel is formed along the sidewall of the opening portion 290a.

The oxide semiconductor layer 230 is in contact with the top surface of the conductive layer 220 and the side surface of the conductive layer 240 inside the opening portion 290. The oxide semiconductor layer 230 is also in contact with part of the top surface of the conductive layer 240. When the oxide semiconductor layer 230 is in contact with not only the side surface of the conductive layer 240 but also the top surface of the conductive layer 240 in this manner, the area where the oxide semiconductor layer 230 and the conductive layer 240 are in contact with each other can be increased as compared with the case where the oxide semiconductor layer 230 is not in contact with the top surface of the conductive layer 240 but in contact with the side surface of the conductive layer 240, for example. Thus, the contact resistance between the oxide semiconductor layer 230 and the conductive layer 240 can be reduced.

The conductive layer 240 includes the opening portion 290b in a region overlapping with the conductive layer 220. Furthermore, it is preferable that the conductive layer 240 not be provided inside the opening portion 290a of the insulating layer 280. That is, it is preferable that the conductive layer 240 not include a region in contact with the side surface of the insulating layer 280 in the opening portion 290a. With such a structure, the opening portion 290b of the conductive layer 240 and the opening portion 290a of the insulating layer 280 can be collectively formed. When the side surface of the conductive layer 240 in the opening portion 290b is aligned or substantially aligned with the side surface of the insulating layer 280 in the opening portion 290a, the thickness distribution of the oxide semiconductor layer 230 provided inside the opening portion 290 can be uniform. In addition, the oxide semiconductor layer 230 can be inhibited from being divided by a step between the conductive layer 240 and the insulating layer 280.

The conductive layer 260 preferably has a stacked-layer structure of a conductive layer 260a and a conductive layer 260b over the conductive layer 260a. Note that the conductive layer 260a and the conductive layer 260b may each further have a stacked-layer structure.

The width of the opening portion 290 is referred to as a width D. The width D varies in the depth direction, in some cases. For example, the width D can be the width of an upper end of the opening portion 290a of the insulating layer 280. Alternatively, the width D can be the width of a lower end of the opening portion 290a of the insulating layer 280. Alternatively, the width D can be the width at half of the depth of the opening portion 290a in the insulating layer 280. Alternatively, the width of the opening portion 290b in the conductive layer 240 can be used.

Portions which are of the oxide semiconductor layer 230 and the insulating layer 250 and positioned inside the opening portion 290 reflect the shape of the opening portion 290. Specifically, the oxide semiconductor layer 230 is provided to cover the bottom and the sidewall of the opening portion 290, and the insulating layer 250 is provided to cover the oxide semiconductor layer 230. The oxide semiconductor layer 230 is preferably provided in contact with the sidewall of the insulating layer 280 in the opening portion 290a. The insulating layer 250 is positioned to face the sidewall of the insulating layer 280 in the opening portion 290a with the oxide semiconductor layer 230 therebetween.

The conductive layer 260 is provided to fill a depressed portion of the insulating layer 250 that reflects the shape of the opening portion 290. When the width D is small, miniaturization of the transistor 200 becomes possible; however, the small width D might decrease the coverage of the sidewall of the opening portion 290 depending on the formation method, thickness, or the like of the components positioned inside the opening portion 290 in the case where the aspect ratio of the opening portion 290 is high or, here, where a value obtained by dividing the depth of the opening portion by the width of the opening portion is large. In the case where the width D is small and the oxide semiconductor layer 230 is thick, coverage of the inside of the opening portion might be further decreased.

The opening portion 290 preferably has a tapered shape at an upper end of the opening portion. The opening portion 290 preferably includes a region having a tapered shape at the upper end of the opening portion and a region which is positioned deeper than the above-mentioned region and which has a steeper sidewall than the upper end. Here, the term “steep” means that the angle of the sidewall with respect to the insulating layer 210 is perpendicular or nearly perpendicular, for example.

With the opening portion 290 having such a shape, the conductive layer 260 can have an appropriate shape even when the size of the transistor 200 is further miniaturized, the width of the opening portion is small, and the aspect ratio is high. Specifically, for example, the conductive layer 260a can be formed on the sidewall of the opening portion 290 with high coverage, and the conductive layer 260b can be formed with a large thickness, so that the conductive layer 260b can be formed over the upper end of the opening portion 290.

The films provided inside the opening portion 290 can be formed by an atomic layer deposition (ALD) method, a sputtering method, a chemical vapor deposition (CVD) method, a vacuum evaporation method, a pulsed laser deposition (PLD) method, or the like.

The opening portion 290 preferably has a tapered shape at the upper end. At least part of the sidewall of the region having the tapered region is preferably covered with the conductive layer 260b.

The opening portion 290 preferably includes a region which is positioned deeper than the above-mentioned region having a tapered shape and which has a steeper sidewall than the upper end. When the opening portion 290 has such a shape, for example, the contact area with the conductive layer 240 is increased in the tapered region, so that the contact resistance between the oxide semiconductor layer 230 and the conductive layer 240 can be reduced. Furthermore, when the insulating layer 280 partly has a tapered shape, for example, the region may function as a region that relieves electric field between the conductive layer 240 and the conductive layer 260.

In the transistor 200 illustrated in FIGS. 2B and 2C, at the opening portion 290, the sidewall of the conductive layer 240 and the sidewall of the insulating layer 280c each include a region having a tapered shape, and the sidewall of the insulating layer 280b and the sidewall of the insulating layer 280a each include a region that is steeper than the sidewall of the conductive layer 240.

It is preferable that the insulating layer 250 favorably cover the sidewall of the opening portion 290 and inhibit a short circuit between the conductive layer 240 and the conductive layer 260.

The conductive layer 260 includes a region positioned over the insulating layer 280. In FIGS. 2B and 2C, the conductive layer 260 includes, over the insulating layer 280, a region that covers each of the conductive layer 240, the oxide semiconductor layer 230, and the insulating layer 250.

In addition, the conductive layer 240 preferably includes a region not covered with the conductive layer 260. In the region not overlapping with the conductive layer 260, an end portion of the conductive layer 240 is positioned outside an end portion of the conductive layer 260. In the region not overlapping with the conductive layer 260, a conductive layer can be provided over and electrically connected to the conductive layer 240.

FIG. 2B illustrates a structure in which the end portion of the conductive layer 240 is positioned outside the end portion of the conductive layer 260 at the outside of the opening portion 290. With such a structure, a plug or the like can be provided over a region that is of the conductive layer 240 and extends beyond the end portion of the conductive layer 260, so as to electrically connect the conductive layer 240 and a conductive layer such as a wiring, an electrode, or the like positioned over the conductive layer 260 to each other.

The insulating layer 250 is provided in contact with the top surface of the oxide semiconductor layer 230. The insulating layer 250 preferably includes a region in contact with the top surface of the conductive layer 240, a region in contact with the side surface of the conductive layer 240, and a region in contact with the top surface of the insulating layer 280.

As illustrated in FIGS. 2B and 2C, part of the insulating layer 250 is positioned outside the opening portion 290, that is, over the conductive layer 240 and the insulating layer 280. In that case, the insulating layer 250 preferably covers end portions of the oxide semiconductor layer 230. Thus, a short circuit between the conductive layer 260 and the oxide semiconductor layer 230 can be prevented. The insulating layer 250 preferably covers end portions of the conductive layer 240. Thus, a short circuit between the conductive layer 260 and the conductive layer 240 can be prevented.

The insulating layer 250 functions as a gate insulating layer of the transistor 200. When the gate insulating layer is thin, a gate potential applied during the operation of the transistor 200 can be reduced. In addition, the transistor 200 can operate at high speed.

Here, FIGS. 2B and 2C illustrate a structure in which the end portion of the oxide semiconductor layer 230 is positioned inside the end portion of the conductive layer 240 at the outside of the opening portion 290. Note that the present invention is not limited thereto. For example, in the X direction, the end portion of the oxide semiconductor layer 230 and the end portion of the conductive layer 240 are aligned or substantially aligned with each other in some cases. Alternatively, the end portion of the oxide semiconductor layer 230 is positioned outside the end portion of the conductive layer 240 in some cases. When the end portion of the oxide semiconductor layer 230 is positioned outside the end portion of the conductive layer 240 and the oxide semiconductor layer 230 covers the end portion of the conductive layer 240, the withstand voltage between the conductive layer 240 and the conductive layer 260 can be further increased, and a leakage current that flows through the insulating layer 250 positioned between the conductive layer 240 and the conductive layer 260 can be further reduced in some cases.

When the angle formed between the top surface of the insulating layer 210 and the sidewall of the opening portion 290 is less than or equal to 60 degrees, preferably less than or equal to 50 degrees, further preferably less than or equal to 40 degrees, the sidewall of the opening portion 290 can have a tapered shape. When the angle formed between the top surface of the insulating layer 210 and the sidewall of the opening portion 290 is less than 20 degrees, the width D of the opening portion 290 is increased and miniaturization of the transistor 200 is difficult in some cases. Thus, in the case where the sidewall of the opening portion 290 is formed to have a tapered shape, the angle formed between the top surface of the insulating layer 210 and the sidewall of the opening portion 290 is greater than or equal to 20 degrees and less than or equal to 75 degrees, preferably greater than or equal to 20 degrees and less than or equal to 70 degrees, further preferably greater than or equal to 20 degrees and less than or equal to 60 degrees, still further preferably greater than or equal to 20 degrees and less than or equal to 50 degrees, for example.

When the angle formed between the top surface of the insulating layer 210 and the sidewall of the opening portion 290 is greater than 60 degrees and less than or equal to 90 degrees, preferably greater than 70 degrees and less than or equal to 90 degrees, further preferably greater than 75 degrees and less than or equal to 90 degrees, still further preferably greater than or equal to 80 degrees and less than or equal to 90 degrees, the sidewall of the opening portion 290 can be steep; accordingly, the semiconductor device can be miniaturized or highly integrated.

Alternatively, for example, the sidewall of the opening portion 290 may have an inverse tapered shape in some cases. In other words, the angle between the side surface of the insulating layer 280 and the top surface of the insulating layer 210 in the opening portion 290 may be larger than 90 degrees in some cases.

The sidewall of the opening portion 290 is preferably provided so as to be perpendicular to the top surface of the insulating layer 210, for example. FIG. 3B illustrates an angle θ1a, an angle θ1b, an angle θ1c, and an angle θ2 which are the angles formed between the top surface of the insulating layer 210 and the side surfaces of the insulating layer 280a, the insulating layer 280b, the insulating layer 280c, and the conductive layer 240, respectively, in the opening portion 290. The angle θ1a, the angle θ1b, the angle θ1c, and the angle θ2 are each greater than 20 degrees and less than or equal to 90 degrees, for example.

FIG. 3B illustrates an example in which the conductive layer 240 and the insulating layer 280c each have a tapered shape. In FIG. 3B, the portions having the tapered shapes are surrounded by a dashed line. The angle θ2 and the angle θ1c are each preferably greater than or equal to 20 degrees and less than or equal to 75 degrees, further preferably greater than or equal to 20 degrees and less than or equal to 70 degrees, still further preferably greater than or equal to 20 degrees and less than or equal to 60 degrees, yet still further preferably greater than or equal to 20 degrees and less than or equal to 50 degrees.

The angle θ1b and the angle θ1a are each preferably greater than 60 degrees and less than or equal to 90 degrees, further preferably greater than 70 degrees and less than or equal to 90 degrees, still further preferably greater than 75 degrees and less than or equal to 90 degrees, yet still further preferably greater than or equal to 80 degrees and less than or equal to 90 degrees.

Note that although the angle θ1a, the angle θ1b, the angle θ1c, and the angle θ2 are the angles formed between the top surface of the insulating layer 210 and the respective layers here, they may be the angles formed between the top surface of the conductive layer 220 and the respective layers.

Note that the thickness of the insulating layer 280c is preferably less than or equal to 50 nm, less than or equal to 30 nm, preferably less than or equal to 20 nm, further preferably less than or equal to 10 nm, in which case, even when the insulating layer 280c has a tapered shape, the size of the opening portion 290 can be prevented from being excessively increased and the area occupied by the transistor can be kept small.

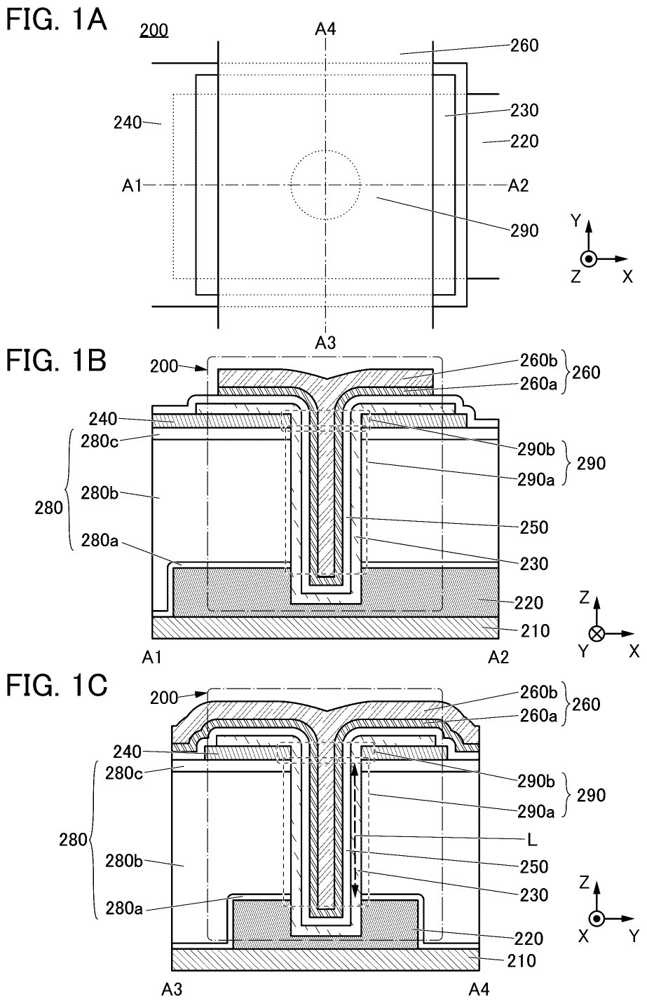

FIGS. 1A to 1C illustrate an example in which the angle θ1a, the angle θ1b, the angle 01c, and the angle θ2 are 90 degrees in FIGS. 2A to 2C.

FIGS. 3C and 3D illustrate variations of FIG. 3B.

FIG. 3C illustrates an example in which the sidewall of the insulating layer 280a at the opening portion 290, as well as the conductive layer 240 and the insulating layer 280c, has a tapered shape. In FIG. 3C, the portions having the tapered shapes are surrounded by dashed lines. When the sidewall of the insulating layer 280a at the opening portion 290 has a tapered shape, coverage with the oxide semiconductor layer 230, the insulating layer 250, and the conductive layer 260a can be increased at the bottom of the opening portion 290 and in the vicinity thereof. Moreover, when the insulating layer 280a is sufficiently thin, an increase in the size of the transistor 200 can also be inhibited. The insulating layer 280a is less than or equal to 50 nm, less than or equal to 30 nm, preferably less than or equal to 20 nm, further preferably less than or equal to 10 nm, for example.

FIG. 3D illustrates an example in which the conductive layer 240 and the insulating layer 280c each include a region having a steep sidewall and the insulating layer 280b and the insulating layer 280a each include a region having a tapered shape. When part of the insulating layer 280 has a tapered shape in this manner, coverage with the components of the transistor 200 can be increased in the opening portion 290, for example.

When a lower end of the sidewall of the conductive layer 240 and an upper end of the sidewall of the insulating layer 280c are discontinuous, the oxide semiconductor layer 230 can include a region that is in contact with the top surface of the insulating layer 280 and is positioned in the opening portion 290. The region functions as, for example, a region that relieves electric field between the conductive layer 240 and the conductive layer 260 in some cases. Furthermore, coverage of the upper end of the opening portion 290 and the vicinity thereof with the oxide semiconductor layer 230 and the layers thereabove, such as the insulating layer 250 and the conductive layer 260, can be increased, for example.

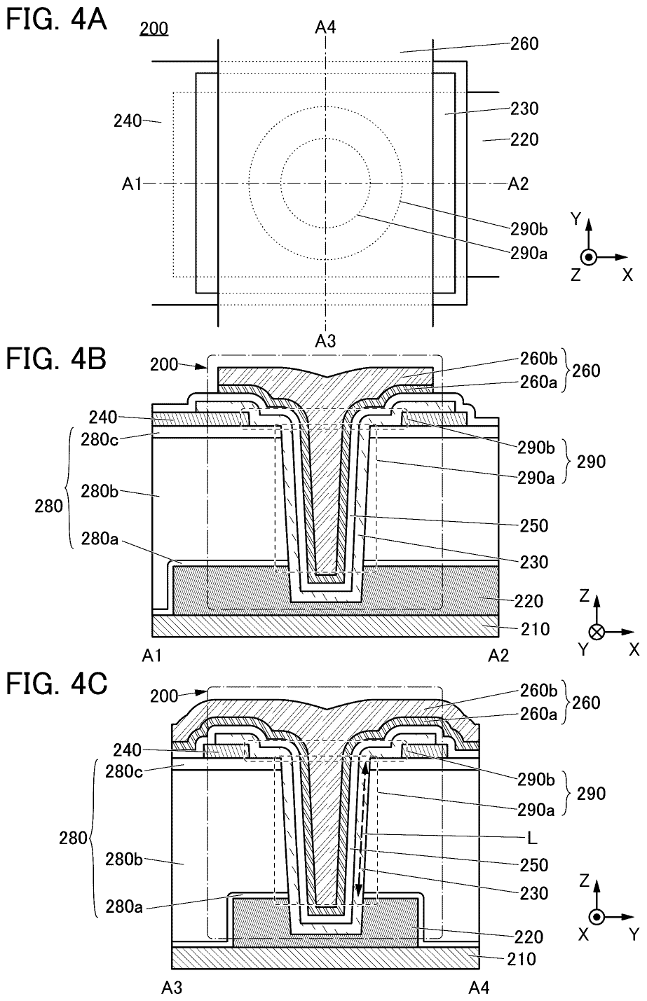

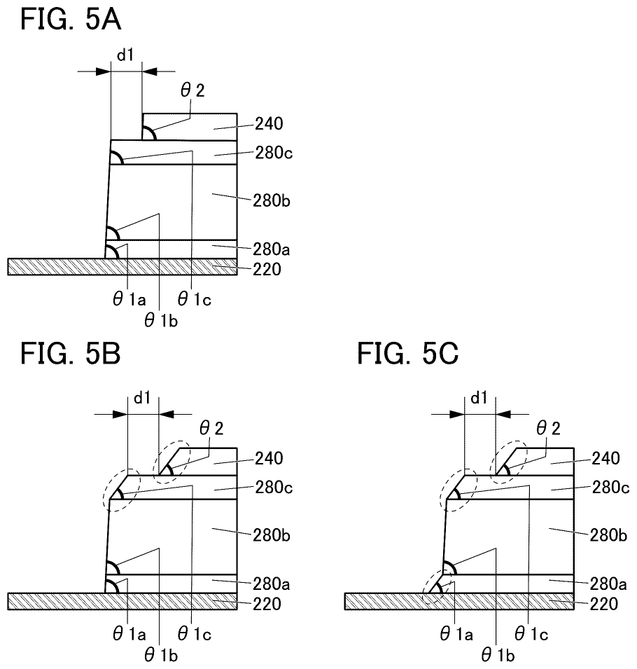

FIG. 4A is a plan view of a semiconductor device including the transistor 200. FIG. 4B is a cross-sectional view taken along a dashed-dotted line A1-A2 in FIG. 4A. FIG. 4C is a cross-sectional view taken along a dashed-dotted line A3-A4 in FIG. 4A. FIG. 5A illustrates the angle θ1a, the angle θ1b, the angle θ1c, and the angle θ2, and corresponds to the cross section illustrated in FIG. 4B. The semiconductor device illustrated in FIGS. 4A to 4C is different from the semiconductor device illustrated in FIGS. 2A to 2C in, for example, that the lower end of the sidewall of the conductive layer 240 and the upper end of the sidewall of the insulating layer 280c are discontinuous. Although FIGS. 4B and 4C illustrate an example in which the sidewalls of the insulating layer 280c and the conductive layer 240 at the opening portion 290 are steeper than those in FIGS. 2B and 2C, the sidewalls may each have a tapered shape.

FIG. 5A illustrates the angle θ1a, the angle θ1b, the angle θ1c, and the angle θ2 which are the angles formed between the top surface of the insulating layer 210 and the side surfaces of the insulating layer 280a, the insulating layer 280b, the insulating layer 280c, and the conductive layer 240, respectively, in the opening portion 290 in FIG. 4B. In the example illustrated in FIG. 5A, the position of the lower end of the sidewall of the conductive layer 240 is shifted outward from the position of the upper end of the sidewall of the insulating layer 280c by a length d1.

In FIG. 5A, the angle θ1a, the angle θ1b, the angle θ1c, and the angle θ2 are each, for example, preferably greater than 60 degrees and less than or equal to 90 degrees, further preferably greater than 70 degrees and less than or equal to 90 degrees, still further preferably greater than 75 degrees and less than or equal to 90 degrees, yet still further preferably greater than or equal to 80 degrees and less than or equal to 90 degrees.

FIGS. 5B and 5C illustrate variations of FIG. 5A.

The angle θ2 and the angle θ1c in FIG. 5B are different from those in FIG. 5A. In FIG. 5B, the portions having the tapered shapes are surrounded by dashed lines. In FIG. 5B, the angle θ2 and the angle θ1c are each, for example, preferably greater than or equal to 20 degrees and less than or equal to 75 degrees, further preferably greater than or equal to 20 degrees and less than or equal to 70 degrees, still further preferably greater than or equal to 20 degrees and less than or equal to 60 degrees, yet still further preferably greater than or equal to 20 degrees and less than or equal to 50 degrees.

The angle θ2, the angle θ1c, and the angle θ1a in FIG. 5C are different from those in FIG. 5A. In FIG. 5C, the portions having the tapered shapes are surrounded by dashed lines. In FIG. 5C, the angle θ2, the angle θ1c, and the angle θ1a are each, for example, preferably greater than or equal to 20 degrees and less than or equal to 75 degrees, further preferably greater than or equal to 20 degrees and less than or equal to 70 degrees, still further preferably greater than or equal to 20 degrees and less than or equal to 60 degrees, yet still further preferably greater than or equal to 20 degrees and less than or equal to 50 degrees.

### <OS Transistor>

In the transistor 200, a metal oxide functioning as a semiconductor (such a metal oxide is also referred to as an oxide semiconductor) is used for the oxide semiconductor layer 230 including a channel formation region. That is, the transistor 200 can be regarded as an OS transistor.

When oxygen vacancies (Vo) and impurities are in a channel formation region of an oxide semiconductor in an OS transistor, electrical characteristics of the OS transistor easily vary and the reliability thereof might worsen. In some cases, hydrogen in the vicinity of an oxygen vacancy forms a defect that is an oxygen vacancy into which hydrogen enters (hereinafter sometimes referred to as V_{O}H), which generates an electron serving as a carrier. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

A region that is of the oxide semiconductor layer 230 and is in contact with the insulating layer 280 and the vicinity thereof function as a channel formation region of the transistor 200. One of a region that is of the oxide semiconductor layer 230 and is in contact with the conductive layer 220 and a region that is of the oxide semiconductor layer 230 and is in contact with the conductive layer 240 functions as a source region, and the other functions as a drain region. That is, the channel formation region is sandwiched between the source region and the drain region.

When the oxide semiconductor layer 230 and the conductive layer 220 are in contact with each other, a metal compound or oxygen vacancies are formed, so that the resistance of the region that is of the oxide semiconductor layer 230 and is in contact with the conductive layer 220 is reduced. Accordingly, the contact resistance between the oxide semiconductor layer 230 and the conductive layer 220 can be reduced. Similarly, when the oxide semiconductor layer 230 and the conductive layer 240 are in contact with each other, the resistance of a region that is of the oxide semiconductor layer 230 and is in contact with the conductive layer 240 is reduced. Accordingly, the contact resistance between the oxide semiconductor layer 230 and the conductive layer 240 can be reduced.

As illustrated in FIG. 3A, the insulating layer 280 is in contact with all the perimeter of the oxide semiconductor layer 230. Thus, the channel formation region of the transistor 200 can be formed in all the perimeter of the oxide semiconductor layer 230 in the opening portion 290 (the entire region in contact with the insulating layer 280). Note that FIG. 3A can be regarded as a cross-sectional view along the XY plane including the channel formation region of the oxide semiconductor layer 230.

The channel length of the transistor 200 is a distance between the source region and the drain region. That is, the channel length of the transistor 200 is determined by the thickness of the insulating layer 280 over the conductive layer 220. In FIG. 2C, a channel length L of the transistor 200 is indicated by a dashed double-headed arrow. The channel length L is a distance between an end portion of a region where the oxide semiconductor layer 230 and the conductive layer 220 are in contact with each other and an end portion of a region where the oxide semiconductor layer 230 and the conductive layer 240 are in contact with each other in a cross-sectional view. That is, the channel length L corresponds to the length of a side surface on the opening portion 290 side of the insulating layer 280 in the cross-sectional view.

The channel length of a planar transistor is limited by the light exposure limit of photolithography, and further miniaturization is difficult. In contrast, in the transistor included in the semiconductor device of one embodiment of the present invention, the channel length can be determined by the thickness of the insulating layer 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200 can have a higher on-state current and higher frequency characteristics.

Since the channel length of the transistor included in the semiconductor device of one embodiment of the present invention is determined by the thickness of the insulating layer 280 over the conductive layer 220, even when the channel length is set greater than or equal to 60 nm, for example, the area occupied by the transistor, specifically, the area of the transistor seen from the above is roughly determined by the width of the opening portion 290. As described later, the width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. For example, even in the case where the channel length is 150 nm, the width of the opening portion 290 can be shorter than 150 nm. That is, a transistor having a width of the opening portion shorter than the channel length can be obtained, in which case the area occupied by the transistor can be reduced and the semiconductor device can be highly integrated.

When the channel length of the transistor is, for example, less than or equal to 1 μm, less than or equal to 500 nm, or less than or equal to 300 nm, the productivity, yield, and the like can be improved in formation of the insulating layer 280 and formation of the opening portion 290 in the insulating layer 280, for example.

Thus, the channel length of the transistor included in the semiconductor device of one embodiment of the present invention is preferably greater than or equal to 0.1 nm, greater than or equal to 1 nm, or greater than or equal to 5 nm, and less than or equal to 1 μm, less than or equal to 500 nm, or less than or equal to 300 nm.

In addition, as described above, the channel formation region, the source region, and the drain region can be formed in the opening portion 290. Thus, the area occupied by the transistor 200 can be reduced as compared with a lateral transistor, e.g., a planar transistor, in which the channel formation region, the source region, and the drain region are provided separately on the X-Y plane. Thus, the semiconductor device can be highly integrated. In the case where the semiconductor device of one embodiment of the present invention is used in a memory device, the storage capacity per unit area can be increased.

As illustrated in FIG. 3A, the oxide semiconductor layer 230, the insulating layer 250, and the conductive layer 260 are provided concentrically. Therefore, a side surface of the conductive layer 260 provided at the center faces a side surface of the oxide semiconductor layer 230 with the insulating layer 250 therebetween. That is, in the top view, all the perimeter of the oxide semiconductor layer 230 serves as the channel formation region. In this case, for example, the channel width of the transistor 200 is determined by the length of the perimeter of the oxide semiconductor layer 230. In other words, the channel width of the transistor 200 is determined by the width of the opening portion 290 (the diameter in the case where the opening portion 290 is circular in the top view). In FIG. 2C and FIG. 3A, the width D of the opening portion 290 is indicated by a dashed double-dotted double-headed arrow. In FIG. 3A, a channel width W of the transistor 200 is indicated by a dashed-dotted double-headed arrow. By increasing the width D of the opening portion 290, the channel width per unit area can be increased and the on-state current can be increased.

In the case where the opening portion 290 is formed by a photolithography method, the width D of the opening portion 290 is limited by the light exposure limit of photolithography. In addition, the width D of the opening portion 290 is determined by the film thicknesses of the oxide semiconductor layer 230, the insulating layer 250, and the conductive layer 260 provided in the opening portion 290. The width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the top view, the width D of the opening portion 290 corresponds to the diameter of the opening portion 290, and the channel width W can be calculated to be “D×π”.

The channel length L of the transistor 200 is preferably shorter than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables a transistor with favorable electrical characteristics and high reliability.

In the case where the opening portion 290 is formed to be circular in a top view, the oxide semiconductor layer 230, the insulating layer 250, and the conductive layer 260 are formed concentrically. This makes the distance between the conductive layer 260 and the oxide semiconductor layer 230 substantially uniform, so that a gate electric field can be substantially uniformly applied to the oxide semiconductor layer 230.

Although an example where the opening portion 290 is circular in the top view is described in this embodiment, the present invention is not limited thereto. For example, the opening portion 290 may have, in the top view, an almost circular shape such as an ellipse, a polygonal shape such as a square, or a polygonal shape with rounded corners such as a square with rounded corners.

FIG. 6A is an enlarged view of part of the cross section illustrated in FIG. 2B. As illustrated in FIG. 6A, a depressed portion overlapping with the opening portion 290 is formed in the conductive layer 220, and at least part of the oxide semiconductor layer 230, part of the insulating layer 250, and part of the conductive layer 260 are formed to fill the depressed portion. With such a structure, the gate electric field of the conductive layer 260 can be easily applied to the oxide semiconductor layer 230 in the vicinity of the conductive layer 220. The depressed portion of the conductive layer 220 is formed by overetching at the time of forming the opening portion 290, for example.

In FIG. 6A, the opening portion 290 and the depressed portion of the conductive layer 220 form a continuous opening portion. In such a case, for example, the bottom of the continuous opening portion serves as the top surface of the conductive layer 220.

FIG. 6B illustrates an example in which the conductive layer 220 has a three-layer stacked structure of a conductive layer 220a, a conductive layer 220b over the conductive layer 220a, and a conductive layer 220c over the conductive layer 220b. The bottom surface of the depressed portion of the conductive layer 220 corresponds to the top surface of the conductive layer 220b, and a side surface of the depressed portion corresponds to a side surface on the opening portion 290 side of the conductive layer 220c. Here, the shortest distance Tc from the top surface of the insulating layer 210 to the top surface of the conductive layer 220c that is in contact with the insulating layer 280 is preferably longer than the shortest distance Ta from the top surface of the insulating layer 210 to the top surface of the insulating layer 250. Thus, the contact resistance between the side surface of the conductive layer 220c and the oxide semiconductor layer 230 can be reduced. Consequently, a decrease in the on-state current of the transistor 200 can be inhibited.

FIG. 6C is a variation of FIG. 6B. In FIG. 6C, the bottom surface of the depressed portion of the conductive layer 220 is positioned above the top surface of the conductive layer 220b. As illustrated in FIG. 6C, the oxide semiconductor layer 230 is not necessarily in contact with the conductive layer 220a or the conductive layer 220b.

FIG. 6D illustrates an example in which the oxide semiconductor layer 230 is in contact with the top surface of the conductive layer 220 (the top surface of the conductive layer 220c in FIG. 6D). The depressed portion is sometimes not provided in the conductive layer 220 as illustrated in FIG. 6D depending on the formation conditions of the opening portion 290.

In FIG. 6D, the bottom of the opening portion 290 corresponds to the top surface of the conductive layer 220.

When the conductive layer 220 is in contact with the side surface of the oxide semiconductor layer 230, the contact area between the conductive layer 220 and the oxide semiconductor layer 230 can be increased, so that contact resistance can be reduced.

When a region where the conductive layer 220 and the conductive layer 260 overlap with each other is included, a gate electric field can be easily applied to the channel formation region of the oxide semiconductor layer 230, so that the electrical characteristics of the transistor can be improved, for example. Furthermore, a gate electric field is easily applied also to a region that is of the oxide semiconductor layer 230 and is in contact with the conductive layer 220, whereby the on-state current of the transistor can be increased, for example.

### <Structure Example 2 of Semiconductor Device>

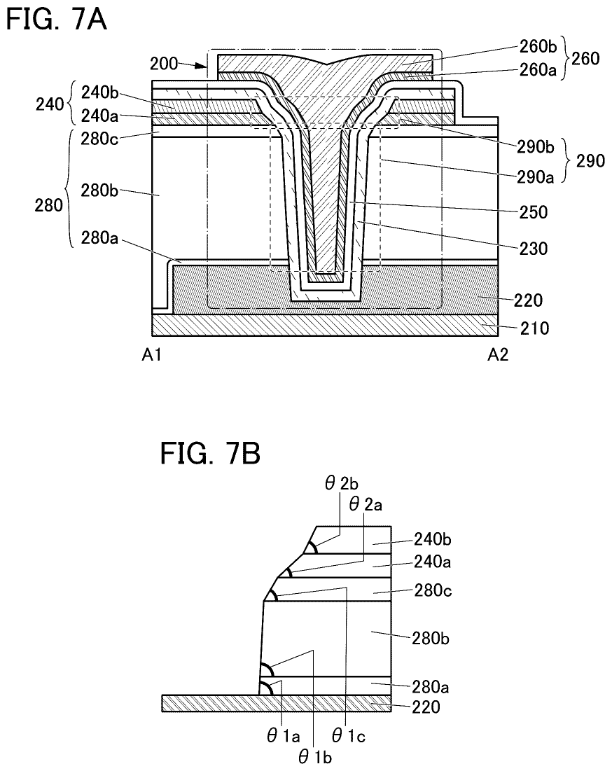

The conductive layer 240 may have a stacked-layer structure of two or more layers. FIG. 7A is different from FIG. 2B mainly in that the conductive layer 240 has a stacked-layer structure of a conductive layer 240a and a conductive layer 240b over the conductive layer 240a.

FIG. 7B illustrates the angle θ1a, the angle θ1b, the angle θ1c, an angle θ2a, and an angle θ2b, and corresponds to the cross section illustrated in FIG. 7A. The angle θ2a and the angle θ2b are angles corresponding to sidewalls of the conductive layer 240a and the conductive layer 240b, respectively.

Although FIG. 7A illustrates an example in which the conductive layer 240 has a two-layer structure, the conductive layer 240 may have a stacked structure of three or more layers. Furthermore, the conductive layer 260a and the conductive layer 260b may each further have a stacked-layer structure.

In the example illustrated in FIG. 7B, the angle θ2b is greater than the angle θ2a. The angle θ2b and the angle θ2a are each preferably greater than or equal to 20 degrees and less than or equal to 60 degrees, further preferably greater than or equal to 20 degrees and less than or equal to 50 degrees, still further preferably greater than or equal to 20 degrees and less than or equal to 40 degrees. When the angle θ2b is greater than the angle θ2a, the tapered shape at the upper end of the opening portion 290 can be a shape of a depressed portion, so that coverage of the upper end of the opening portion 290 and the vicinity thereof with the oxide semiconductor layer 230 and the layers thereabove, such as the insulating layer 250 and the conductive layer 260, can be increased, for example.

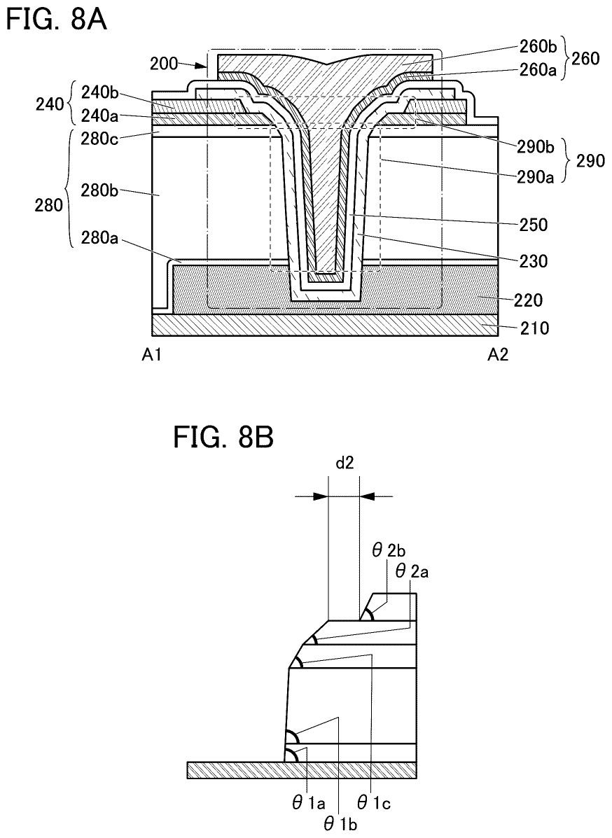

FIGS. 8A and 8B illustrate a variation of FIGS. 7A and 7B. FIG. 8A illustrates an example in which the lower end of the sidewall of the conductive layer 240b and the upper end of the sidewall of the conductive layer 240a are discontinuous. FIG. 8B illustrates the angle θ1a, the angle θ1b, the angle θ1c, the angle θ2a, and the angle θ2b, and corresponds to the cross section illustrated in FIG. 8A. As illustrated in FIG. 8B, the position of the lower end of the sidewall on the opening portion 290 side of the conductive layer 240b is shifted outward from the position of the upper end of the sidewall on the opening portion 290 side of the conductive layer 240a by a length d2.

In FIG. 8A, the oxide semiconductor layer 230 includes a region in contact with the top surface of the conductive layer 240a. Accordingly, the contact area between the oxide semiconductor layer 230 and the conductive layer 240a can be increased, so that the contact resistance can be reduced. When the conductive layer 240a and the conductive layer 240b form a step-like shape at the upper end of the opening portion 290 as illustrated in FIG. 8A, coverage of the upper end of the opening portion 290 and the vicinity thereof with the oxide semiconductor layer 230 and the layers thereabove, such as the insulating layer 250 and the conductive layer 260, can be increased, for example.

### <Structure Example 3 of Semiconductor Device>

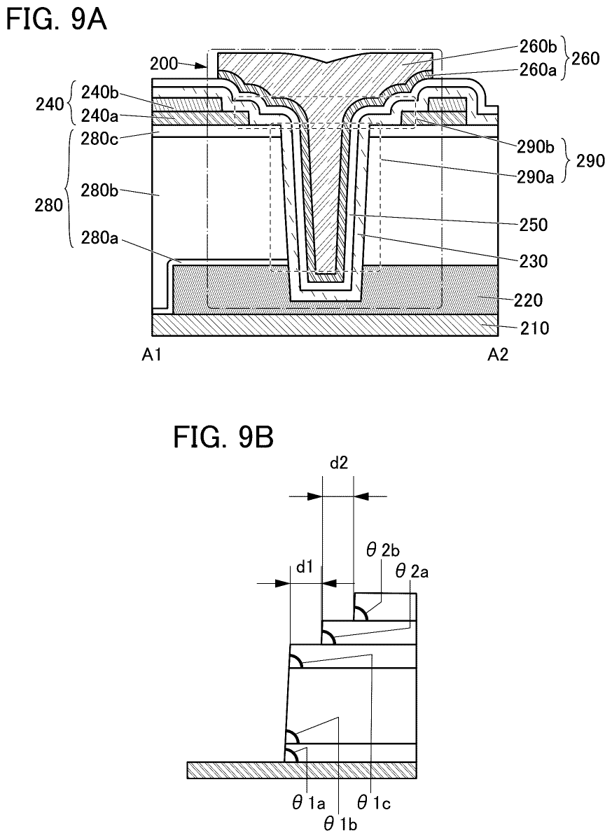

FIG. 9A is different from FIG. 4B mainly in that the conductive layer 240 has a stacked-layer structure of the conductive layer 240a and the conductive layer 240b over the conductive layer 240a. In FIG. 9A, an end portion on the opening portion 290 side of the conductive layer 240b is positioned outside an end portion on the opening portion 290 side of the conductive layer 240a. Thus, the conductive layer 240a and the conductive layer 240b form a step-like shape.

FIG. 9B illustrates the angle θ1a, the angle θ1b, the angle θ1c, the angle θ2a, and the angle θ2b, and corresponds to the cross section illustrated in FIG. 9A. The angle θ2a and the angle θ2b are angles corresponding to the sidewalls of the conductive layer 240a and the conductive layer 240b, respectively. The position of the lower end of the sidewall on the opening portion 290 side of the conductive layer 240b is shifted outward from the position of the upper end of the sidewall on the opening portion 290 side of the conductive layer 240a by the length d2.

Although FIG. 9A illustrates an example in which the conductive layer 240 has a two-layer structure, the conductive layer 240 may have a stacked structure of three or more layers. Although FIG. 9B illustrates an example in which each of the sidewalls of the insulating layer 280a, the insulating layer 280b, the insulating layer 280c, the conductive layer 240a, and the conductive layer 240b is steep, each of the sidewalls may have a tapered shape.

### <Insulating Layers 283 and 285>

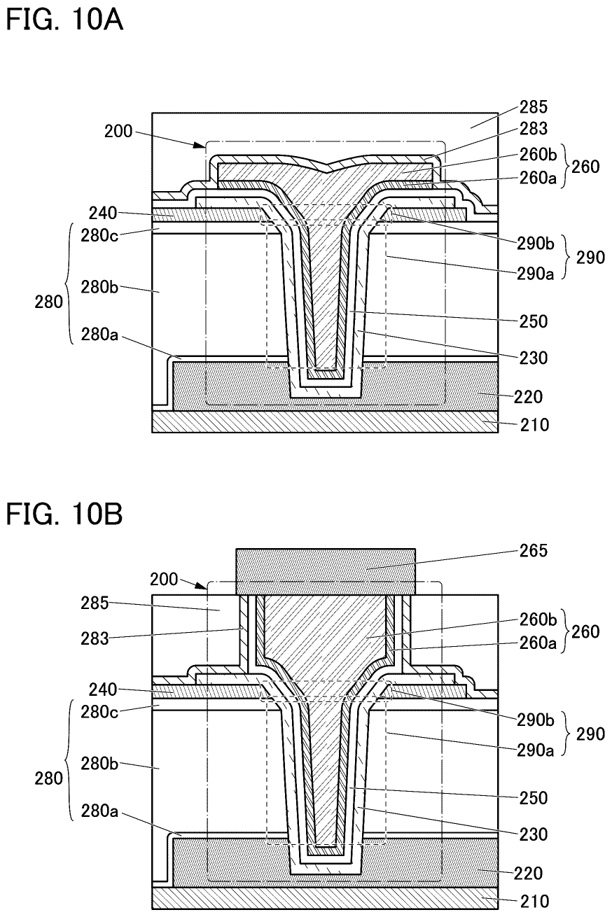

As illustrated in FIG. 10A, an insulating layer 283 over the transistor 200 and an insulating layer 285 over the insulating layer 283 can be provided in the semiconductor device. The insulating layer 283 and the insulating layer 285 each function as an interlayer film. The insulating layer 283 is provided to cover the conductive layer 260, the insulating layer 280, and the like. In the structure example illustrated in FIG. 10A, for example, the insulating layer 283 can be formed by a deposition method of isotropically forming a film with high coverage, and the insulating layer 285 with a flat top surface can be formed over the insulating layer 283.

### <Variation of Semiconductor Device>

A semiconductor device illustrated in FIG. 10B includes the insulating layer 283 and the insulating layer 285 over the transistor 200 and a conductive layer 265 over the insulating layer 285. It is preferable that the top surface of the conductive layer 260 be level with or substantially level with the top surface of the insulating layer 285. The conductive layer 265 is provided over the insulating layer 285, the insulating layer 283, and the conductive layer 260. The conductive layer 260 and the conductive layer 265 are electrically connected to each other. The conductive layer 265 is preferably in contact with the top surface of the conductive layer 260.

In the semiconductor device illustrated in FIG. 10B, the area where the conductive layer 260 overlaps with the conductive layer 240 over the insulating layer 280 is extremely small. Since the insulating layer 285 is provided between the conductive layer 265 and the conductive layer 240, a larger thickness of the insulating layer 285 can reduce the parasitic capacitance between the conductive layer 265 and the conductive layer 240.

### <Materials of Components of Semiconductor Device>

Materials that can be used for the semiconductor device of this embodiment are described below. Note that the layers included in the semiconductor device of this embodiment may have a single-layer structure or a stacked-layer structure.

### [Insulating Layers]

An inorganic insulating film is preferably used for each of the insulating layers (the insulating layer 210, the insulating layer 250, the insulating layer 280, the insulating layer 283, the insulating layer 285, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specifically, it is preferable to use a barrier insulating layer against impurities such as water and hydrogen and oxygen.

Note that in this specification and the like, a barrier insulating layer refers to an insulating layer having a barrier property. In addition, the barrier property refers to a property that does not easily allow diffusion of a target substance, a property that does not easily allow passage of a target substance, a property with low permeability of a target substance, a function of inhibiting diffusion of a target substance, or a function of inhibiting transmission of a target substance. Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

As the insulating layer having a function of inhibiting the passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be given, for example. In addition, an oxide containing aluminum and hafnium (hafnium aluminate) can be given, for example. Furthermore, metal nitrides such as aluminum nitride, silicon nitride oxide, and silicon nitride can be given, for example.

In addition, an insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, the number of oxygen vacancies in the oxide semiconductor layer can be reduced. Examples of an insulating layer in which a region containing excess oxygen is easily formed include silicon oxide, silicon oxynitride, and porous silicon oxide.

With miniaturization and high integration of a transistor, for example, a problem such as generation of a leakage current may arise because of a thin gate insulating layer. When a material with a high dielectric constant (also referred to as a high-k material) is used for the gate insulating layer, the voltage at the time of operation of the transistor can be reduced while the physical thickness is maintained. Furthermore, the equivalent oxide thickness (EOT) of the gate insulating layer can be reduced. When a material with a high dielectric constant is used for a dielectric layer of a capacitor, the element can have a larger capacitance value. By contrast, when a material with a low dielectric constant is used for the insulating layer functioning as an interlayer film, parasitic capacitance generated between wirings can be reduced. Thus, a material is preferably selected depending on the function of an insulating layer. Note that a material with a low dielectric constant is a material with high dielectric strength.

Examples of a material with a high dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include resins such as polyester, polyolefin, polyamide (e.g., nylon and aramid), polyimide, polycarbonate, and acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

For example, an inorganic insulating material such as silicon oxide, silicon oxynitride, and silicon nitride oxide can be used for both a layer in which a material with a high dielectric constant is suitably used, such as a gate insulating layer, and a layer in which a material with a low dielectric constant is suitably used, such as an interlayer film. These materials have relatively low dielectric constants as compared with a high-k material such as hafnium oxide, for example, and thus are each expressed as a material with a low dielectric constant in this specification and the like in some cases.

A material that can show ferroelectricity may be used for an insulating layer included in the semiconductor device. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Note that although the metal oxide and the metal nitride are shown above as examples of the material that can have ferroelectricity, one embodiment of the present invention is not limited thereto. For example, a metal oxynitride in which nitrogen is added to any of the above-described metal oxides, a metal nitride oxide in which oxygen is added to any of the above-described metal nitrides, or the like may be used.

As the material that can show ferroelectricity, a mixture or compound containing a plurality of materials selected from the above-listed materials can be used, for example. Alternatively, the insulating layer 130 can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

A metal oxide containing one or both of hafnium and zirconium is preferable because the metal oxide can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can show ferroelectricity processed into a layer shape is referred to as a ferroelectric layer in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer 130 needs to include a crystal. It is particularly preferable that the insulating layer include a crystal having an orthorhombic crystal structure, in which case ferroelectricity is exhibited. A crystal included in the insulating layer may have one or more of crystal structures selected from cubic, tetragonal, orthorhombic, monoclinic, and hexagonal crystal structures. Alternatively, the insulating layer may have an amorphous structure. In that case, the insulating layer may have a composite structure including an amorphous structure and a crystal structure.

The insulating layer 250 functions as the gate insulating layer of the transistor 200. The insulating layer 250 is preferably formed using a material with a high dielectric constant.

The insulating layer 250 preferably has a function of trapping and fixing hydrogen. In this case, the hydrogen concentration in the oxide semiconductor layer 230 (in particular, the hydrogen concentration in the channel formation region of the transistor) can be reduced. Accordingly, V_{O}H in the channel formation region can be reduced, so that the channel formation region can be an i-type or substantially i-type region.

Examples of a material for an insulating layer having a function of capturing or fixing hydrogen include metal oxides such as an oxide containing hafnium, an oxide containing aluminum, an oxide containing aluminum and hafnium (hafnium aluminate), and an oxide containing magnesium. Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

Note that a function of capturing or fixing a target substance can be rephrased as a property that does not easily allow diffusion of a target substance. Thus, a function of capturing or fixing a target substance can be rephrased as a barrier property.

In the case where the insulating layer 250 has a stacked-layer structure, it is preferable to use a layer having a function of capturing and fixing hydrogen as any of the layers (hereinafter referred to as a first insulating layer of the insulating layer 250). In the case where the insulating layer 250 has a stacked-layer structure of two layers, a layer having a function of capturing or fixing hydrogen is used as the layer in contact with the oxide semiconductor layer 230; and in the case where the insulating layer 250 has a stacked-layer structure of three or more layers, a layer having a function of capturing or fixing hydrogen is used as the layer that is close to the oxide semiconductor layer 230, whereby hydrogen contained in the oxide semiconductor layer 230 can be more effectively captured or fixed. Thus, the hydrogen concentration in the oxide semiconductor layer 230 can be lowered.

In addition to the first insulating layer, a second insulating layer of the insulating layer 250 is preferably formed using a barrier insulating layer against hydrogen. Examples of a barrier insulating layer against hydrogen include aluminum oxide, magnesium oxide, hafnium oxide, gallium oxide, silicon nitride, and silicon nitride oxide.

As the first insulating layer of the insulating layer 250, hafnium silicate or the like is preferably used, for example. The first insulating layer of the insulating layer 250 preferably has an amorphous structure. When the layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. Furthermore, the thickness distribution of the film provided over the insulating layer can be uniform.

Furthermore, inhibiting formation of a crystal grain boundary in the insulating layer can reduce a leakage current due to the defect states in the crystal grain boundary. Thus, the insulating layer can function as an insulating film with a low leakage current.

Since hafnium oxide is a material with a high dielectric constant, hafnium silicate is a material having a high dielectric constant depending on the content of silicon. Accordingly, when hafnium silicate is used for a gate insulating layer, a gate potential applied during operation of the transistor can be lowered while the physical thickness of the gate insulating layer is maintained. In addition, the equivalent oxide thickness (EOT) of the gate insulating layer can be reduced.

As described above, for the first insulating layer of the insulating layer 250, an oxide containing aluminum and/or hafnium is preferably used, an oxide containing aluminum and/or hafnium and having an amorphous structure is further preferably used, and aluminum oxide having an amorphous structure is still further preferably used.

When a barrier insulating layer against hydrogen is used as the second insulating layer of the insulating layer 250, diffusion of impurities contained in the conductive layer 260 into the oxide semiconductor layer 230 can be inhibited. Silicon nitride is suitable for the insulating layer 250 because of its high hydrogen barrier property. Here, the second insulating layer is preferably over the first insulating layer.

With such a structure, a semiconductor device having favorable electrical characteristics can be provided. A highly reliable semiconductor device can be provided. A semiconductor device with a small variation in transistor's electrical characteristics can be provided. A semiconductor device that has a high on-state current can be provided.

Furthermore, the insulating layer 250 may include a thermally stable insulating layer such as silicon oxide or silicon oxynitride.

Furthermore, the insulating layer 250 preferably includes a layer that can supply oxygen to the oxide semiconductor layer 230. An oxide can be used for the layer that can supply oxygen. When the insulating layer 250 contains silicon oxide or silicon oxynitride, oxygen can be adequately supplied from the insulating layer 250 to the oxide semiconductor layer 230.

The insulating layer 250 may include, between a pair of insulating layers having a function of capturing and fixing hydrogen, a thermally stable insulating layer.

The insulating layer 250 preferably includes a barrier insulating layer against oxygen. In this case, oxidation of the conductive layer 240, the conductive layer 260, and the like can be inhibited. In the case where the insulating layer 250 has a stacked-layer structure, a layer in contact with the conductive layer 240 and a layer in contact with the conductive layer 260 are each preferably a barrier insulating layer against oxygen.

The layer of the insulating layer 250 which is in contact with the conductive layer 240 is preferably less likely to transmit oxygen than at least the insulating layer 280. When the layer has a barrier property against oxygen, oxidation of the side surface of the conductive layer 240 can be inhibited, and accordingly formation of an oxide film on the side surface can be inhibited. It is thus possible to inhibit a reduction in the on-state current or field-effect mobility of the transistor 200.

When a barrier insulating layer against hydrogen and oxygen is used as the above-described second insulating layer, for example, oxidation of the conductive layer 260 can be inhibited. Furthermore, diffusion of oxygen contained in the oxide semiconductor layer 230 into the conductive layer 260 can be inhibited, and accordingly formation of oxygen vacancies in the oxide semiconductor layer 230 can be inhibited.

Examples of the barrier insulating layer against oxygen include an oxide containing hafnium, an oxide containing aluminum, an oxide containing aluminum and hafnium (hafnium aluminate), magnesium oxide, gallium oxide, gallium zinc oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate).

An oxide containing hafnium and silicon (hafnium silicate) is an excellent insulating layer that functions as a barrier insulating layer against oxygen and moreover easily has an amorphous structure and thereby has a function of capturing or fixing hydrogen as described above.

Silicon nitride is an excellent insulating layer that functions as a barrier insulating layer against oxygen and moreover has a high barrier property against hydrogen as described above.

The insulating layer 250 preferably has a two-layer structure in which the first insulating layer having a function of capturing or fixing hydrogen and the second insulating layer having a barrier property against hydrogen and oxygen are stacked in this order from the oxide semiconductor layer 230 side.

For example, an oxide containing one or both of aluminum and hafnium can be used for the first insulating layer, and silicon nitride can be used for the second insulating layer.

The insulating layer 250 preferably has a three-layer structure in which a third insulating layer containing a material with a relatively low dielectric constant, the first insulating layer having a function of capturing or fixing hydrogen, and the second insulating layer having a barrier property against hydrogen and oxygen are stacked in this order from the oxide semiconductor layer 230 side. The material with a relatively low dielectric constant contained in the third insulating layer refers to, for example, a material with a lower dielectric constant than any one or more of the other layers in the stacked-layer structure. Here, silicon oxide or silicon oxynitride can be used as the third insulating layer. The third insulating layer is a layer in contact with the oxide semiconductor layer 230. When an oxide is used for the third insulating layer, oxygen can be supplied to the oxide semiconductor layer 230. Providing the second insulating layer can inhibit oxygen contained in the third insulating layer from diffusing into the conductive layer 260 and inhibit the conductive layer 260 from being oxidized. Furthermore, a reduction in the amount of oxygen supplied from the third insulating layer to the oxide semiconductor layer 230 can be inhibited.

For example, silicon oxide or silicon oxynitride can be used for the third insulating layer, an oxide containing one or both of aluminum and hafnium can be used for the first insulating layer, and silicon nitride can be used for the second insulating layer.

The insulating layer 250 preferably has a four-layer structure where a fourth insulating layer having a barrier property against oxygen, a third insulating layer containing a material with a relatively low dielectric constant, a first insulating layer having a function of capturing or fixing hydrogen, and a second insulating layer having a barrier property against hydrogen and oxygen are stacked in this order from the oxide semiconductor layer 230 side. The first insulating layer to the third insulating layer can have a structure similar to that of the layers used in the above three-layer structure. The fourth insulating layer is in contact with the oxide semiconductor layer 230. When the fourth insulating layer has a barrier property against oxygen, release of oxygen from the oxide semiconductor layer 230 can be inhibited. For the fourth insulating layer, aluminum oxide is preferably used, for example. Aluminum oxide has a function of capturing or fixing hydrogen, and thus is suitably used for the fourth insulating layer in contact with the oxide semiconductor layer 230.

For example, aluminum oxide can be used for the fourth insulating layer, silicon oxide or silicon oxynitride can be used for the third insulating layer, an oxide containing one or both of aluminum and hafnium can be used for the first insulating layer, and silicon nitride can be used for the second insulating layer.

In the insulating layer 250, it is preferable that a region overlapping with the channel formation region of the oxide semiconductor layer 230 especially have a thickness greater than or equal to 0.1 nm and less than or equal to 30 nm, preferably greater than or equal to 0.1 nm and less than or equal to 20 nm, preferably greater than or equal to 0.1 nm and less than or equal to 10 nm, further preferably greater than or equal to 0.1 nm and less than or equal to 8.0 nm, further preferably greater than or equal to 0.5 nm and less than or equal to 7.0 nm.

The thickness of each layer included in the insulating layer 250 is preferably thin for miniaturization of the transistor. The thickness of each layer included in the insulating layer 250 is, for example, greater than or equal to 0.1 nm and less than or equal to 10 nm, greater than or equal to 0.1 nm and less than or equal to 5 nm, greater than or equal to 0.5 nm and less than or equal to 5 nm, greater than or equal to 1 nm and less than 5 nm, or greater than or equal to 1 nm and less than or equal to 3 nm. Note that each layer included in the insulating layer 250 at least partly includes a region with the above-described thickness.

Typically, the thicknesses of the fourth insulating layer, the third insulating layer, the first insulating layer, and the second insulating layer are 1 nm, 2 nm, 2 nm, and 1 nm, respectively. Such a structure enables the transistor to have favorable electrical characteristics even when the transistor is miniaturized or highly integrated.

The insulating layer 210 functions as an interlayer film and preferably has a low dielectric constant. In the case where a material with a low dielectric constant is used for an interlayer film, the parasitic capacitance generated between wirings can be reduced. Silicon oxide and silicon oxynitride are thermally stable, and thus are suitable for the insulating layer 210.

The concentration of impurities such as water or hydrogen in the insulating layer 210 is preferably reduced. This can inhibit entry of impurities such as water or hydrogen into the channel formation region of the oxide semiconductor layer 230.

As the insulating layer 210, a barrier insulating layer against hydrogen is preferably used. When the insulating layer 210 provided outside the oxide semiconductor layer 230 has a barrier property against hydrogen, diffusion of hydrogen into the oxide semiconductor layer 230 can be inhibited.

Examples of a material for the barrier insulating layer against hydrogen include aluminum oxide, magnesium oxide, hafnium oxide, gallium oxide, silicon nitride, and silicon nitride oxide.

For example, a silicon nitride film is preferably used as the insulating layer 210.

Furthermore, the insulating layer 210 may have a stacked-layer structure of two layers. For example, an insulating layer having a function of capturing or fixing hydrogen can be used as the upper layer of the insulating layer 210. Accordingly, hydrogen in the oxide semiconductor layer 230 can be diffused into the upper layer of the insulating layer 210 through the conductive layer 220, and the hydrogen can be captured or fixed. Thus, the hydrogen concentration in the oxide semiconductor layer 230 can be lowered.

For example, a silicon nitride film is preferably used as the lower layer of the insulating layer 210 and an oxide film containing hafnium and silicon (hafnium silicate film) is preferably used as the upper layer.

As either or both of the insulating layer 283 and the insulating layer 285, a barrier insulating layer against hydrogen is preferably used. In this case, diffusion of hydrogen from above the insulating layer 283 into the oxide semiconductor layer 230 can be inhibited. A silicon nitride film and a silicon nitride oxide film can be suitably used for the insulating layer 283 because they release few impurities (e.g., water and hydrogen) and are less likely to transmit oxygen and hydrogen.

It is particularly preferable to use a silicon nitride film formed by a sputtering method as either or both of the insulating layer 283 and the insulating layer 285. A deposition gas in a sputtering method need not include molecules containing hydrogen; thus, the hydrogen concentration in the insulating layer 283 can be reduced. When the insulating layer 283 is formed by a sputtering method, a high-density silicon nitride film can be obtained.

As either or both of the insulating layer 283 and the insulating layer 285, an insulating layer having a function of capturing or fixing hydrogen may be used. With such a structure, diffusion of hydrogen from above the insulating layer 283 and the insulating layer 285 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For either or both of the insulating layer 283 and the insulating layer 285, aluminum oxide, hafnium oxide, hafnium silicate, or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

Furthermore, the semiconductor device can have a structure that does not include either one of the insulating layer 283 and the insulating layer 285.

For the insulating layer 285, a material with a low dielectric constant can be used, for example. In the case where a material with a low dielectric constant is used for an interlayer film, parasitic capacitance between wirings can be reduced.

The concentration of impurities such as water or hydrogen in the insulating layer 285 is preferably reduced. This can inhibit entry of impurities such as water or hydrogen into the channel formation region of the oxide semiconductor layer 230.

The insulating layer 280 preferably includes the above-described barrier insulating layer against hydrogen. The insulating layer 280 is provided to surround the oxide semiconductor layer 230. When the insulating layer 280 provided outside the oxide semiconductor layer 230 has a barrier property against hydrogen, diffusion of hydrogen into the oxide semiconductor layer 230 can be inhibited. For example, the insulating layer 280 preferably includes a silicon nitride film.

Note that silicon nitride also has a barrier property against oxygen. Thus, using silicon nitride for the insulating layer 280 can inhibit extraction of oxygen from the oxide semiconductor layer 230, and accordingly can inhibit formation of an excess amount of oxygen vacancies in the oxide semiconductor layer 230.

Furthermore, when silicon nitride is used for the insulating layer 280, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved.

The insulating layer 280 preferably includes any of an oxide insulating film, an oxynitride film, and an insulating layer including a region containing excess oxygen, which are described above.

For example, the insulating layer including a region containing excess oxygen can be formed by deposition by a sputtering method in an atmosphere containing oxygen. Since a molecule containing hydrogen is not used as a deposition gas in the sputtering method, the hydrogen concentration in the insulating layer 280 can be reduced. When at least one layer in the insulating layer 280 is formed in this manner, oxygen can be supplied from the insulating layer 280 to the channel formation region of the oxide semiconductor layer 230, so that oxygen vacancies and VoH therein can be reduced.

The concentration of impurities such as water or hydrogen in the insulating layer 280 is preferably reduced. This can inhibit entry of impurities such as water or hydrogen into the channel formation region of the oxide semiconductor layer 230.

Note that since the thickness of the insulating layer 280 over the conductive layer 220 corresponds to the channel length of the transistor 200, the thickness of the insulating layer 280 is set as appropriate depending on the design value of the channel length of the transistor 200.

The insulating layer 280 preferably has a stacked-layer structure including the insulating layer 280a, the insulating layer 280b over the insulating layer 280a, and the insulating layer 280c over the insulating layer 280b, for example.

The insulating layer 280b is a layer in contact with the channel formation region of the oxide semiconductor layer 230. When an insulating layer containing oxygen is used as the insulating layer 280b, oxygen can be supplied to the oxide semiconductor layer 230.

The insulating layer 280b preferably includes a region having a higher oxygen content than at least one of the insulating layers 280a and 280c. In particular, the insulating layer 280b preferably includes a region having a higher oxygen content than the insulating layers 280a and 280c. When the insulating layer 280b has a high oxygen content, an i-type region can be easily formed in the oxide semiconductor layer 230 in the vicinity of the insulating layer 280b.

It is further preferable that a film from which oxygen is released by heating be used for the insulating layer 280b. When the insulating layer 280b releases oxygen by being heated during the manufacturing process of the transistor 200, the oxygen can be supplied to the oxide semiconductor layer 230. The oxygen supply from the insulating layer 280b to the oxide semiconductor layer 230, particularly to the channel formation region of the oxide semiconductor layer 230, reduces the amount of oxygen vacancies and VoH in the oxide semiconductor layer 230, so that the transistor can have favorable electrical characteristics and high reliability.

In order to improve the electrical characteristics and reliability of the OS transistor, it is important that the amount of oxygen supplied to the oxide semiconductor be optimized after the hydrogen concentration in the oxide semiconductor is sufficiently reduced.

For example, the amount of released oxygen molecules of the insulating layer 280b is preferably greater than or equal to 1.0×10¹⁴ molecules/cm² and less than 1.0×10¹⁵ molecules/cm². Note that the amount of released oxygen molecules can be measured by thermal desorption spectrometry.

In particular, when the channel length of the transistor 200 is short, the influence of oxygen vacancies and VoH in the channel formation region on the electrical characteristics and reliability is especially large. Accordingly, when the amount of oxygen supplied to the oxide semiconductor layer 230 is optimized after the hydrogen concentration in the oxide semiconductor layer 230 is sufficiently reduced, a transistor with a short channel length, favorable electrical characteristics, and high reliability can be provided.

The insulating layer 280b is preferably formed by a deposition method such as a sputtering method or a PECVD method. It is particularly preferable to employ a sputtering method, in which a hydrogen gas does not need to be used as a film deposition gas, to form a film having an extremely low hydrogen content. Therefore, supply of hydrogen to the oxide semiconductor layer 230 is inhibited and electrical characteristics of the transistor 200 can be stabilized.

In the case where a large amount of oxygen is supplied to the oxide semiconductor layer 230, heat treatment in an oxygen-containing atmosphere or plasma treatment in an oxygen-containing atmosphere is preferably performed after formation of the insulating layer 280b, for example. Alternatively, an oxide film may be formed over the top surface of the insulating layer 280b by a sputtering method in an oxygen atmosphere to supply oxygen. After that, the oxide film may be removed. Such treatment can supply oxygen to the insulating layer 280b and increase the amount of oxygen supplied to the oxide semiconductor layer 230.

The contact region between the oxide semiconductor layer 230 and the insulating layer 280a and the contact region between the oxide semiconductor layer 230 and the insulating layer 280c are supplied with a smaller amount of oxygen than the contact region between the oxide semiconductor layer 230 and the insulating layer 280b. Thus, the contact region between the oxide semiconductor layer 230 and the insulating layer 280a and the contact region between the oxide semiconductor layer 230 and the insulating layer 280c each have a low resistance in some cases. That is, by adjusting the thickness of the insulating layer 280a, the range of a region functioning as one of the source region and the drain region can be controlled. Similarly, by adjusting the thickness of the insulating layer 280c, the range of a region functioning as the other of the source region and the drain region can be controlled. As described above, the thicknesses of the insulating layers 280a and 280c can be set as appropriate in accordance with the characteristics required for the transistor.

A material with a low dielectric constant is preferably used for the insulating layer 280b. In that case, parasitic capacitance generated between wirings can be reduced. For example, silicon oxide or silicon oxynitride can be suitably used for the insulating layer 280b.

For each of the insulating layer 280a and the insulating layer 280c, a barrier insulating layer against oxygen is preferably used. Provision of the insulating layer 280a between the insulating layer 280b and the conductive layer 220 can inhibit the conductive layer 220 from being oxidized and having high resistance. Furthermore, provision of the insulating layer 280c between the insulating layer 280b and the conductive layer 240 can inhibit the conductive layer 240 from being oxidized and having high resistance.

As the insulating layer 280a, an insulating layer having a function of capturing or fixing hydrogen may be used. With such a structure, diffusion of hydrogen from below the insulating layer 280a into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 280a, magnesium oxide, aluminum oxide, hafnium oxide, an oxide containing hafnium and silicon, or the like can be used. Alternatively, for example, a stacked-layer film of aluminum oxide and silicon nitride over the aluminum oxide may be used as the insulating layer 280a. Similarly, an insulating layer having a function of capturing or fixing hydrogen may be used as the insulating layer 280c.

For example, silicon nitride can be used for the insulating layers 280a and 280c, and silicon oxide can be used for the insulating layer 280b.

### [Conductive Layer]

For the conductive layers (e.g., the conductive layer 220, the conductive layer 240, and the conductive layer 260) included in the semiconductor device, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, it is preferable to use tantalum nitride, titanium nitride, ruthenium nitride, a nitride containing molybdenum, a nitride containing tungsten, titanium, and aluminum, a nitride containing tantalum and aluminum, ruthenium oxide, an oxide containing strontium and ruthenium, an oxide containing lanthanum and nickel, or the like. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (a registered trademark)), and indium zinc oxide containing tungsten oxide. In this specification and the like, a conductive film deposited using the conductive material containing oxygen may be referred to as an oxide conductive film.

In addition, a conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

For the conductive layer 260, any of the above metal elements, an alloy containing any of the above metal elements as a component, an alloy containing a combination of the above metal elements, or the like can be used. For example, a material having high conductivity, such as tungsten, is preferably used. For the conductive layer 260, a conductive material that is not easily oxidized, a conductive material having a function of inhibiting diffusion of oxygen, or the like is preferably used. As described above, examples of the conductive material include a conductive material containing nitrogen and a conductive material containing oxygen. Thus, a decrease in conductivity of the conductive layer 260 can be inhibited.

It is particularly preferable to use, for the conductive layer 260, a conductive material containing oxygen and a metal element contained in the metal oxide where a channel is formed. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide where a channel is formed can be captured in some cases. Hydrogen entering from a surrounding insulating layer or the like can also be captured in some cases.

The conductive layer 260 has a thickness greater than or equal to 3 nm and less than or equal to 500 nm, for example. The thickness of the conductive layer 260 is, for example, larger than or equal to the thickness of the insulating layer 250. When the conductive layer 260 has a large thickness, the resistance of the conductive layer 260 can be reduced.

Furthermore, the conductive layer 260 preferably has a two-layer structure of the conductive layer 260a and the conductive layer 260b over the conductive layer 260a.

When the conductive layer 260a is formed using a conductive material having a function of inhibiting diffusion of oxygen, release of oxygen from the oxide semiconductor layer 230 can be inhibited and formation of oxygen vacancies in the oxide semiconductor layer 230 can be inhibited, for example.

Furthermore, the use of a conductive material that is not easily oxidized for the conductive layer 260a can inhibit the conductive layer 260a from being oxidized and thereby having a reduced conductivity owing to release of oxygen from the oxide semiconductor layer 230 or release of oxygen from the insulating layer 250, for example.

A material used for the conductive layer 260b preferably has higher conductivity than the material used for the conductive layer 260a, for example. When the conductive layer 260b has a large thickness, the amount of current flowing through the conductive layer 260b can be further increased.

When a deposition method with favorable coverage is used for the conductive layer 260a, the conductive layer 260a can be favorably formed along the sidewall of the opening portion 290.

For the conductive layer 260a, a conductive material containing nitrogen, a conductive material containing oxygen, or the like can be used, for example. For the conductive layer 260a, a conductive material containing oxygen and a metal element contained in the metal oxide where the channel is formed can be used, for example.

As the conductive layer 260a, for example, a conductive material containing the above metal element and nitrogen can be used; tantalum nitride, titanium nitride, ruthenium nitride, a nitride containing molybdenum, a nitride containing tungsten, titanium, and aluminum, a nitride containing tantalum and aluminum, or the like can be used, for example.

For the conductive layer 260a, a conductive material containing the above metal element and oxygen can be used, for example; examples of the conductive material include ruthenium oxide, an oxide containing strontium and ruthenium, and an oxide containing lanthanum and nickel.

One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may also be used.

For the conductive layer 260a, titanium, tantalum, ruthenium, or a material containing one or more selected from the metal elements is preferable because of being a conductive material that is not easily oxidized, a conductive material having a function of inhibiting diffusion of oxygen, or a material that maintains the conductivity even after absorbing oxygen.

For the conductive layer 260b, any of the above metal elements, an alloy containing any of the above metal elements as a component, an alloy containing a combination of the above metal elements, or the like can be used, for example. For example, tungsten can be used.

Furthermore, the conductive layer 260a may have a stacked-layer structure. Moreover, the conductive layer 260b may have a stacked-layer structure. In the case where the conductive layer 260a has a stacked-layer structure, a plurality of materials that can be used for the conductive layer 260a are stacked, for example. Alternatively, a plurality of materials selected from materials that can be used for the conductive layer of one embodiment of the present invention may be stacked. In the case where the conductive layer 260b has a stacked-layer structure, a plurality of materials that can be used for the conductive layer 260b are stacked, for example. Alternatively, a plurality of materials selected from materials that can be used for the conductive layer of one embodiment of the present invention may be stacked.

Each of the conductive layers 220 and 240 is in contact with the oxide semiconductor layer 230, and thus is preferably formed using a conductive material that is not easily oxidized, a conductive material that maintains its low electrical resistance even after being oxidized, an oxide conductive material, or a conductive material that has a function of inhibiting diffusion of oxygen. Examples of the conductive material include a conductive material containing nitrogen and a conductive material containing oxygen. Thus, a decrease in conductivity of the conductive layer 220 and the conductive layer 240 can be inhibited.

When a conductive material containing oxygen is used for the conductive layer 220 or the conductive layer 240, the conductive layer 220 or the conductive layer 240 can maintain its conductivity even after absorbing oxygen. It is also preferable that an insulating layer containing oxygen, such as hafnium oxide, be used as the insulating layer 210 in order that the conductive layer 220 can maintain its conductivity. For each of the conductive layers 220 and 240, ITO, ITSO, IZO (registered trademark), or the like is preferably used, for example.

In the case where the conductive layer 220 has a three-layer structure of a first conductive layer (e.g., the conductive layer 220a), a second conductive layer (e.g., the conductive layer 220b), and a third conductive layer (e.g., the conductive layer 220c) stacked in this order over the insulating layer 210, a conductive material that is not easily oxidized or a conductive material having a function of inhibiting diffusion of oxygen is preferably used for the first conductive layer, a material having high conductivity is preferably used for the second conductive layer, and a conductive material containing oxygen is preferably used for the third conductive layer. Specifically, for example, titanium nitride is preferably used for the first conductive layer, tungsten is preferably used for the second conductive layer, and ITO or ITSO is preferably used for the third conductive layer. In this case, titanium nitride is in contact with the insulating layer 210, and ITO or ITSO is in contact with the oxide semiconductor layer 230. Such a structure can maintain conductivity even when the conductive layer 220 is in contact with the oxide semiconductor layer 230. In the case of using an oxide insulating layer for the insulating layer 210, the conductive layer 220 can be inhibited from being excessively oxidized by the insulating layer 210. When tungsten with high conductivity is used for the second conductive layer, the conductivity of the conductive layer 220 can be increased.

In the case where the conductive layer 240 has a stacked-layer structure of two layers (e.g., the conductive layer 240a and the conductive layer 240b), for example, the lower layer is preferably formed using a material having higher conductivity than the upper layer and the upper layer is preferably formed using a conductive material containing oxygen. Specifically, for example, ruthenium, tungsten, titanium nitride, or tantalum nitride is preferably used for the lower layer, and ITO or ITSO is preferably used for the upper layer. In this case, ITO or ITSO is in contact with the oxide semiconductor layer 230. Such a structure can maintain conductivity even when the conductive layer 240 is in contact with the oxide semiconductor layer 230. When a material having higher conductivity than the upper layer is used for the lower layer, the conductivity of the conductive layer 240 can be increased.

In the case where the conductive layer 240 has a stacked-layer structure of two layers, a material having high conductivity may be used for the upper layer (e.g., the conductive layer 240b), and a conductive material containing oxygen may be used for the lower layer (e.g., the conductive layer 240a). In such a case, for example, when the oxide semiconductor layer 230 is in contact with the top surface of the conductive layer 240a, the contact resistance between the conductive layer 240 and the oxide semiconductor layer 230 can be reduced.

### [Oxide Semiconductor Layer 230]

As described above, the oxide semiconductor layer 230 includes a channel formation region. The channel formation region can be regarded as an i-type (intrinsic) or substantially i-type region. The oxide semiconductor layer 230 further includes a source region and a drain region. The source and drain regions are n-type regions (low-resistance regions) having a higher carrier concentration than the channel formation region.

There is no particular limitation on the crystallinity of the semiconductor material used for the oxide semiconductor layer 230, and any of an amorphous semiconductor, a single crystal semiconductor, and a semiconductor having other crystallinity than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The band gap of the metal oxide functioning as a semiconductor is preferably greater than or equal to 2.0 eV, further preferably greater than or equal to 2.5 eV. The use of such a metal oxide having a wide band gap can reduce the off-state current of the transistor. The off-state current of the OS transistor is small, so that power consumption of the semiconductor device can be sufficiently reduced. The OS transistor has high frequency characteristics, which enables the semiconductor device to operate at high speed.

The off-state current of the OS transistor can be lower than or equal to 100 zA (z: zept, 10⁻²¹), lower than or equal to 50 zA, lower than or equal to 10 zA, lower than or equal to 1 zA, lower than or equal to 100 yA (y: yocto, 10⁻²⁴), or lower than or equal to 10 yA per channel width of 1 μm. The off-state current of the OS transistor used in the semiconductor device of one embodiment of the present invention is preferably lower than or equal to 50 zA, lower than or equal to 10 zA, lower than or equal to 1 zA, lower than or equal to 100 yA, or lower than or equal to 10 yA per transistor, for example.

The temperature dependence of off-state current can be found by measurement of the off-state current at a plurality of temperatures and extrapolation with the use of an Arrhenius plot. The off-state current of the OS transistor used in the semiconductor device of one embodiment of the present invention is preferably lower than or equal to 1 aA (a: atto=10⁻¹⁸), further preferably lower than or equal to 100 zA, still further preferably lower than or equal to 10 zA at 110° C. At 27° C., the off-state current is preferably lower than or equal to 1 zA, further preferably lower than or equal to 100 yA, still further preferably lower than or equal to 10 yA.

Examples of the metal oxide that can be used for the oxide semiconductor layer 230 include indium oxide, gallium oxide, and zinc oxide. The metal oxide preferably contains at least indium (In) or zinc (Zn). The metal oxide preferably contains two or three selected from indium, an element M, and zinc. The element M is a metal element or metalloid element that has a high bonding energy with oxygen and is, for example, a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, the oxide semiconductor layer 230 can be formed using indium oxide (In oxide), indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide, IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

By increasing the proportion of the number of indium atoms in the total number of atoms of all the metal elements included in the metal oxide, the field-effect mobility of the transistor can be increased. In addition, the transistor can have a high on-state current.

Instead of indium or in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements contained in the metal oxide, the metal oxide can have a large band gap. That is, formation of oxygen vacancies in the metal oxide can be inhibited. Accordingly, generation of carriers due to oxygen vacancies is inhibited, which makes the off-state current of the transistor low. Furthermore, a shift in the threshold voltage of the transistor can be inhibited. Furthermore, changes in the electrical characteristics of the transistor can be reduced to improve the reliability of the transistor.

The composition of the metal oxide used for the oxide semiconductor layer 230 affects the electrical characteristics and reliability of the transistor. Therefore, by determining the composition of the metal oxide in accordance with the electrical characteristics and reliability required for the transistor, the semiconductor device can have both excellent electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements of such an In-M-Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the neighborhood of any of the above atomic ratios. Note that the neighborhood of the atomic ratio includes ±30% of an intended atomic ratio. By increasing the proportion of the number of In atoms in the metal oxide, the on-state current, field-effect mobility, or the like of the transistor can be improved.

When a composition having an atomic ratio of In:M:Zn=1:1:1 or in the neighborhood thereof is used as the metal oxide, the transistor can have normally-off characteristics. In the case where the metal oxide is deposited by a sputtering method, zinc might be reduced in the deposited metal oxide. Therefore, for example, the atomic ratio of the target is preferably In:M:Zn=1:1:1.2 or in the neighborhood thereof. In the case where deposition is performed by an ALD method, In might be reduced in the deposited metal oxide.

The proportion of the number of In atoms may be less than that of the number of element M atoms in the In-M-Zn oxide. Examples of the atomic ratio of the metal elements of such an In-M-Zn oxide include In:M:Zn=1:3:2, In:M:Zn=1:3:3, and In:M:Zn=1:3:4 and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

In the case where the metal oxide is an In—Zn oxide, examples of the atomic ratio of metal elements in the In—Zn oxide include In:Zn=1:1, In:Zn=2:1, In:Zn=4:1, and a composition in the neighborhood of any of these atomic ratios. In addition, the In—Zn oxide may contain a slight amount of the element M. For example, in the case where Sn is contained as the element M, examples of the atomic ratio of metal elements in the metal oxide include In:Sn:Zn=2:0.1:1, In:Sn:Zn=4:0.1:1, and a composition in the neighborhood of any of these atomic ratios.

Analysis of the composition of the metal oxide used as the oxide semiconductor layer 230 can be performed by energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES), for example. Alternatively, these methods may be combined as appropriate to be employed for analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage. In some cases, the element M is difficult to quantize or the element M is not detected.

A sputtering method or an ALD method can be suitably used for forming the metal oxide. Note that in the case where the metal oxide is formed by a sputtering method, the composition of the formed metal oxide may be different from the composition of a target. In particular, the zinc content percentage of the formed metal oxide may be reduced to approximately 50% of that of the target. The metal oxide may be formed by a chemical vapor deposition (CVD) method, a molecular beam epitaxy (MBE) method, a pulsed laser deposition (PLD) method, or the like.

The oxide semiconductor layer 230 may have a stacked-layer structure including two or more metal oxide layers. The two or more metal oxide layers included in the oxide semiconductor layer 230 may have the same composition or substantially the same compositions. Employing a stacked-layer structure of metal oxide layers having the same composition can reduce the manufacturing cost because the metal oxide layers can be formed using the same sputtering target.

The two or more metal oxide layers in the oxide semiconductor layer 230 may have different compositions.

The oxide semiconductor layer 230 can have a two-layer structure, for example. Hereinafter, the first layer is referred to as an oxide layer 230a, and the second layer is referred to as an oxide layer 230b. Note that the oxide layer 230a and the oxide layer 230b are not illustrated here. Note that the oxide layer 230a is a layer closer to the conductive layer 220 and the sidewall of the opening portion 290, and the oxide layer 230b is a layer closer to the insulating layer 250, for example. The positions of the oxide layer 230a and the oxide layer 230b are not limited thereto.

For the oxide layer 230a, it is preferable to use a material having higher conductivity than a material for the oxide layer 230b, for example. When a material having high conductivity is used for the oxide layer 230a which is in contact with the source electrode and the drain electrode (the conductive layer 220 and the conductive layer 240), the contact resistance between the oxide semiconductor layer 230 and the conductive layer 220 and the contact resistance between the oxide semiconductor layer 230 and the conductive layer 240 can be reduced, so that the transistor can have a high on-state current.

Here, when a material having high conductivity is used for the oxide layer 230b provided on the side of the conductive layer 260 functioning as the gate electrode, the threshold voltage of the transistor 200 is shifted and a drain current flowing at the time when the gate voltage is 0 V (hereinafter also referred to as a cutoff current) becomes large in some cases. Specifically, the threshold voltage might be low when the transistor 200 is an n-channel transistor. Thus, a material having lower conductivity than a material for the oxide layer 230a is preferably used for the oxide layer 230b. Accordingly, in the case where the transistor 200 is an n-channel transistor, the transistor can have a high threshold voltage and a low cut-off current. Note that characteristics with a low cut-off current is sometimes referred to as normally-off characteristics.

When the oxide semiconductor layer 230 has a stacked-layer structure and a material having higher conductivity than a material for the oxide layer 230b is used for the oxide layer 230a, as described above, the transistor can have normally-off characteristics and a high on-state current. Consequently, the semiconductor device can have both low power consumption and high performance.

The carrier concentration in the oxide layer 230a is preferably higher than that in the oxide layer 230b. When the carrier concentration in the oxide layer 230a is increased, the conductivity is increased and the contact resistance between the oxide semiconductor layer 230 and the conductive layer 220 and the contact resistance between the oxide semiconductor layer 230 and the conductive layer 240 can be reduced, so that the transistor can have a high on-state current. When the carrier concentration in the oxide layer 230b is reduced, the conductivity is reduced, so that the transistor can have normally-off characteristics.

Note that the oxide semiconductor layer 230 is not limited to having the above structure, and a material having lower conductivity than a material for the oxide layer 230b may be used for the oxide layer 230a. The carrier concentration in the oxide layer 230a may be lower than that in the oxide layer 230b.

The band gap of a first metal oxide used for the oxide layer 230a is preferably different from that of a second metal oxide used for the oxide layer 230b. For example, a difference between the band gaps of the first and second metal oxides is preferably greater than or equal to 0.1 eV, further preferably greater than or equal to 0.2 eV, still further preferably greater than or equal to 0.3 eV.

The band gap of the first metal oxide used for the oxide layer 230a is preferably smaller than that of the second metal oxide used for the oxide layer 230b. Accordingly, the contact resistance between the oxide semiconductor layer 230 and the conductive layer 220 and the contact resistance between the oxide semiconductor layer 230 and the conductive layer 240 can be reduced, so that the transistor can have a high on-state current. In the case where the transistor 200 is an n-channel transistor, the transistor can have a high threshold voltage and normally-off characteristics. Furthermore, when the second metal oxide has a large band gap, carriers can be inhibited from being generated and induced in the oxide layer 230b and at the interface between the oxide layer 230b and the insulating layer 250. This can improve the reliability of the transistor.

For example, the content percentage of the element M in the first metal oxide is preferably lower than that of the element M in the second metal oxide. Specifically, for example, a metal oxide with an atomic ratio of In:M:Zn=1:1:1 or the neighborhood thereof is preferably used for the oxide layer 230a, and a metal oxide with an atomic ratio of In:M:Zn=1:3:2 or the neighborhood thereof is preferably used for the oxide layer 230b. In this case, it is particularly preferable to use one or more of gallium, aluminum, and tin as the element M.

Note that the oxide semiconductor layer 230 is not limited to having the above structure, and the band gap of the first metal oxide may be larger than that of the second metal oxide.

The content percentage of the element M in the first metal oxide is preferably lower than that of the element M in the second metal oxide. The first metal oxide may contain no or a slight amount of element M. For example, the first metal oxide used for the oxide layer 230a is preferably an In—Zn oxide, and the second metal oxide used for the oxide layer 230b is preferably an In-M-Zn oxide. Specifically, the first metal oxide can be an In—Zn oxide, and the second metal oxide can be an In—Ga—Zn oxide.

For example, as the oxide layer 230a, it is preferable to use a metal oxide with an atomic ratio of In:Zn=1:1 or the neighborhood thereof, a metal oxide with an atomic ratio of In:Zn=2:1 or the neighborhood thereof, a metal oxide with an atomic ratio of In:Sn:Zn=2:0.1:1 or the neighborhood thereof, a metal oxide with an atomic ratio of In:Zn=4:1 or the neighborhood thereof, a metal oxide with an atomic ratio of In:Sn:Zn=4:0.1:1 or the neighborhood thereof, or an indium oxide. As the metal oxide layer 230b, it is preferable to use a metal oxide with an atomic ratio of In:Ga:Zn=1:1:1 or the neighborhood thereof, a metal oxide with an atomic ratio of In:Ga:Zn=1:3:2 or the neighborhood thereof, or a metal oxide with an atomic ratio of In:Ga:Zn=1:3:4 or the neighborhood thereof. With this structure, the transistor 200 can have a high on-state current and high reliability with small variations.

Note that the oxide semiconductor layer 230 is not limited to having the above structure, and the content percentage of the element M in the first metal oxide may be higher than that of the element M in the second metal oxide.

Alternatively, the use of a metal oxide having an atomic ratio of In:M:Zn=1:1:1 or a composition in the neighborhood thereof for each of the oxide layer 230a and the oxide layer 230b enables the transistor to be normally off.

There is no particular limitation on the crystallinity of the semiconductor material used for the oxide semiconductor layer 230, and any of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that the oxide semiconductor layer 230 include a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide layer having crystallinity as the oxide semiconductor layer 230, the density of defect states in the oxide semiconductor layer 230 can be reduced, which enables the semiconductor device to have high reliability. Note that the CAAC structure is a crystal structure in which a plurality of nanocrystals (typically, a plurality of IGZO nanocrystals) have c-axis alignment and are connected on the a-b plane without alignment. According to a high-resolution cross-sectional TEM image of an OS film having the CAAC structure, metal atoms are arranged in a layered manner in the crystal parts. Thus, the CAAC structure of the OS film can also be referred to as a structure including the layered crystal parts.

The polycrystalline structure includes a crystal grain boundary (grain boundary). When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. A CAAC structure has a fewer crystal grain boundaries (grain boundaries) in the a-b plane than the polycrystalline structure; thus, a highly reliable semiconductor device can be achieved.

As the crystallinity of the metal oxide layer used as the oxide semiconductor layer 230 becomes higher, the density of defect states in the oxide semiconductor layer 230 can be reduced. In contrast, with the use of a metal oxide layer having low crystallinity, a large amount of current can flow through the transistor.

The higher the substrate temperature (the stage temperature) in the formation of the metal oxide layer is, the higher the crystallinity of the metal oxide layer can be. The crystallinity of the metal oxide layer can be increased as the proportion of the flow rate of an oxygen gas to the flow rate of the whole formation gas (also referred to as oxygen flow rate ratio) used in formation is higher.

The crystallinity of the oxide semiconductor layer 230 can be analyzed with an X-ray diffraction (XRD) pattern, a transmission electron microscope (TEM) image, or an electron diffraction (ED) pattern, for example. Alternatively, these methods may be combined as appropriate to be employed for analysis.

The oxide semiconductor layer 230 can have a stacked-layer structure of two or more metal oxide layers having different crystallinities. In that case, the compositions of the two or more metal oxide layers may be different from, the same as, or substantially the same as each other. For example, in a stacked-layer structure of a first metal oxide layer and a second metal oxide layer thereover, the second metal oxide layer can include a region with higher crystallinity than the first metal oxide layer. Alternatively, the second metal oxide layer can include a region having lower crystallinity than the first metal oxide layer. Note that in the case where the second metal oxide layer includes a region having lower crystallinity than the first metal oxide layer, heat treatment (also referred to as crystallization treatment) is performed after formation of the second metal oxide layer, whereby the crystallinity of the second metal oxide layer can be increased.

For example, a metal oxide with an atomic ratio of In:M:Zn=1:3:2 or the neighborhood thereof or a metal oxide with an atomic ratio of In:M:Zn=1:3:4 or the neighborhood thereof is preferably used for the oxide layer 230a, and a metal oxide with an atomic ratio of In:M:Zn=1:1:1 or the neighborhood thereof is preferably used for the oxide layer 230b. When a metal oxide with a high ratio of Zn to In is used for the oxide layer 230a, the crystallinity of the oxide layer 230a can be increased. Furthermore, when the oxide layer 230b is formed over the oxide layer 230a with high crystallinity, the crystallinity of the oxide layer 230b can be easily increased. This is preferable because the crystallinity of the whole oxide semiconductor layer 230 can be increased. In this case, it is particularly preferable to use gallium, aluminum, or tin as the element M. For example, two IGZO layers having different compositions may be stacked. Alternatively, a stacked-layer structure of one selected from an indium oxide, an indium gallium oxide, and IGZO, and one selected from IAZO, IAGZO, and ITZO (registered trademark) may be employed, for example.

Furthermore, the oxide semiconductor layer 230 may have a stacked-layer structure of three or more layers. The oxide semiconductor layer 230 can have a three-layer structure of an oxide layer, the oxide layer 230a over the oxide layer, and the oxide layer 230b over the oxide layer 230a, for example.

The oxide layer 230a and the oxide layer 230b can have the above-described structure. The oxide layer positioned below the oxide layer 230a can have a structure similar to that of the oxide layer 230b. Hereinafter, the oxide layer and the oxide layer 230b are collectively described as a pair of oxide layers between which the oxide layer 230a is interposed.

For example, for the oxide layer 230a, it is preferable to use a metal oxide with an atomic ratio of In:Zn=1:1 or the neighborhood thereof, a metal oxide with an atomic ratio of In:Zn=2:1 or the neighborhood thereof, a metal oxide with an atomic ratio of In:Sn:Zn=2:0.1:1 or the neighborhood thereof, a metal oxide with an atomic ratio of In:Zn=4:1 or the neighborhood thereof, a metal oxide with an atomic ratio of In:Sn:Zn=4:0.1:1 or the neighborhood thereof, or an indium oxide. For the pair of oxide layers between which the oxide layer 230a is interposed, it is preferable to use a metal oxide with an atomic ratio of In:Ga:Zn=1:1:1 or the neighborhood thereof, a metal oxide with an atomic ratio of In:Ga:Zn=1:3:2 or the neighborhood thereof, or a metal oxide with an atomic ratio of In:Ga:Zn=1:3:4 or the neighborhood thereof.

The pair of oxide layers between which the oxide layer 230a is interposed preferably has a larger band gap than the oxide layer 230a. Accordingly, the oxide layer 230a is interposed between the pair of oxide layers with a large band gap, and functions as a main current path (channel). When the oxide layer 230a is interposed between the pair of oxide layers, the trap states at and near the interface with the oxide layer 230a can be reduced. Accordingly, a buried-channel transistor where a channel is away from the interface with an insulating layer can be achieved, whereby the field-effect mobility can be increased. Furthermore, the influence of interface states that might be formed on the back channel side is reduced, so that light deterioration (e.g., light negative bias deterioration) of the transistor can be inhibited and the reliability of the transistor can be increased.

The thickness of the oxide semiconductor layer 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a miniaturized semiconductor device, the thickness of the oxide semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

In the deposition of the oxide semiconductor layer, two kinds of deposition methods, that is, a sputtering method and an ALD method, are preferably used. For example, after a first oxide semiconductor layer having a CAAC structure is formed by a sputtering method, a second oxide semiconductor layer having lower crystallinity than the CAAC structure is formed by an ALD method, in which case, an atomic layer of the second oxide semiconductor layer is expected to fill or repair a gap between crystal parts in the atomic level in the CAAC structure of the first oxide semiconductor layer. After the second oxide semiconductor layer is formed by an ALD method, heat treatment (e.g., at a temperature higher than or equal to 100° C. and lower than or equal to 500° C., preferably higher than or equal to 200° C. and lower than or equal to 450° C., further preferably higher than or equal to 300° C. and lower than or equal to 400° C.) is preferably performed. By the heat treatment, the gap between crystal parts in the atomic level in the CAAC structure of the first oxide semiconductor layer is expected to be repaired by the second oxide semiconductor layer (i.e., crystal molecules formed by the ALD method). The oxide semiconductor layer formed by the two kinds of deposition methods may be referred to as a hybrid OS.

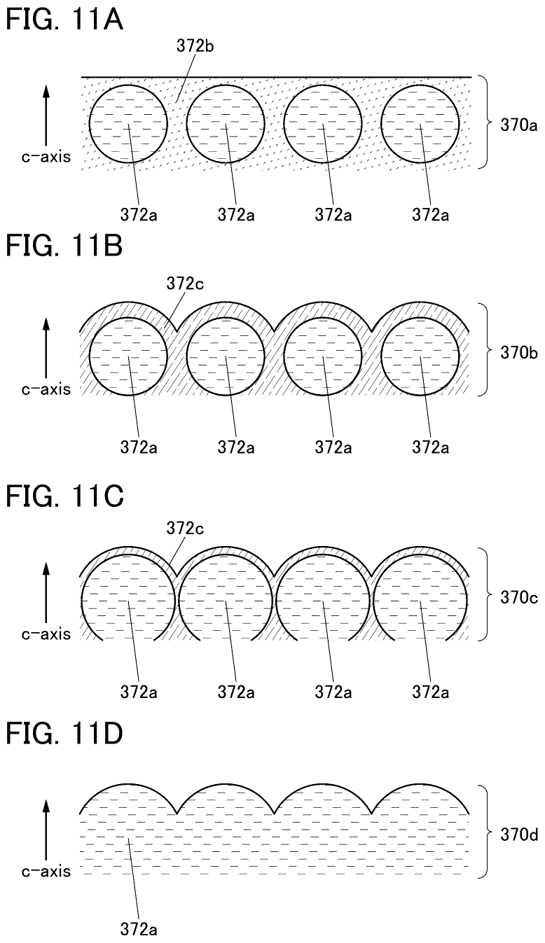

Here, a concept of the heat treatment that increases the crystallinity of an oxide semiconductor layer will be described with reference to FIGS. 11A to 11D. Note that FIGS. 11A to 11D are conceptual diagrams each illustrating cross sections of an oxide semiconductor layer having a CAAC structure. In each of the drawings, the c-axis is indicated by an arrow.

An oxide semiconductor layer 370a illustrated in FIG. 11A includes regions 372a and a region 372b positioned between the regions 372a. The regions 372a each correspond to a region having a CAAC structure (i.e., a structure including a layered crystal part), and the region 372b corresponds to a region between the CAAC structures. The CAAC structure has fewer crystal grain boundaries in the a-b plane than the polycrystalline structure. As described above, even in the oxide semiconductor layer 370a having the CAAC structure, a minute gap or a minute space (the region 372b in FIG. 11A) can exist between crystal parts, in some cases.

In view of the above, in order to increase the crystallinity of an oxide semiconductor layer, that is, in order to reduce the region 372b illustrated in FIG. 11A, after an oxide semiconductor layer having a CAAC structure is formed by a sputtering method as the first oxide semiconductor layer, an oxide semiconductor layer having a microcrystalline or an amorphous structure with lower crystallinity than the CAAC structure is formed by an ALD method as the second oxide semiconductor layer.

Specifically, as illustrated in FIG. 11B, after an oxide semiconductor layer including the regions 372a is formed by a sputtering method as the first oxide semiconductor layer, an oxide semiconductor layer including a region 372c having lower crystallinity than the CAAC structure is formed by an ALD method as the second oxide semiconductor layer. In FIG. 11B, an oxide semiconductor layer 370b includes the regions 372a and the region 372c. Since atomic layers can be deposited one by one by an ALD method, the second oxide semiconductor layer can be formed so as to fill the region 372b.

Then, heat treatment is performed, whereby the regions 372a included in the first oxide semiconductor layer serve as seeds and the crystallinity of the region 372c included in the second oxide semiconductor layer is increased. In other words, the regions 372a included in the first oxide semiconductor layer can serve as seeds in crystal growth of the region 372c included in the second oxide semiconductor layer. Alternatively, the regions 372a of the first oxide semiconductor layer having the CAAC structure can serve as nuclei in crystal growth of the region 372c included in the second oxide semiconductor layer having the amorphous structure. The model of this crystal growth can be understood through a concept similar to that of hetero epitaxy. In FIG. 11C, an oxide semiconductor layer 370c includes the regions 372a and the region 372c. The regions 372a illustrated in FIG. 11C are each a region with higher crystallinity or higher density of crystal parts than the regions 372a illustrated in FIG. 11B. By the heat treatment, the crystallinity of one or both of the regions 372a and the region 372c can be increased. The region 372c includes a crystal part having a crystal structure similar to that of the crystal part included in the regions 372a, for example. Alternatively, the region 372c includes a crystal part that is connected with the crystal part included in the region 372a, for example.

In FIG. 11D, an oxide semiconductor layer 370d includes the region 372a. The region 372a is a region having further higher crystallinity than the regions 372a illustrated in FIGS. 11B and 11C, where there is no boundary between the region 372a and the region 372c or a boundary is not observed between the region 372a and the region 372c. Thus, the whole oxide semiconductor layer 370d has a CAAC structure. When the whole oxide semiconductor layer 370d has a CAAC structure as illustrated in FIG. 11D, a highly reliable semiconductor device can be achieved. Whether there is the boundary between the region 372a and the region 372c can be examined with a cross-sectional TEM, a cross-sectional STEM, or the like, for example.

Even in the case where a minute gap or a minute space is included in the first oxide semiconductor layer, depositing the second oxide semiconductor layer over the first oxide semiconductor layer or depositing the second oxide semiconductor layer over the first oxide semiconductor layer and performing heat treatment can fill the minute gap or the minute space in the first oxide semiconductor layer. When an oxide semiconductor layer having a CAAC structure is used as the first oxide semiconductor layer and an oxide semiconductor layer having a microcrystalline or amorphous structure is used as the second oxide semiconductor layer in this manner, a dense oxide semiconductor layer with increased crystallinity can be provided. When the dense oxide semiconductor layer with increased crystallinity is used in a channel formation region of a transistor, an increase in electric resistance of the oxide semiconductor layer can be inhibited or initial characteristics (particularly on-state current) of the transistor can be improved; thus, a transistor suitable for high-speed operation can be expected.

In the case where an oxide semiconductor layer is formed by both a sputtering method and an ALD method and the oxide semiconductor layer formed by an ALD method is thin, the obtained oxide semiconductor layer can be regarded as not a stacked-layer structure of the oxide semiconductor layer formed by a sputtering method and the oxide semiconductor layer formed by an ALD method, but an oxide semiconductor layer having a single-layer structure. For example, when the thickness of the oxide semiconductor layer formed by an ALD method is greater than 0 nm and less than or equal to 3 nm, preferably greater than 0 nm and less than or equal to 2 nm, further preferably greater than 0 nm and less than or equal to 1 nm, the oxide semiconductor layer formed by two kinds of deposition methods, which are a sputtering method and an ALD method, can be regarded as having a single-layer structure. In such a case, for example, a boundary between the oxide semiconductor layer formed by a sputtering method and the oxide semiconductor layer formed by an ALD method is not observed in a cross-sectional TEM image, a cross-sectional STEM image, or the like. However, when the thickness of the oxide semiconductor layer formed by an ALD method exceeds 3 nm, the oxide semiconductor layer can be regarded as having a stacked-layer structure, a multilayer structure, or a multi-structure of the oxide semiconductor layer formed by a sputtering method and the oxide semiconductor layer formed by an ALD method, in some cases.

In the case where the oxide semiconductor layer is formed by both a sputtering method and an ALD method, the metal oxide formed by a sputtering method and the metal oxide formed by an ALD method preferably have different compositions from each other. Typically, a metal oxide having an atomic ratio of In:Ga:Zn=1:1:1 or a composition in the neighborhood thereof can be deposited by a sputtering method, and then a metal oxide having an atomic ratio of In:Ga:Zn=4:0.1:1 or a composition in the neighborhood thereof can be deposited by an ALD method. The oxide semiconductor layer having the above compositions forms a structure having high reliability owing to the metal oxide having an atomic ratio of In:Ga:Zn=1:1:1 or a composition in the neighborhood thereof and having high on-state current or high field-effect mobility owing to the metal oxide having an atomic ratio of In:Ga:Zn=4:0.1:1 or a composition in the neighborhood thereof. Instead of the metal oxide having an atomic ratio of In:Ga:Zn=4:0.1:1 or a composition in the neighborhood thereof, a metal oxide having an atomic ratio of In:Ga:Zn=1:0:0, that is, indium oxide or a metal oxide with a high In proportion can be used.

The oxide semiconductor layer formed by the two kinds of deposition methods can be regarded as having a structure where a space between crystal parts of the CAAC structure is filled with an atomic layer formed by an ALD method. Note that this structure can be analyzed by analysis methods such as a cross-sectional SEM, a cross-sectional STEM, a cross-sectional TEM, SIMS, and EDX.

The oxide semiconductor layer having the CAAC structure formed by the two kinds of deposition methods sometimes has one or more of a higher dielectric constant, higher film density, and higher film hardness than the oxide semiconductor layer having the CAAC structure formed by one kind of deposition method. With the use of the oxide semiconductor layer having the CAAC structure formed by two kinds of deposition methods for a channel formation region of a transistor as described above, the transistor can have excellent characteristics (e.g., a high on-state current, high field-effect mobility, a low S value, high frequency characteristics (also referred to as f characteristics), or high reliability).

Hydrogen contained in the oxide semiconductor reacts with oxygen bonded to a metal atom to be water, and thus sometimes forms an oxygen vacancy (Vₒ) in the oxide semiconductor. A defect where hydrogen enters an oxygen vacancy (hereinafter, referred to as VoH) serves as a donor and generates an electron serving as a carrier in some cases. In other cases, bonding of part of hydrogen to oxygen bonded to a metal atom generates an electron serving as a carrier. Thus, a transistor including an oxide semiconductor that contains a large amount of hydrogen is likely to have normally-on characteristics (that is, the threshold voltage is likely to be a negative value). Moreover, hydrogen in an oxide semiconductor is easily transferred by a stress such as heat or an electric field; thus, a large amount of hydrogen in an oxide semiconductor might degrade the reliability of a transistor.

Accordingly, the amount of VoH in the oxide semiconductor layer 230 is preferably reduced as much as possible so that the oxide semiconductor layer 230 becomes a highly purified intrinsic or substantially highly purified intrinsic oxide semiconductor. In sufficiently reducing the amount of VoH in an oxide semiconductor, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

The carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. The minimum carrier density of an oxide semiconductor in the region functioning as the channel formation region is not limited and can be 1×10⁻⁹ cm⁻³, for example.

The influence of impurities in the metal oxide (oxide semiconductor) will be described here.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

Note that for the semiconductor device of this embodiment, a transistor containing another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used as a semiconductor material of a transistor include single crystal silicon, polycrystalline silicon, microcrystalline silicon, and amorphous silicon. An example of polycrystalline silicon is low-temperature polysilicon (LTPS).

Alternatively, a semiconductor layer of a transistor may include a layered material functioning as a semiconductor. The layered material generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include the above semiconductor substrates provided with an insulator region, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

### <Method 1 for Manufacturing Semiconductor Device>

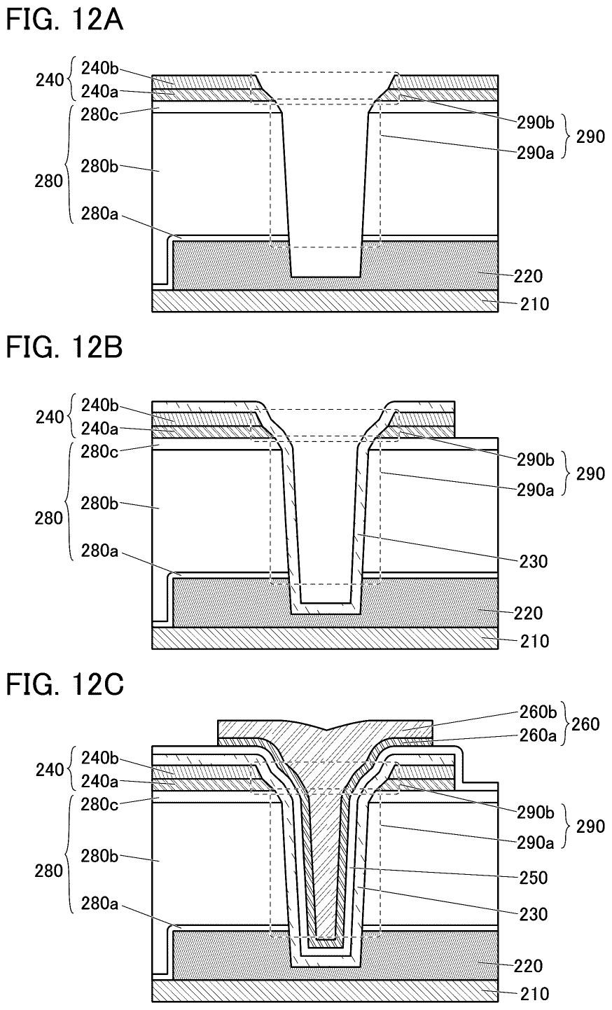

A method for manufacturing a semiconductor device is described with reference to FIGS. 12A to 12C. Here, a method for manufacturing the structure illustrated in FIG. 7A is described as an example. Note that as for a material and a formation method of each component, portions similar to those described above are not described in some cases.

Thin films included in the semiconductor device (e.g., insulating films, semiconductor films, and conductive films) can be formed by a sputtering method, a CVD method, a vacuum evaporation method, a PLD method, an ALD method, or the like.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. Furthermore, an RF superimposed DC sputtering method can be given. For deposition using an insulating target, an RF sputtering method is preferably used. A DC sputtering method is used mainly in the case of deposition using a conductive target. In a DC sputtering method, not only formation of a conductive film but also formation of an insulating film is possible when reactive sputtering is performed. The pulsed DC sputtering method is mainly used in the case where a compound such as an oxide, a nitride, or a carbide is deposited by a reactive sputtering method. In an RF superimposed DC sputtering method, the ion energy and the potential on the target side can be controlled during deposition. Thus, deposition-induced damage can be reduced as compared with that in the case of an RF sputtering method. Moreover, a high-quality film can be obtained.

As a sputtering method, for example, an ionization sputtering method, a long throw sputtering method, or the like can be used. The ionization sputtering method is a method in which a sputtering particle generated from a target is ionized by RF or the like and deposited with anisotropy by a self bias or the like. In the long throw sputtering method, the distance between a sputtering target and a substrate is long to enable deposition with anisotropy.

Note that CVD methods can be classified into a PECVD method, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a PECVD method. A thermal CVD method does not use plasma and thus causes less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during deposition.

As the ALD method, a thermal ALD method, in which a precursor and a reactant react with each other only by a thermal energy, a plasma-enhanced ALD (PEALD) method, in which a reactant excited by plasma is used, and the like can be used.

An ALD method enables a single atomic layer to be deposited at a time, and has various advantages such as deposition of an extremely thin film, deposition on a component with a high aspect ratio, deposition of a film with a small number of defects such as pinholes, deposition with excellent coverage, and low-temperature deposition. In the plasma-enhanced ALD (PEALD) method, the use of plasma is sometimes preferable for lower-temperature deposition. Note that a precursor used in the ALD method sometimes contains impurities such as carbon. Thus, a film formed by the ALD method may contain impurities such as carbon in a larger amount than a film formed by another film formation method. Note that impurities can be quantified by X-ray photoelectron spectroscopy (XPS).

Unlike in the film formation method in which particles ejected from a target or the like are deposited, a film is formed by reaction at a surface of an object in a CVD method and an ALD method. Thus, a CVD method and an ALD method can provide good step coverage, almost regardless of the shape of an object. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another deposition method with a high deposition rate, such as a CVD method.

When a CVD method or an ALD method is employed, the composition of a film can be controlled with the flow rate ratio of the source gases. For example, in a CVD method and an ALD method, a film with a certain composition can be formed by adjusting the flow rate ratio of the source gases. As another example, in a CVD method and an ALD method, by changing the flow rate ratio of the source gases during the film deposition, a film whose composition is continuously changed can be formed. In the case where a film is deposited while the flow rate ratio of the source gases is changed, as compared to the case where a film is deposited using a plurality of deposition chambers, the time taken for the deposition can be shortened because the time taken for transfer and pressure adjustment is omitted. Hence, the productivity of the semiconductor device can be improved in some cases.

By a CVD method, a film with a certain composition can be deposited by adjusting the flow rate ratio of the source gases. For example, a CVD method enables a film with a gradually-changed composition to be deposited by changing the flow rate ratio of the source gases during deposition. In the case where a film is deposited while the flow rate ratio of the source gases is changed, as compared to the case where a film is deposited using a plurality of deposition chambers, the time taken for the deposition can be shortened because the time taken for transfer and pressure adjustment is omitted. Hence, the productivity of the semiconductor device can be improved in some cases.

An ALD method, with which a plurality of different kinds of precursors are introduced at a time, enables deposition of a film with desired composition. In the case where a plurality of different kinds of precursors are introduced, the cycle number of precursor deposition is controlled, whereby a film with desired composition can be deposited.

Thin films included in the semiconductor device (e.g., insulating films, semiconductor films, and conductive films) can be formed by a wet process such as spin coating, dipping, spray coating, ink-jetting, dispensing, screen printing, offset printing, doctor blade coating, slit coating, roll coating, curtain coating, or knife coating.

In processing a thin film included in the semiconductor device, a photolithography method or the like can be employed. Alternatively, the thin film may be processed by a nanoimprinting method, a sandblasting method, a lift-off method, or the like. Alternatively, an island-shaped thin film may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which any of the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV, X-rays, or an electron beam to perform extremely fine processing. Note that a photomask is not needed when light exposure is performed by scanning with a beam such as an electron beam.

For etching of a thin film, a dry etching method, a wet etching method, a sandblast method, or the like can be used.

First, the conductive layer 220 is formed over the insulating layer 210, the insulating layer 280 is formed over the conductive layer 220, and the conductive layer 240 is formed over the insulating layer 280. Here, the insulating layer 280 has a three-layer stacked structure of the insulating layer 280a, the insulating layer 280b, and the insulating layer 280c.

Note that it is preferable that the top surface of the deposited insulating layer 280 be planarized by planarization treatment by a chemical mechanical polishing (CMP) method (also referred to as CMP treatment). By the planarization treatment of the insulating layer 280, the formation surface of the conductive layer 240 functioning as a wiring can be made flat, whereby disconnection of the conductive layer 240 can be inhibited. Note that the planarization treatment is not necessarily performed, in which case the manufacturing cost can be reduced.

Next, the opening portion 290 is formed in the conductive layer 240 and the insulating layer 280 at a position overlapping with the conductive layer 220 (FIG. 12A). At this time, a depressed portion is formed in the conductive layer 220 at a position overlapping with the opening portion 290.

Since the opening portion 290 has a high aspect ratio, part of the conductive layer 240 and part of the insulating layer 280 are preferably processed by anisotropic etching. It is particularly preferable to use a dry etching method because it is suitable for microfabrication. The processing may be performed on the layers under different conditions.

Here, processing conditions which make the sidewalls of the conductive layer 240 and the insulating layer 280c have tapered shapes are preferably used. Furthermore, processing conditions which make the sidewall of the insulating layer 280b have a steep shape are preferably used.

The insulating layer 280a may be formed under processing conditions which make the sidewall of the insulating layer 280a have a tapered shape or processing conditions which make the sidewall of the insulating layer 280a have a steep shape.

Here, when the material of the insulating layer 280c and the material of the insulating layer 280b are appropriately selected, the insulating layer 280c and the insulating layer 280b can be formed into a tapered shape and a steep shape, respectively, by dry etching under the same conditions.

Next, heat treatment may be performed. The heat treatment is performed, for example, at a temperature higher than or equal to 250° C. and lower than or equal to 650° C., preferably higher than or equal to 300° C. and lower than or equal to 500° C., further preferably higher than or equal to 320° C. and lower than or equal to 450° C.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as water contained in the insulating layer 280, for example, can be reduced before the oxide semiconductor layer 230 is deposited.

The gas used in the above heat treatment preferably has high purity. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the insulating layer 280 as much as possible.

An opening may be formed in the conductive layer 240 and the insulating layer 280 using the same mask or different masks.

Next, the oxide semiconductor layer 230 is formed to cover the opening portion 290. The oxide semiconductor layer 230 is formed in contact with the top surface of the conductive layer 220, the side surface of the insulating layer 280, and the top surface and the side surface of the conductive layer 240.

The oxide semiconductor layer 230 can be formed by a sputtering method, a CVD method, an MBE method, a PLD method, or an ALD method, for example.

The formed oxide semiconductor layer 230 is preferably a film having as uniform thickness as possible along the top surface of the conductive layer 220, the side surface of the insulating layer 280, and the side surface of the conductive layer 240, inside the opening portion 290. The use of an ALD method allows formation of a thin film with good controllability. Therefore, the oxide semiconductor layer 230 is preferably formed by an ALD method.

In addition, when the oxide semiconductor layer 230 has high crystallinity, diffusion of impurities in the oxide semiconductor layer 230 is inhibited, leading to a small variation in electrical characteristics and high reliability of the transistor. The oxide semiconductor layer 230 is preferably formed by a sputtering method, in which case a layer with high crystallinity can be obtained easily as compared with the case of using an ALD method.

In the case where the oxide semiconductor layer 230 is deposited by a sputtering method, oxygen or a mixed gas of oxygen and a noble gas is used as a sputtering gas. An increase in the proportion of oxygen in the sputtering gas can increase the amount of excess oxygen contained in the oxide film to be deposited. Moreover, when the oxide film is formed by a sputtering method, a target of the In-M-Zn oxide can be used, for example.

When the oxide semiconductor layer 230 is deposited by a sputtering method and the proportion of oxygen in the sputtering gas is higher than 30% and lower than or equal to 100%, preferably higher than or equal to 70% and lower than or equal to 100%, an oxygen-excess oxide semiconductor is formed. A transistor including an oxygen-excess oxide semiconductor in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in a channel formation region can have relatively high field-effect mobility. In addition, when the oxide semiconductor layer is deposited while the substrate is being heated, the crystallinity of the oxide semiconductor layer can be improved.

Next, the conductive layer 240 and the oxide semiconductor layer 230 are processed into island shapes (FIG. 12B). Here, the conductive layer 240 and the oxide semiconductor layer 230 can be processed collectively with the use of the same mask.

Note that the step of processing the conductive layer 240 into an island shape and the step of processing the oxide semiconductor layer 230 into an island shape may be performed independently of each other. In this case, for example, the step of processing the conductive layer 240 into an island shape and the step of providing the opening portion 290 in the conductive layer 240 can be performed independently of each other, in which case, either of the steps may be performed first. Alternatively, after light exposure using a mask for processing into a quadrangular island shape and light exposure using a mask for providing a circular opening portion are performed, etching may be performed to collectively perform processing into the island shape and formation of the opening portion. Exposure using a multi-tone mask (typically a half-tone mask or a gray-tone mask) may be used.

Next, the insulating layer 250 is formed over the oxide semiconductor layer 230 and the insulating layer 280. The insulating layer 250 is formed in contact with the oxide semiconductor layer 230.

Next, heat treatment is preferably performed. The heat treatment is preferably performed in a temperature range where the oxide semiconductor layer 230 does not become polycrystal. The heat treatment temperature is preferably higher than or equal to 100° C. and lower than or equal to 650° C., further preferably higher than or equal to 250° C. and lower than or equal to 600° C., still further preferably higher than or equal to 350° C. and lower than or equal to 550° C. For the details of the heat treatment, the above description can be referred to.

The gas used in the above heat treatment preferably has high purity. The heat treatment using a highly purified gas can prevent the entry of moisture or the like into the oxide semiconductor layer 230 as much as possible.

In this embodiment, heat treatment is performed at 450° C. for an hour at a flow rate ratio of a nitrogen gas to an oxygen gas of 4:1. With the heat treatment using the above-described oxygen gas, impurities such as carbon, water, and hydrogen in the oxide semiconductor layer 230 can be reduced. Impurities in the film are reduced in the above manner, whereby the crystallinity of the oxide semiconductor layer 230 can be improved and a dense structure can be obtained. Accordingly, the crystal region in the oxide semiconductor layer 230 can be increased, and an in-plane variation in the oxide semiconductor layer 230 can be reduced. Thus, an in-plane variation in electrical characteristics of the transistor can be reduced.

In the case where the insulating layer 280 contains oxygen, oxygen is preferably supplied from the insulating layer 280 to the channel formation region of the oxide semiconductor layer 230 by the heat treatment. Accordingly, oxygen vacancies and VoH can be reduced.

Next, a conductive layer to be the conductive layer 260a is formed over the insulating layer 250. The conductive layer to be the conductive layer 260a is formed to cover the top surface of the conductive layer 220, the side surface of the insulating layer 280, and the top and side surfaces of the conductive layer 240 with the oxide semiconductor layer 230 and the insulating layer 250 therebetween. Next, a conductive layer to be the conductive layer 260b is formed.

The conductive layer 260a and the conductive layer 260b are formed in contact with the insulating layer 250 provided in the opening portion 290 with a high aspect ratio. Thus, the conductive layer to be the conductive layer 260a and the conductive layer to be the conductive layer 260b are each preferably formed by a deposition method with favorable coverage, further preferably formed by an ALD method, a metal CVD method, or the like.

Next, part of the conductive layer to be the conductive layer 260b and part of the conductive layer to be the conductive layer 260a are removed using a mask, whereby the conductive layer 260b and the conductive layer 260a are formed (FIG. 12C).

Through the above steps, the semiconductor device of one embodiment of the present invention can be manufactured.

### <Method 2 for Manufacturing Semiconductor Device>

An example of a method for manufacturing the semiconductor device illustrated in FIG. 10B is described below.

First, the structure illustrated in FIG. 12B is manufactured. Next, a dummy structure is formed in a region where the insulating layer 250 and the conductive layer 260 are provided. Then, the insulating layer 283 and the insulating layer 285 are formed outside the dummy structure.

Then, the dummy structure is removed to form the insulating layer 250 and the conductive layer 260.

Next, the conductive layer 265 is formed over the conductive layer 260 and the insulating layer 285.

Through the above steps, the semiconductor device illustrated in FIG. 10B can be manufactured. Note that the method for manufacturing the semiconductor device illustrated in FIG. 10B is not limited to that described here.

This embodiment can be combined with any of the other embodiments as appropriate. In this specification, in the case where a plurality of structure examples are shown in one embodiment, the structure examples can be combined as appropriate.

### Embodiment 2

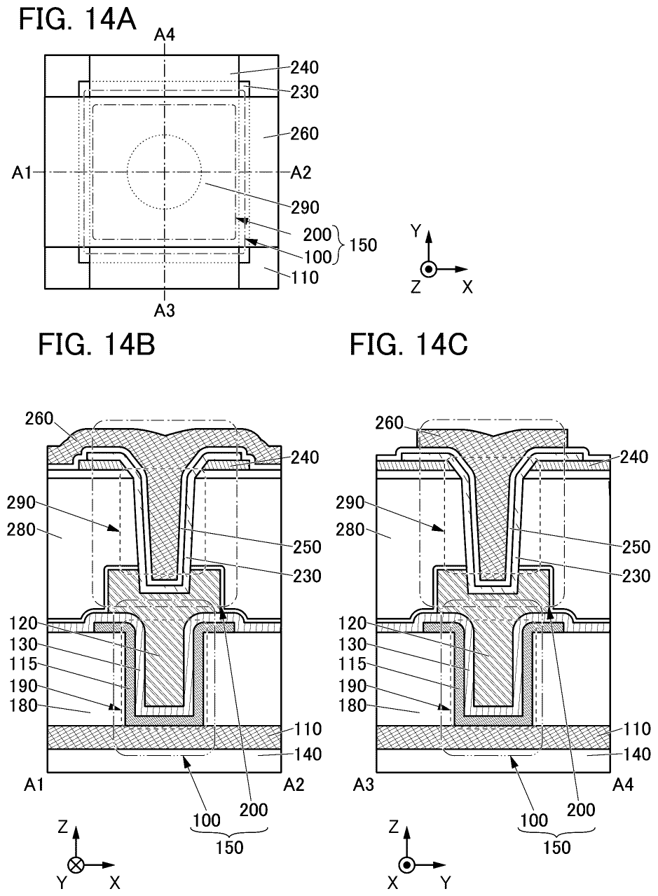

In this embodiment, memory devices of one embodiment of the present invention will be described with reference to FIGS. 14A to 14C, FIGS. 15A and 15B, FIG. 16, and FIG. 17. The memory device of one embodiment of the present invention includes a memory cell. The memory cell includes a transistor and a capacitor.

### Structure Example 1 of Memory Device

A structure of a memory device including a transistor and a capacitor is described with reference to FIGS. 14A to 14C. FIG. 14A is a plan view of a memory device including the transistor 200 and a capacitor 100. FIG. 14B is a cross-sectional view taken along dashed-dotted line A1-A2 in FIG. 14A. FIG. 14C is a cross-sectional view taken along dashed-dotted line A3-A4 in FIG. 14A.

The memory device illustrated in FIGS. 14A to 14C includes an insulating layer 140 over a substrate (not illustrated), a conductive layer 110 over the insulating layer 140, a memory cell 150 over the conductive layer 110, an insulating layer 180 over the conductive layer 110, the insulating layer 280, the insulating layer 283 over the memory cell 150. The insulating layer 140, the insulating layer 180, the insulating layer 280, and the insulating layer 283 function as interlayer films. The conductive layer 110 functions as a wiring.

The memory cell 150 includes the capacitor 100 over the conductive layer 110 and the transistor 200 over the capacitor 100.

The capacitor 100 includes a conductive layer 115 over the conductive layer 110, an insulating layer 130 over the conductive layer 115, and a conductive layer 120 over the insulating layer 130. The conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (MIM) capacitor.

As illustrated in FIGS. 14B and 14C, the opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. The insulating layer 130 is placed so that at least part of the insulating layer 130 is positioned in the opening portion 190. The conductive layer 120 is placed so that at least part of the conductive layer 120 is positioned in the opening portion 190. Note that the conductive layer 120 is preferably provided to fill the opening portion 190 as illustrated in FIGS. 14B and 14C. Note that the films provided inside the opening portion 190 are preferably formed by a method enabling high coverage, such as an ALD method. Thus, the coverage with the films can be improved. For example, the conductive layer 115, the insulating layer 130, and the conductive layer 120 are preferably formed by an ALD method, a metal CVD method, or the like.

The upper electrode and the lower electrode of the capacitor 100 face each other with the dielectric therebetween, along the side surface of the opening portion 190 as well as the bottom surface thereof; thus, the capacitance per unit area can be larger. Accordingly, the deeper the opening portion 190 is, the larger the capacitance of the capacitor 100 can be. Increasing the capacitance per unit area of the capacitor 100 in this manner allows stable reading operation of the memory device. This also allows further miniaturization or high integration of the memory device.

FIGS. 14B and 14C illustrate an example where the sidewall of the opening portion 190 is perpendicular to the top surface of the conductive layer 110. At this time, the opening portion 190 has a cylindrical shape. Such a structure enables miniaturization or high integration of the memory device.

The conductive layer 115 and the insulating layer 130 are stacked along the sidewall of the opening portion 190 and the top surface of the conductive layer 110. The conductive layer 120 is provided over the insulating layer 130 to fill the opening portion 190. The capacitor 100 having such a structure may be referred to as a trench-type capacitor or a trench capacitor.

The insulating layer 280 is provided over the capacitor 100. That is, the insulating layer 280 is positioned over the conductive layer 115, the insulating layer 130, and the conductive layer 120. In other words, the conductive layer 120 is positioned under the insulating layer 280.

The transistor 200 includes the conductive layer 120 (corresponding to the conductive layer 220 in FIG. 2B or the like), the conductive layer 240 over the insulating layer 280, the oxide semiconductor layer 230, the insulating layer 250 over the oxide semiconductor layer 230, and the conductive layer 260 over the insulating layer 250. The oxide semiconductor layer 230 functions as the semiconductor layer, the conductive layer 260 functions as the gate electrode, the insulating layer 250 functions as the gate insulating layer, the conductive layer 120 functions as one of the source electrode and the drain electrode, and the conductive layer 240 functions as the other of the source electrode and the drain electrode.

The description in Embodiment 1 (FIGS. 2A to 2C, FIGS. 3A to 3D, or the like) can be referred to for the transistor 200; thus, the detailed description thereof is omitted. The transistor included in the memory cell 150 is not limited to the transistor 200 in FIGS. 2A to 2C, FIGS. 3A to 3D, or the like, and any of the transistors described as examples in Embodiment 1 can be used.

As illustrated in FIGS. 14A to 14C, the transistor 200 is provided to overlap with the capacitor 100. The opening portion 290 where part of the components of the transistor 200 is provided includes a region overlapping with the opening portion 190 where part of the components of the capacitor 100 is provided. In particular, since the conductive layer 120 has a function of one of the source electrode and the drain electrode of the transistor 200 and a function of the upper electrode of the capacitor 100, the transistor 200 and the capacitor 100 share part of the structure. With such a structure, the transistor 200 and the capacitor 100 can be provided without an increase in the area in a plan view. Thus, the area of the memory cell 150 can be reduced, so that the memory cells 150 can be arranged densely and the storage capacity of the memory device can be increased. In other words, the memory device can be highly integrated.

When the transistor 200 is provided above the capacitor 100, the transistor 200 is not affected by heat treatment in manufacturing the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

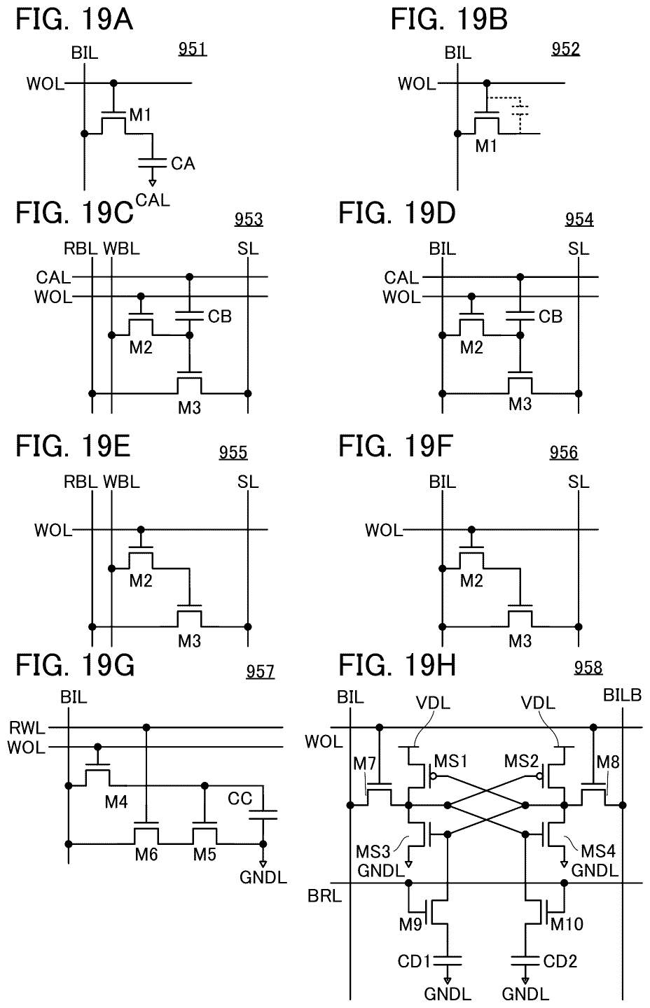

FIG. 19A is a circuit diagram of the memory device described in this embodiment. As illustrated in FIG. 19A, the structure illustrated in FIGS. 14A to 14C functions as a memory cell. A memory cell 951 includes a transistor M1 and a capacitor CA. Here, the transistor M1 corresponds to the transistor 200, and the capacitor CA corresponds to the capacitor 100.

One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 260, and the wiring CAL corresponds to the conductive layer 110. As illustrated in FIGS. 14A to 14C, it is preferable that the conductive layer 260 be provided to extend in the X direction and the conductive layer 240 be provided to extend in the Y direction. With such a structure, the wiring BIL and the wiring WOL are provided to intersect with each other. Although the wiring CAL (the conductive layer 110) is provided in a plane shape in FIG. 14A, the present invention is not limited thereto. For example, the wiring CAL may be provided parallel to the wiring WOL (the conductive layer 260) or the wiring BIL (the conductive layer 240).

Note that the memory cell will be described in detail in a later embodiment.

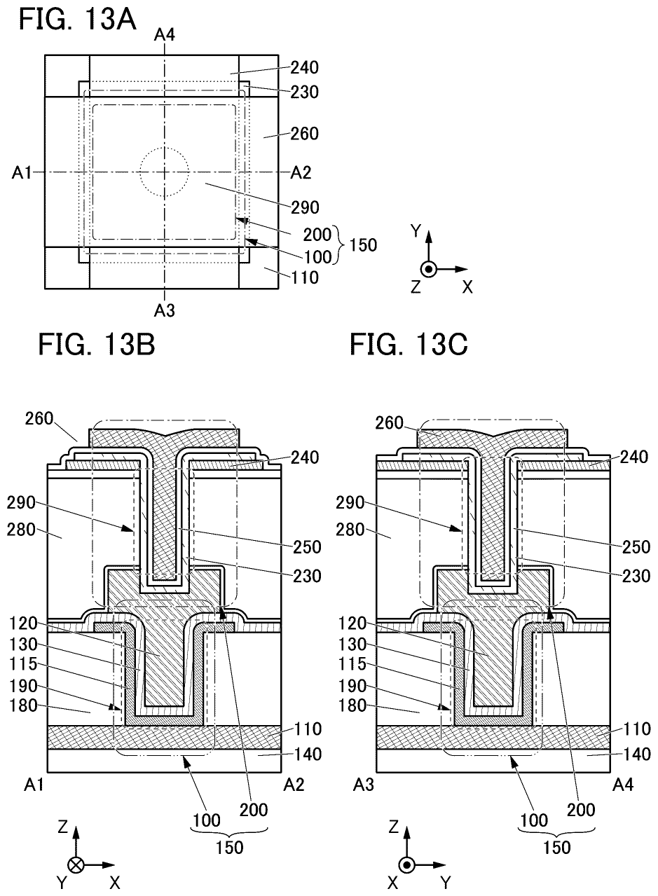

FIGS. 13A to 13C illustrate an example in which the structure illustrated in FIGS. 1A to 1C is used as the structure of the transistor 200 in FIGS. 14A to 14C.

### [Capacitor 100]

The capacitor 100 includes the conductive layer 115, the insulating layer 130, and the conductive layer 120. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL and can be provided in a plane shape, for example. The conductive layer 110 can be formed as a single layer or stacked layers using the conductive material described in [Conductive layer] in Embodiment 1. For example, a conductive material with high conductivity such as tungsten can be used for the conductive layer 110. With the use of a conductive material with high conductivity, the conductivity of the conductive layer 110 can be improved and the wiring CAL can function sufficiently.

For the conductive layer 115, a single layer or stacked layers of a conductive material that is less likely to be oxidized, a conductive material having a function of inhibiting diffusion of oxygen, or the like is preferably used. For example, titanium nitride, indium tin oxide to which silicon is added, or the like may be used. Alternatively, a structure where titanium nitride is stacked over tungsten may be used, for example. Alternatively, a structure where tungsten is stacked over first titanium nitride and second titanium nitride is stacked over the tungsten may be used, for example. With such a structure, when an oxide is used for the insulating layer 130, the conductive layer 110 can be inhibited from being oxidized by the insulating layer 130. When an oxide is used for the insulating layer 180, the conductive layer 110 can be inhibited from being oxidized by the insulating layer 180.

The insulating layer 130 is provided over the conductive layer 115. The insulating layer 130 can be provided to be in contact with the top and side surfaces of the conductive layer 115. That is, the insulating layer 130 preferably covers the side end portion of the conductive layer 110. This can prevent a short circuit between the conductive layer 115 and the conductive layer 120.

Alternatively, the side end portion of the insulating layer 130 and the side end portion of the conductive layer 115 may be aligned with each other. With such a structure, the insulating layer 130 and the conductive layer 115 can be formed using the same mask, so that the manufacturing process of the memory device can be simplified.

For the insulating layer 130, a material with a high dielectric constant (a high-k material) is preferably used. Using such a high-k material for the insulating layer 130 allows the insulating layer 130 to be thick enough to inhibit a leakage current and the capacitor 100 to have a sufficiently high capacitance.

The insulating layer 130 preferably has a stacked-layer structure using an insulating layer that contains a high-k material. A stacked-layer structure containing a material with a high dielectric constant (a high-k material) and a material with higher dielectric strength than the high-k material is preferably used. For example, as the insulating layer 130, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Alternatively, a material that can have ferroelectricity may be used for the insulating layer 130. Description in Embodiment 1 can also be referred to for the details of the material that can have ferroelectricity.

A metal oxide containing one or both of hafnium and zirconium is preferable as the insulating layer 130 because the metal oxide can have ferroelectricity even when being a thin film of several nanometers. The thickness of the insulating layer 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). For example, the thickness is preferably greater than or equal to 8 nm and less than or equal to 12 nm. With the use of the ferroelectric layer that can have a small thickness, the capacitor 100 can be combined with a miniaturized semiconductor element such as a transistor to fabricate a semiconductor device.

A metal oxide containing one or both of hafnium and zirconium is preferable as the insulating layer 130 because the metal oxide can have ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even with an area of less than or equal to 10000 nm² or less than or equal to 1000 nm², a ferroelectric layer can have ferroelectricity in some cases. With a small-area ferroelectric layer, the area occupied by the capacitor 100 can be reduced.

The ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 120 is provided in contact with part of the top surface of the insulating layer 130. The side end portion of the conductive layer 120 is preferably positioned inside the side end portion of the conductive layer 115 in both the X direction and the Y direction. Note that in the structure where the insulating layer 130 covers the side end portion of the conductive layer 115, the side end portion of the conductive layer 120 may be positioned outside the side end portion of the conductive layer 115.

The conductive layer 120 can be formed to have a single-layer structure or a stacked-layer structure using any of the conductive materials described in [Conductive layer] in Embodiment 1. A conductive material that is not easily oxidized, a conductive material having a function of inhibiting diffusion of oxygen, or the like is preferably used for the conductive layer 120. For example, titanium nitride, tantalum nitride, or the like can be used. For example, a structure in which tantalum nitride is stacked over titanium nitride may be used. In that case, titanium nitride is in contact with the insulating layer 130 and tantalum nitride is in contact with the oxide semiconductor layer 230. With such a structure, the conductive layer 120 can be inhibited from being excessively oxidized by the oxide semiconductor layer 230. In the case of using an oxide for the insulating layer 130, the conductive layer 120 can be inhibited from being excessively oxidized by the insulating layer 130. Alternatively, the conductive layer 120 may have a structure in which tungsten is stacked over titanium nitride, for example.

The conductive layer 120 includes a region in contact with the oxide semiconductor layer 230 and thus is preferably formed using a conductive material containing oxygen. When a conductive material containing oxygen is used for the conductive layer 120, the conductive layer 120 can maintain its conductivity even when absorbing oxygen. It is also preferable that an insulating layer containing oxygen, such as zirconium oxide, be used as the insulating layer 130 in order that the conductive layer 120 can maintain its conductivity. As the conductive layer 120, a single layer or a stacked layer of ITO, ITSO, IZO (registered trademark), or the like can be used, for example.

The insulating layer 180 functions as an interlayer film and preferably has a low dielectric constant. In the case where a material with a low dielectric constant is used for an interlayer film, the parasitic capacitance between wirings can be reduced. As the insulating layer 180, an insulating layer containing a material with a low dielectric constant can be used as a single layer or stacked layers. Silicon oxide and silicon oxynitride, which have thermal stability, are preferable.

Although the insulating layer 180 has a single-layer structure in FIGS. 14B and 14C, the present invention is not limited thereto. The insulating layer 180 may have a stacked-layer structure of two layers or three or more layers.

### Structure Example 2 of Memory Device

The memory cell 150 including the transistor 200 and the capacitor 100 described in this embodiment can be used as a memory cell of the memory device. The transistor 200 is a transistor whose channel is formed in a semiconductor layer containing an oxide semiconductor. Since the transistor 200 has a low off-state current, a memory device including the transistor 200 can retain stored data for a long time. In other words, such a memory device does not require refresh operation or has an extremely low frequency of refresh operation, leading to a sufficient reduction in power consumption. The transistor 200 has high frequency characteristics and thus enables the memory device to perform reading and writing at high speed.

The memory cells 150 are arranged in a matrix three-dimensionally, whereby a memory cell array can be formed.

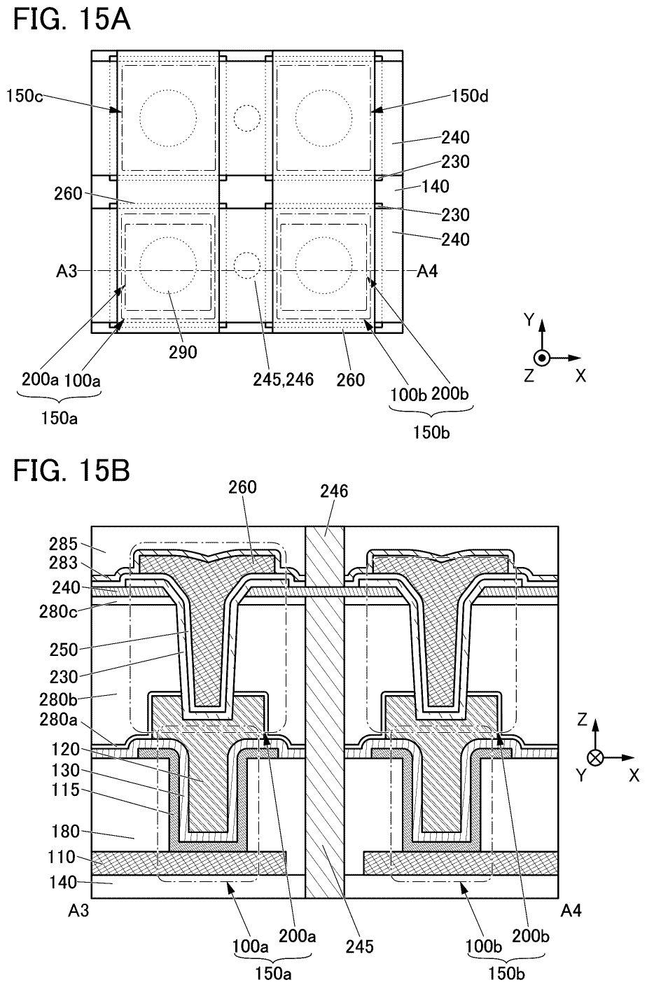

FIG. 15A is a plan view of a memory device. FIG. 15A illustrates an example where 2×2 memory cells (a memory cell 150a to a memory cell 150d) are arranged in the X direction and the Y direction.

FIG. 15B is a cross-sectional view taken along dashed-dotted line A3-A4 in FIG. 15A. In FIGS. 15A and 15B, two memory cells (the memory cells 150a and 150b in FIG. 15B) are connected to a common wiring (a conductive layer 246).

Here, the memory cells 150a and 150b illustrated in FIGS. 15A and 15B each have a structure similar to that of the memory cell 150. The memory cell 150a includes a capacitor 100a and a transistor 200a, and the memory cell 150b includes a capacitor 100b and a transistor 200b. The memory cells 150c and 150d illustrated in FIG. 15A each have a structure similar to that of the memory cell 150. Thus, in the memory device illustrated in FIGS. 15A and 15B, components having the same functions as the components of the memory device illustrated in FIGS. 14A to 14C are denoted by the same reference numerals. The description of the memory cell 150 in <Structure example 1 of memory device> can be referred to for the details of the memory cells 150a to 150d.

As illustrated in FIGS. 15A and 15B, the conductive layer 265 functioning as the wiring WOL is provided in each of the memory cells 150a and 150b. As illustrated in FIG. 15A, one conductive layer 260 is shared by the memory cells 150a and 150c, and another conductive layer 260 is shared by the memory cells 150b and 150d. One conductive layer 240 functioning as part of the wiring BIL is shared by the memory cells 150a and 150b. That is, the conductive layer 240 is in contact with the oxide semiconductor layer 230 of the memory cell 150a and the oxide semiconductor layer 230 of the memory cell 150b. Another conductive layer 240 is shared by the memory cells 150c and 150d.

Here, the memory device illustrated in FIGS. 15A and 15B includes the conductive layers 245 and 246 functioning as plugs (also can be referred to as connection electrodes) electrically connected to the memory cells 150a and 150b. The conductive layer 245 is placed in an opening portion formed in the insulating layers 140, 180, 130, and 280, and is in contact with the bottom surface of the conductive layer 240. The conductive layer 246 is placed in an opening portion formed in the insulating layer 285, the insulating layer 283, and the insulating layer 250, and is in contact with the top surface of the conductive layer 240. Note that a conductive material that can be used for the conductive layer 240, for example, can be used for the conductive layers 245 and 246.

The conductive layers 245 and 246 each function as a plug or a wiring for electrically connecting the memory cells 150a and 150b to a wiring, an electrode, a terminal, or a circuit element such as a switch, a transistor, a capacitor, an inductor, a resistor, or a diode. For example, the conductive layer 245 can be electrically connected to a sense amplifier (not illustrated) provided below the memory device illustrated in FIG. 15B, and the conductive layer 246 can be electrically connected to a similar memory device (not illustrated) provided above the memory device illustrated in FIG. 15B. In this case, the conductive layers 245 and 246 function as part of the wiring BIL. When the memory device or the like is provided above or below the memory device illustrated in FIG. 15B in this manner, the storage capacity per unit area can be increased.

The memory cells 150a and 150b have a line-symmetric structure with a perpendicular bisector of the dashed-dotted line A3-A4 as the symmetric axis. Thus, the transistors 200a and 200b are also placed symmetrically with the conductive layers 245 and 246 therebetween. Note that the conductive layer 240 has a function of the other of the source electrode and the drain electrode of the transistor 200a and a function of the other of the source electrode and the drain electrode of the transistor 200b. The transistors 200a and 200b share the conductive layers 245 and 246 functioning as plugs. With the above connection structure between the two transistors and the plugs, a memory device that can be miniaturized or highly integrated can be provided.

Note that the conductive layer 110 functioning as the wiring CAL may be provided in each of the memory cells 150a and 150b or may be provided in common to the memory cells 150a and 150b. However, as illustrated in FIG. 15B, the conductive layer 110 is provided to be apart from the conductive layer 245 so that the conductive layers 110 and 245 are not short-circuited.

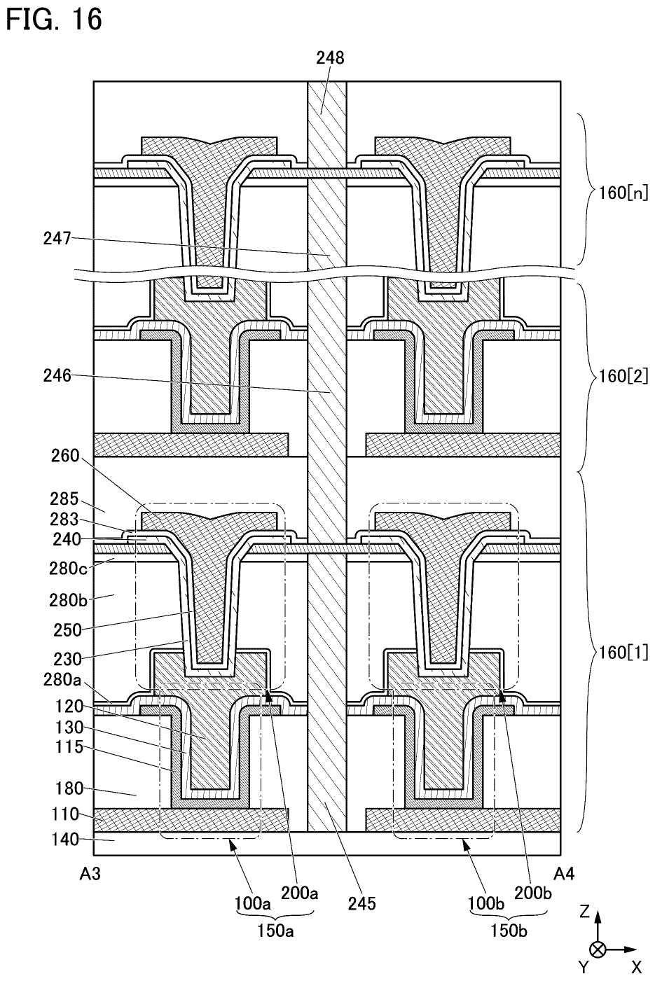

FIG. 16 illustrates an example where four memory cells illustrated in FIG. 15A are stacked in n layers (n is an integer greater than or equal to 3) in the Z direction. FIG. 16 is a cross-sectional view taken along dashed-dotted line A3-A4 in FIG. 15A.

The memory device illustrated in FIG. 16 includes n memory layers 160. Specifically, a memory layer 160[2] is provided over a memory layer 160[1], (n−2) memory layers are provided over the memory layer 160[2], and a memory layer 160[n] is provided in the uppermost stage. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are electrically connected to a sense amplifier (not illustrated) provided below the n memory layers 160.

When a plurality of memory cells are stacked as illustrated in FIG. 16, the cells can be provided in an integrated manner without increasing the area occupied by the memory cell array. That is, a 3D memory cell array can be formed.

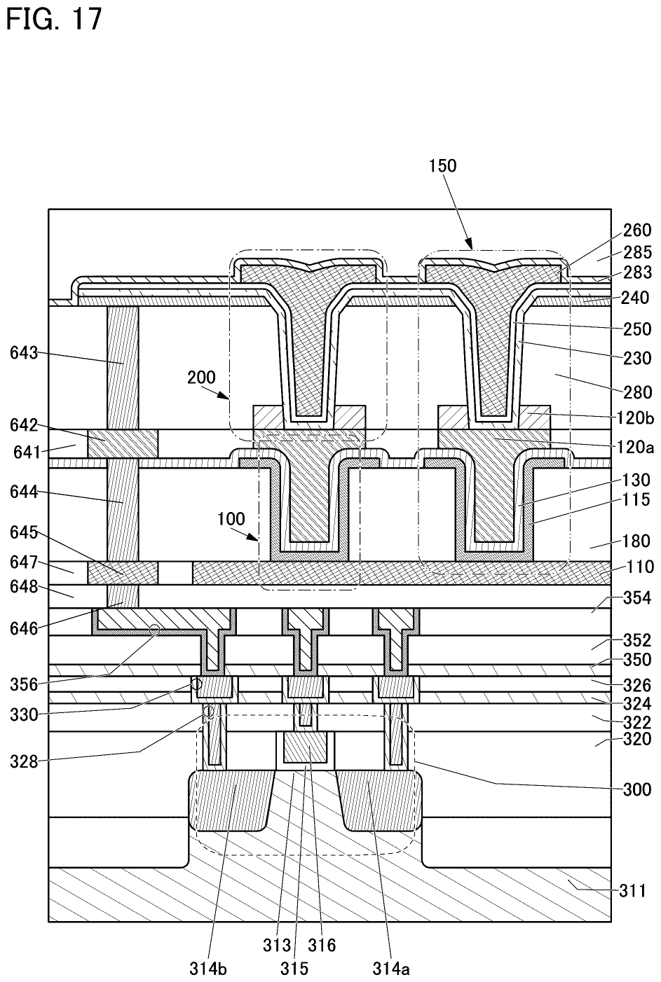

FIG. 17 illustrates a cross-sectional structure example of a memory device in which a layer including a memory cell is stacked over a layer including a driver circuit provided with a sense amplifier.

In FIG. 17, the memory cell 150 (the transistor 200 and the capacitor 100) is provided above a transistor 300.

The transistor 300 is one of the transistors included in the sense amplifier.

For the memory cell 150 illustrated in FIG. 17, the description of the memory cell 150 in <Structure example 1 of memory device> can be referred to. FIG. 17 illustrates an example in which the capacitor 100 includes, instead of the conductive layer 120, a conductive layer 120a and a conductive layer 120b over the conductive layer 120a. Here, a material that can be used for the conductive layer 220c can be used for the conductive layer 120b, for example. A material that can be used for the conductive layer 220a and the conductive layer 220b can be used for the conductive layer 120a, for example. Although FIG. 17 illustrates an example in which the oxide semiconductor layer 230 is in contact with the top surface of the conductive layer 120a, the oxide semiconductor layer 230 is not necessarily in contact with the top surface of the conductive layer 120a.

When the sense amplifier is provided to overlap with the memory cell 150 as illustrated in FIG. 17, the bit line can be shortened. Accordingly, the bit line capacitance can be reduced and the memory device can be driven at high speed.

The memory device illustrated in FIG. 17 can correspond to a semiconductor device 900 described in Embodiment 3. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 can be a p-channel transistor or an n-channel transistor.

In the transistor 300 illustrated in FIG. 17, the semiconductor region 313 (part of the substrate 311) where a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 17 is just an example and is not limited to having the structure illustrated therein; an appropriate transistor can be used in accordance with a circuit structure or a driving method.

Wiring layers including an interlayer film, a wiring, a plug, and the like may be provided between the structure bodies. A plurality of wiring layers can be provided in accordance with the design. Here, a plurality of conductive layers functioning as plugs or wirings are collectively denoted by the same reference numeral in some cases. Furthermore, in this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer insulating films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIG. 17, an insulating layer 350, an insulating layer 352, and an insulating layer 354 are stacked sequentially. Furthermore, a conductive layer 356 is formed in the insulating layers 350, 352, and 354. The conductive layer 356 functions as a plug or a wiring.

As the insulating layer 352, the insulating layer 354, and the like functioning as interlayer films, the above-described insulating layer that can be used for the semiconductor device or the memory device can be used.

As the conductive layer functioning as a plug or a wiring, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in an insulating layer 641. The conductive layers 642 and 120a can be formed using the same material in the same step. The conductive layer 644 is embedded in the insulating layers 180 and 130. The conductive layer 645 is embedded in an insulating layer 647. The conductive layers 645 and 110 can be formed using the same material in the same step. The conductive layer 646 is embedded in an insulating layer 648. The transistor 300 and the conductive layer 110 are electrically insulated from each other by the insulating layer 648.

As described above, the memory device of this embodiment includes a transistor with reduced parasitic capacitance, and thus can have higher operation speed. In addition, since the memory device of this embodiment includes a capacitor and a transistor that overlap with each other, the area occupied by the memory cell in a plan view can be reduced and a memory device with a high degree of integration can be obtained.

This embodiment can be combined with any of the other embodiments as appropriate.

### Embodiment 3

In this embodiment, the semiconductor device 900 of one embodiment of the present invention will be described. The semiconductor device 900 can function as a memory device.

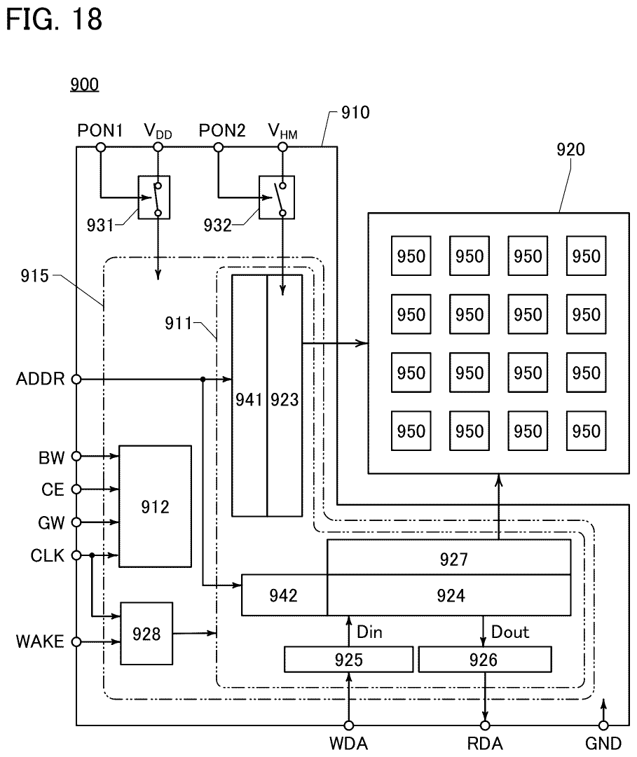

FIG. 18 is a block diagram illustrating a structure example of the semiconductor device 900. The semiconductor device 900 illustrated in FIG. 18 includes a driver circuit 910 and a memory cell array 920. The memory cell array 920 includes at least one memory cell 950. FIG. 18 illustrates an example in which the memory cell array 920 includes a plurality of memory cells 950 arranged in a matrix.

The memory device (e.g., the memory cell 150) described in Embodiment 2 can be used for the memory cell 950.

The driver circuit 910 includes a power switch (PSW) 931, a PSW 932, and a peripheral circuit 915. The peripheral circuit 915 includes a peripheral circuit 911, a control circuit 912 (Control Circuit), and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941 (Row Decoder), a column decoder 942 (Column Decoder), a row driver 923 (Row Driver), a column driver 924 (Column Driver), an input circuit 925 (Input Cir.), an output circuit 926 (Output Cir.), and a sense amplifier 927 (Sense Amplifier).

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 18 but can be more than one. In that case, a power switch is provided for each power domain.

Structure examples of other memory cells each of which can be used as the memory cell 950 are described with reference to FIGS. 19A to 19H.

In the following description, the expression “two components are connected to each other” includes the case where the two components are electrically connected through a circuit element (a transistor, a switch, a diode, a resistor, or the like). The term “electrical connection” means a possibility that a current flows between two components. Note that the case where two components are connected through a switch or a transistor is included as electrical connection because a current can flow when the components are in an on state.

### [DOSRAM]

FIG. 19A illustrates a circuit structure example of a memory cell for a DRAM. In this specification and the like, a DRAM using an OS transistor is referred to as a dynamic oxide semiconductor random access memory (DOSRAM). A memory cell 951 includes the transistor M1 and the capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL. Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The memory cell that can be used as the memory cell 950 is not limited to the memory cell 951, and the circuit structure can be changed. For example, a memory cell 952 illustrated in FIG. 19B may be used. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 19C illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential (sometimes referred to as a ground potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 19D. In a memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as the write bit line and the read bit line in the memory cell 954.

A memory cell 955 illustrated in FIG. 19E is an example in which the capacitor CB and the wiring CAL in the memory cell 953 are omitted. A memory cell 956 illustrated in FIG. 19F is an example in which the capacitor CB and the wiring CAL in the memory cell 954 are omitted. Such structures enable high integration of memory cells.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 19G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 19H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 19H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. The gate of the transistor M9 is connected to a wiring BRL. A second terminal of the transistor M10 is connected to a first terminal of the capacitor CD2. The gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed in such a manner that the wiring BIL and the wiring BILB are precharged with a predetermined potential, and then a high-level potential is applied to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted.

Note that the transistors MS1 to MS4 may be Si transistors.

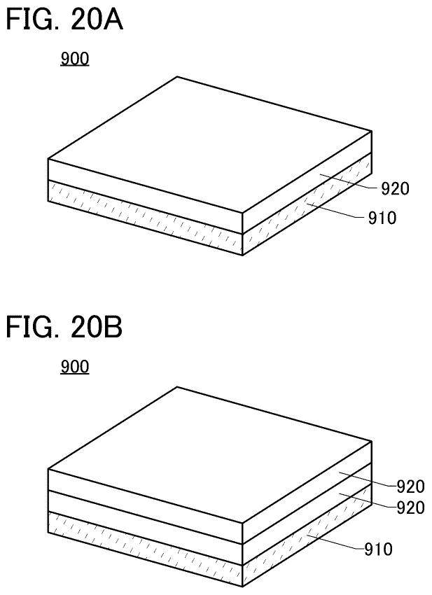

The driver circuit 910 and the memory cell array 920 included in the semiconductor device 900 may be provided on the same plane. Alternatively, as illustrated in FIG. 20A, the driver circuit 910 and the memory cell array 920 may be provided to overlap each other. Overlapping the driver circuit 910 and the memory cell array 920 can shorten a signal propagation distance. As illustrated in FIG. 20B, a plurality of memory cell arrays 920 may be stacked over the driver circuit 910.

Next, description is made on an example of an arithmetic processing device that can include the semiconductor device, such as the memory device described above.

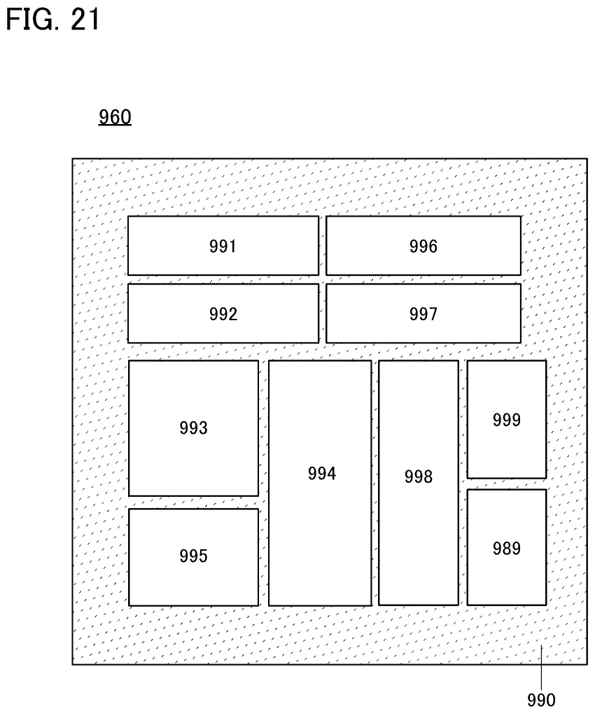

FIG. 21 is a block diagram of an arithmetic device 960. The arithmetic device 960 illustrated in FIG. 21 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 21 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory cell array 920 can be stacked over the arithmetic device 960. The memory cell array 920 can be used as a cache. Here, the cache interface 989 may have a function of supplying data retained in the memory cell array 920 to the cache 999. Moreover, in this case, the driver circuit 910 is preferably included in part of the cache interface 989.

Note that it is also possible that the cache 999 is not provided and only the memory cell array 920 is used as a cache.

The arithmetic device 960 illustrated in FIG. 21 is only an example with a simplified structure, and the actual arithmetic device 960 has a variety of structures depending on the application. For example, what is called a multicore structure is preferably employed in which a plurality of cores each including the arithmetic device 960 in FIG. 21 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 21, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

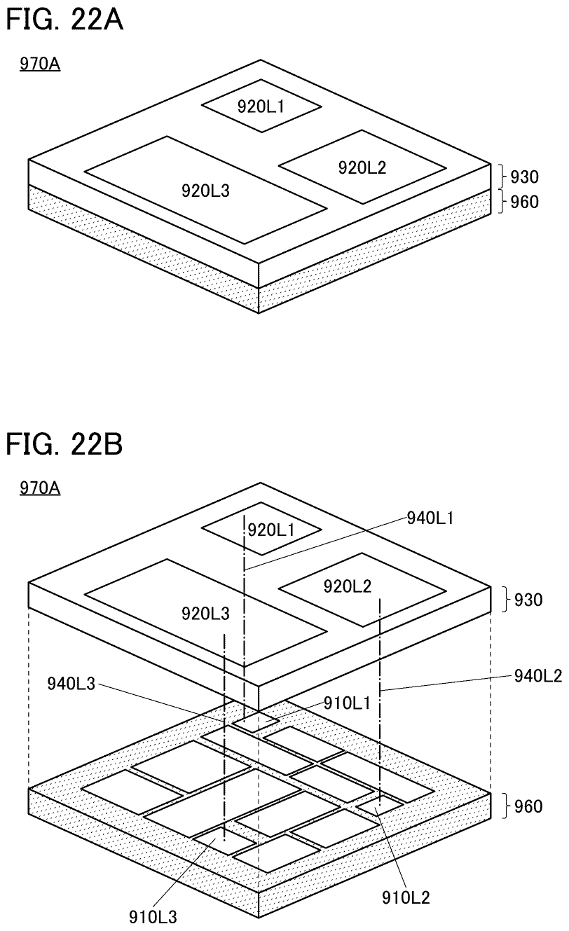

The memory cell array 920 and the arithmetic device 960 can be provided to overlap with each other. FIGS. 22A and 22B are perspective views of a semiconductor device 970A. The semiconductor device 970A includes a layer 930 provided with memory cell arrays over the arithmetic device 960. A memory cell array 920L1, a memory cell array 920L2, and a memory cell array 920L3 are provided in the layer 930. The arithmetic device 960 and each of the memory cell arrays overlap with each other. For easy understanding of the structure of the semiconductor device 970A, the arithmetic device 960 and the layer 930 are separately illustrated in FIG. 22B.

Overlapping the arithmetic device 960 and the layer 930 including the memory cell arrays can shorten the connection distance therebetween. Accordingly, the communication speed therebetween can be increased. Moreover, a short connection distance leads to lower power consumption.

As a method for stacking the layer 930 including the memory cell arrays and the arithmetic device 960, either of the following methods may be employed: a method in which the layer 930 including the memory cell arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory cell arrays 920L1, 920L2, and 920L3 provided in the layer 930 are each used as a cache. In this case, for example, the memory cell array 920L1, the memory cell array 920L2, and the memory cell array 920L3 can be used as an L1 cache (also referred to as a level 1 cache), an L2 cache (also referred to as a level 2 cache), and an L3 cache (also referred to as a level 3 cache), respectively. Among the three memory cell arrays, the memory cell array 920L3 has the highest capacity and the lowest access frequency. The memory cell array 920L1 has the lowest capacity and the highest access frequency.

Note that in the case where the cache 999 provided in the arithmetic device 960 is used as the L1 cache, the memory cell arrays provided in the layer 930 can each be used as the lower-level cache or the main memory. The main memory has higher capacity and lower access frequency than the cache.

As illustrated in FIG. 22B, a driver circuit 910L1, a driver circuit 910L2, and a driver circuit 910L3 are provided. The driver circuit 910L1 is connected to the memory cell array 920L1 through a connection electrode 940L1. Similarly, the driver circuit 910L2 is connected to the memory cell array 920L2 through a connection electrode 940L2, and the driver circuit 910L3 is connected to the memory cell array 920L3 through a connection electrode 940L3.

Note that although the case where three memory cell arrays function as caches is described here, the number of memory cell arrays may be one, two, or four or more.

In the case where the memory cell array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory cell array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

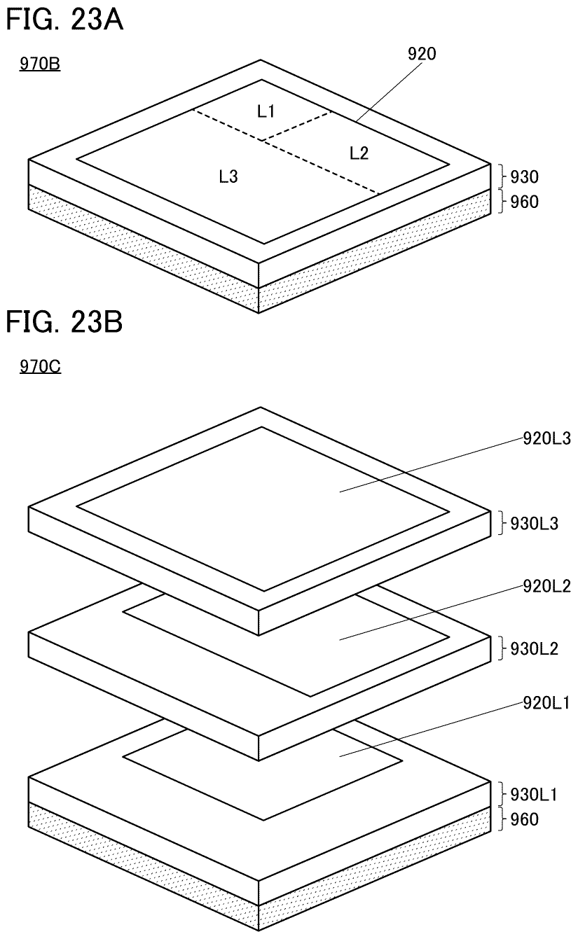

The layer 930 including one memory cell array 920 may be provided to overlap with the arithmetic device 960. FIG. 23A is a perspective view of a semiconductor device 970B.

In the semiconductor device 970B, one memory cell array 920 can be divided into a plurality of areas having different functions. FIG. 23A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory cell arrays may be stacked. FIG. 23B is a perspective view of a semiconductor device 970C.

In the semiconductor device 970C, a layer 930L1 including the memory cell array 920L1, a layer 930L2 including the memory cell array 920L2 over the layer 930L1, and a layer 930L3 including the memory cell array 920L3 over the layer 930L2 are stacked. The memory cell array 920L1 physically closest to the arithmetic device 960 can be used as a high-level cache, and the memory cell array 920L3 physically farthest from the arithmetic device 960 can be used as a low-level cache or a main memory. Such a structure can increase the capacity of each memory cell array, leading to higher processing capability.

This embodiment can be combined with any of the other embodiments as appropriate.

### Embodiment 4

In this embodiment, application examples of the memory device of one embodiment of the present invention will be described.

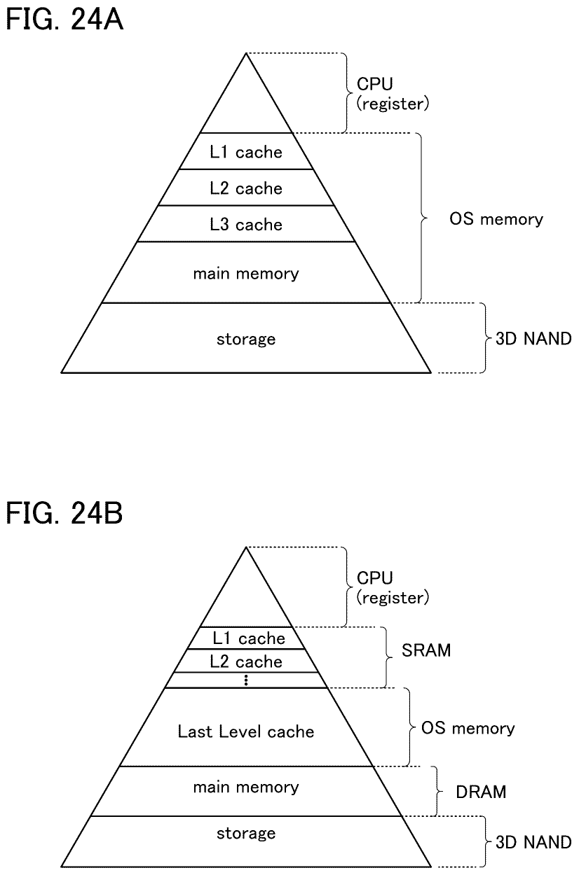

In general, a variety of memory devices are used in semiconductor devices such as computers in accordance with the intended use. FIG. 24A illustrates the hierarchy of various memory devices used in a semiconductor device. The memory devices at the upper levels require a higher operating speed, whereas the memory devices at the lower levels require a larger memory capacity and a higher memory density. FIG. 24A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in an arithmetic processing device, for example. Therefore, the storage needs to have a high memory capacity and a high memory density rather than operating speed. For example, a high-capacity nonvolatile memory device such as a 3D NAND memory device can be used.

The memory device including an oxide semiconductor (the OS memory) of one embodiment of the present invention operates fast and can retain data for a long time. Thus, as illustrated in FIG. 24A, the memory device of one embodiment of the present invention can be favorably used at both the level including the cache and the level including the main memory. The memory device of one embodiment of the present invention can also be used at the level including the storage.

As the OS memory, any of the DOSRAM, NOSRAM, and OS-SRAM described above can be suitably used.

Among these memories, the cache requires a higher operating speed.

By contrast, the main memory has a higher capacity than the cache and thus a memory element used in the main memory preferably has a lower power consumption than that used in the cache. The OS memory of one embodiment of the present invention can achieve a long retention time owing to the extremely low off-state current of the OS transistor. With the use of an OS memory as a main memory, a long retention time can be achieved and power consumption of the memory device can be reduced. As the main memory, a DOSRAM having an operating speed lower than or equal to 15 ns and a long retention time can be used, for example. In the case of a DRAM including a transistor that uses silicon, the retention time is approximately 64 milliseconds (ms). The DOSRAM using an OS transistor can achieve a retention time that is approximately ten times that of the DRAM. With a longer retention time, the refresh rate can be lower, so that power consumption of the memory device can be reduced. When the write time and the read time of the DOSRAM are each set to be shorter than or equal to 15 nanoseconds (ns), the DOSRAM can be suitably used as the main memory. The retention time of the DOSRAM is preferably longer than or equal to 0.64 seconds(s). The write time and the read time of the DOSRAM of one embodiment of the present invention are each preferably shorter than or equal to 15 ns. At least one of the write time and the read time of the DOSRAM of one embodiment of the present invention is longer than or equal to 1 ns and shorter than 15 ns, for example. Alternatively, at least one of the write time and the read time of the DOSRAM of one embodiment of the present invention is longer than 2 ns and shorter than 15 ns, for example. The retention time of the DOSRAM of one embodiment of the present invention is preferably longer than or equal to 0.16 s, further preferably longer than or equal to 0.32 s, still further preferably longer than or equal to 0.64 s. The memory is preferably operated at an environment temperature ranging from −40° C. to 110° C., for example.

With the use of the transistor illustrated in FIGS. 1A to 1C, FIGS. 2A to 2C, or the like in the OS memory, the area occupied by the transistor can be further reduced as compared with the case of using a planar-type transistor. By further using the DOSRAM structure illustrated in FIGS. 14A to 14C, FIGS. 15A and 15B, or the like, where the transistor is provided over the capacitor so as to overlap with the capacitor, memory cells can be arranged at high density. Moreover, with the use of an OS transistor, high operating speed and long-time data retention can be achieved.

FIG. 24B illustrates an example in which an SRAM is used as at least one of the caches and the OS memory of one embodiment of the present invention is used as the other cache.

The lowest-level cache can be referred to as a last level cache (LLC). The LLC does not require a higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 24B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 24B.

This embodiment can be combined with any of the other embodiments as appropriate.

### Embodiment 5

In this embodiment, a display device of one embodiment of the present invention will be described.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device, a module which is mounted with an integrated circuit (IC) by a chip on glass (COG) method, a chip on film (COF) method, or the like, and the like.

That is, the display device in this embodiment may have a function of a touch panel. The display device can employ any of a variety of sensor elements that can sense proximity or touch of a sensing target such as a finger, for example.

For example, a variety of types such as a capacitive type, a resistive type, a surface acoustic wave type, an infrared type, an optical type, and a pressure-sensitive type can be used for the sensor.

Examples of the capacitive touch sensor are a surface capacitive touch sensor and a projected capacitive touch sensor. Examples of the projected capacitive touch sensor include a self-capacitive touch sensor and a mutual capacitive touch sensor. The use of a mutual capacitive touch sensor is preferable because multiple points can be detected simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element and a counter substrate.

### [Display Module]

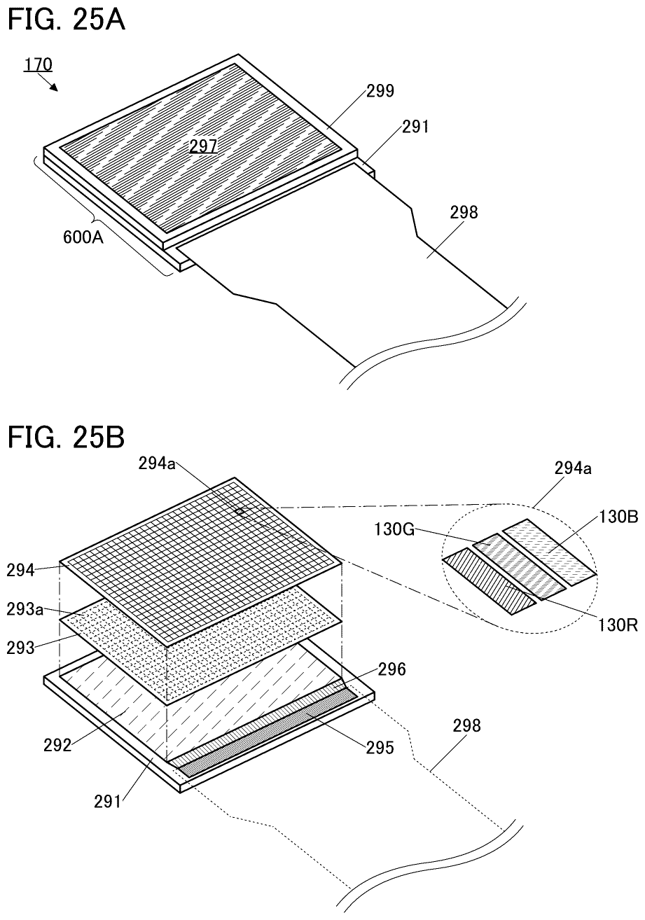

FIG. 25A is a perspective view of a display module 170. The display module 170 includes a display device 600A and an FPC 298. Note that the display device included in the display module 170 is not limited to the display device 600A and may be a display device 600B described later.

The display module 170 includes a substrate 291 and a substrate 299. The display module 170 includes a display portion 297. The display portion 297 is a region of the display module 170 where an image is displayed, and is a region where light emitted from pixels provided in a pixel portion 294 described later can be seen.

FIG. 25B is a perspective view schematically illustrating the structure on the substrate 291 side. Over the substrate 291, a circuit portion 292, a pixel circuit portion 293 over the circuit portion 292, and the pixel portion 294 over the pixel circuit portion 293 are stacked. In addition, a terminal portion 295 for connection to the FPC 298 is included in a portion over the substrate 291 that does not overlap with the pixel portion 294. The terminal portion 295 and the circuit portion 292 are electrically connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side in FIG. 25B. FIG. 25B illustrates an example where one pixel 294a includes a subpixel 130R emitting red light, a subpixel 130G emitting green light, and a subpixel 130B emitting blue light.

The subpixel includes a display element. Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

As the light-emitting element, a self-luminous light-emitting element such as a light-emitting diode (LED), an organic LED (OLED), or a semiconductor laser can be used. Examples of the LED include a mini LED and a micro LED.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement. FIG. 25B illustrates an example where stripe arrangement is employed as the pixel arrangement.

The pixel circuit portion 293 includes a plurality of pixel circuits 293a arranged periodically.

One pixel circuit 293a is a circuit that controls driving of a plurality of elements included in one pixel 294a. One pixel circuit 293a can be provided with three circuits each of which controls light emission of one light-emitting element. For example, the pixel circuit 293a can include at least one selection transistor, one current control transistor (driving transistor), and a capacitor for one light-emitting element. In this case, a gate signal is input to a gate of the selection transistor, and a source signal is input to a source of the selection transistor. With such a structure, an active-matrix display device is achieved.

The circuit portion 292 includes a circuit for driving the pixel circuits 293a in the pixel circuit portion 293. For example, one or both of a gate line driver circuit and a source line driver circuit are preferably included. The circuit portion 292 may also include at least one of an arithmetic circuit, a memory circuit, a power supply circuit, and the like.

The FPC 298 functions as a wiring for supplying a video signal, a power supply potential, or the like to the circuit portion 292 from the outside. An IC may be mounted on the FPC 298.

The display module 170 can have a structure where one or both of the pixel circuit portion 293 and the circuit portion 292 are stacked below the pixel portion 294; thus, the aperture ratio (the effective display area ratio) of the display portion 297 can be significantly high. Furthermore, the pixels 294a can be arranged extremely densely and thus the display portion 297 can have a significantly high resolution.

Such a display module 170 has an extremely high resolution, and thus can be suitably used for a device for VR such as an HMD or a glasses-type device for AR. For example, even in the case of a structure where the display portion of the display module 170 is seen through a lens, pixels of the extremely-high-resolution display portion 297 included in the display module 170 are prevented from being seen when the display portion is enlarged by the lens, so that display providing a high sense of immersion can be performed. Without being limited thereto, the display module 170 can be suitably used for electronic devices including a relatively small display portion. For example, the display module 170 can be favorably used in a display portion of a wearable electronic device, such as a wrist watch.

### Structure Example 1 of Display Device

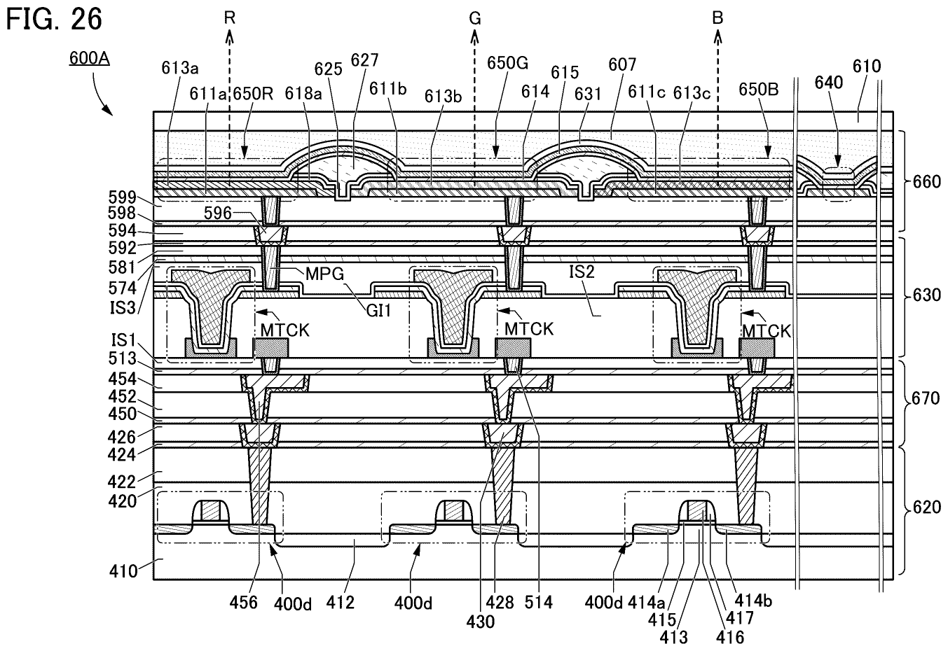

FIG. 26 is a cross-sectional view of the display device 600A. The display device 600A is an example of a display device having a metal maskless (MML) structure. In other words, the display device 600A includes a light-emitting element that is formed without using a fine metal mask.

An island-shaped light-emitting layer of the light-emitting element included in the display device having the MML structure is formed in such a manner that a light-emitting layer is formed on the entire surface and then the light-emitting layer is processed by a lithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by forming a light-emitting layer and performing processing three times by photolithography.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having the MML structure. The MML structure can reduce the manufacturing cost as described above, and thus is suitable for mass production of the device.

A display device having the MML structure does not require a pseudo improvement in resolution by employing a unique pixel arrangement such as a PenTile arrangement; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

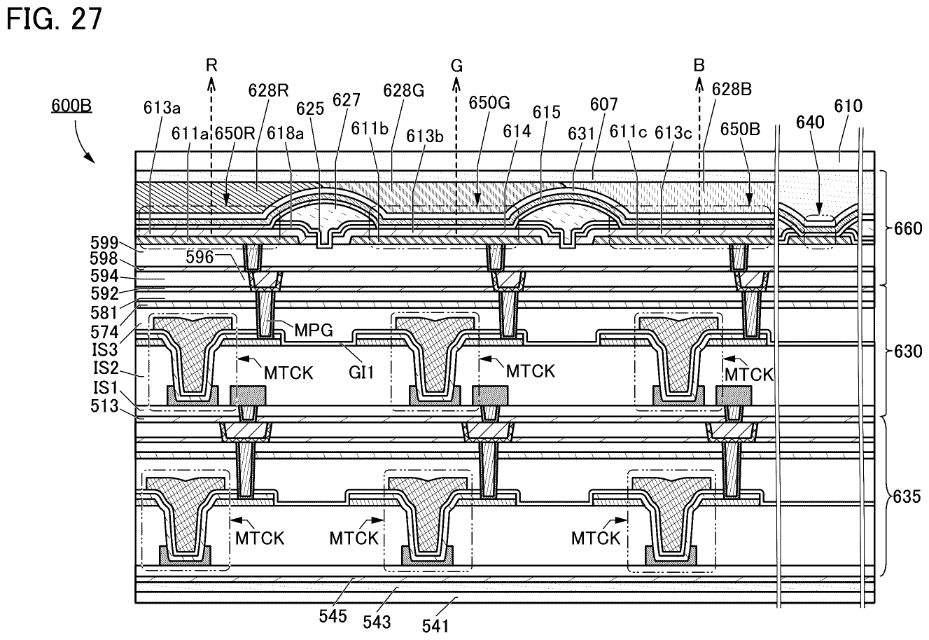

Moreover, providing a sacrificial layer over the light-emitting layer can reduce damage to the light-emitting layer in the manufacturing process of the display device, resulting in an increase in reliability of the light-emitting element. Note that the sacrificial layer may remain in the completed display device or may be removed in the manufacturing process. For example, a sacrificial layer 618a illustrated in FIG. 26 and FIG. 27 is part of the sacrificial layer provided over the light-emitting layer.

Employing a film formation step using an area mask and a processing step using a resist mask enables a light-emitting element to be manufactured by a relatively easy process.

FIG. 26 is a schematic cross-sectional view of the display device 600A (a semiconductor device) of one embodiment of the present invention. The display device 600A is provided with a pixel circuit, a driver circuit, and the like over a substrate 410. Note that in the display device 600A in FIG. 26, a wiring layer 670 is illustrated in addition to an element layer 620, an element layer 630, and an element layer 660. The wiring layer 670 is a layer provided with a wiring.

A pixel circuit of the display device is preferably provided in the element layer 630. A driver circuit (one or both of a gate driver and a source driver) of the display device is preferably provided in the element layer 620. One or more of a variety of circuits such as an arithmetic circuit and a memory circuit may be provided in the element layer 620.

For example, the element layer 620 includes the substrate 410 on which a transistor 400d is formed. The wiring layer 670 is provided above the transistor 400d, and a wiring for electrically connecting the transistor 400d to a conductive layer, a transistor, or the like provided in the element layer 630 (a conductive layer 514 in FIG. 26) is provided in the wiring layer 670. The element layer 630 and the element layer 660 are provided above the wiring layer 670, and the element layer 630 includes a transistor MTCK and the like, for example. The element layer 660 includes a light-emitting element 650 (a light-emitting element 650R, a light-emitting element 650G, and a light-emitting element 650B in FIG. 26) and the like.

The transistor 400d is an example of a transistor included in the element layer 620. The transistor MTCK is an example of a transistor included in the element layer 630. The light-emitting element (the light-emitting element 650R, the light-emitting element 650G, and the light-emitting element 650B) is an example of a light-emitting element included in the element layer 660.

As the transistor MTCK, an OS transistor can be used, for example. FIG. 26 illustrates an example in which the transistor 200 described in the above embodiments is used as the transistor MTCK.

As the substrate 410, a semiconductor substrate (e.g., a single crystal substrate formed of silicon or germanium) can be used, for example. Besides such a semiconductor substrate, any of the following can be used as the substrate 410: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base film including a fibrous material. In the description of this embodiment, the substrate 410 is a semiconductor substrate containing silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and low-resistance regions 414a and 414b functioning as source and drain regions. Thus, the transistor 400d is a Si transistor. Although FIG. 26 illustrates the structure where one of the source and the drain of the transistor 400d is electrically connected to the conductive layer 514 provided in the element layer 630 through the conductive layer 428, the conductive layer 430, and the conductive layer 456, the electrical connection structure of the display device of one embodiment of the present invention is not limited thereto.

The transistor 400d can have a fin-type structure when, for example, the top surface of the semiconductor region 413 and the side surface thereof in the channel width direction are covered with the conductive layer 416 with the insulating layer 415 as a gate insulating layer therebetween. The effective channel width can be increased in the fin-type transistor 400d, so that the on-state characteristics of the transistor 400d can be improved. In addition, contribution of the electric field of the gate electrode can be increased, so that the off-state characteristics of the transistor 400d can be improved. The transistor 400d may have a planar structure instead of a fin-type structure.

Note that the transistor 400d can be a p-channel transistor or an n-channel transistor. Alternatively, a plurality of transistors 400d including both the p-channel transistor and the n-channel transistor may be used.

A region of the semiconductor region 413 where a channel is formed, a region in the vicinity thereof, and the low-resistance regions 414a and 414b functioning as the source and drain regions preferably contain a silicon-based semiconductor, specifically, preferably contain single crystal silicon. Alternatively, the above-described regions may be formed using germanium, silicon germanium, gallium arsenide, aluminum gallium arsenide, or gallium nitride, for example. Alternatively, the transistor 400d may contain silicon whose effective mass is adjusted by applying stress to the crystal lattice and thereby changing the lattice spacing. Alternatively, the transistor 400d may be a high-electron-mobility transistor (HEMT) containing gallium arsenide and aluminum gallium arsenide, for example.

For the conductive layer 416 functioning as the gate electrode, a semiconductor material such as silicon that contains an element imparting n-type conductivity (e.g., arsenic or phosphorus) or an element imparting p-type conductivity (e.g., boron or aluminum) can be used. For another example, for the conductive layer 416, a conductive material such as a metal material, an alloy material, or a metal oxide material can be used.

Note that a material of a conductive layer determines the work function; thus, selecting the material of the conductive layer can adjust the threshold voltage of a transistor. Specifically, one or both of titanium nitride and tantalum nitride are preferably used for the conductive layer. Furthermore, in order to ensure the conductivity and embeddability of the conductive layer, one or both of tungsten and aluminum are preferably stacked over the conductive layer. In particular, tungsten is preferable in terms of heat resistance.

The element isolation layer 412 is provided to separate a plurality of transistors on the substrate 410 from each other. The element isolation layer can be formed by a local oxidation of silicon (LOCOS) method, a shallow trench isolation (STI) method, or a mesa isolation method.

Over the transistor 400d illustrated in FIG. 26, an insulating layer 420 and an insulating layer 422 are stacked in this order from the substrate 410 side.

For the insulating layers 420 and 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may function as a planarization film for eliminating a level difference caused by the transistor 400d or the like covered with the insulating layers 420 and 422. For example, the top surface of the insulating layer 422 may be planarized by planarization treatment using a CMP method or the like to improve the planarity.

The conductive layer 428 connected to the transistor MTCK and the like provided above the insulating layer 422 is embedded in the insulating layer 420 and the insulating layer 422. Note that the conductive layer 428 has a function of a plug or a wiring.

In the display device 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

For example, over the insulating layers 422 and 428, the insulating layers 424 and 426 are stacked in this order. An opening portion is formed in the insulating layers 424 and 426 in each region overlapping with the conductive layer 428. In addition, the conductive layer 430 is embedded in the opening portion.

The insulating layer 450, the insulating layer 452, and the insulating layer 454 are sequentially stacked over the insulating layer 426 and the conductive layer 430. An opening portion is formed in the insulating layers 450, 452, and 454 in each region overlapping with the conductive layer 430. The conductive layer 456 is embedded in the opening portion.

The conductive layers 430 and 456 each have a function of a plug or a wiring that is connected to the transistor 400d.

Note that for example, the insulating layers 424 and 450 are preferably formed using an insulating layer having a barrier property against at least one of hydrogen, oxygen, and water, like an insulating layer 592 described later. The insulating layers 426, 452, and 454 are preferably formed using an insulating layer having a relatively low dielectric constant to reduce the parasitic capacitance generated between wirings, like an insulating layer 594 described later. The insulating layers 426, 452, and 454 each have functions of an interlayer insulating film and a planarization film.

The conductive layer 456 preferably includes a conductive layer having a barrier property against at least one of hydrogen, oxygen, and water.

Note that as the conductive layer having a barrier property against hydrogen, tantalum nitride is preferably used, for example. By stacking tantalum nitride and tungsten, which has high conductivity, diffusion of hydrogen from the transistor 400d can be inhibited while the conductivity of a wiring is ensured. In this case, a tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. A conductive layer functioning as a plug or a wiring is embedded in the insulating layer IS1 and the insulating layer 513. Thus, the transistor 400d can be electrically connected to the conductive layer 514 provided in the element layer 630. Alternatively, one of a source and a drain of the transistor MTCK and one of the source and the drain of the transistor 400d may be electrically connected to each other.

The transistor MTCK is provided over the insulating layer IS1. An insulating layer IS3, an insulating layer 574, and an insulating layer 581 are stacked in this order over the transistor MTCK. A conductive layer MPG functioning as a plug or a wiring is embedded in the insulating layer IS3, the insulating layer 574, and the insulating layer 581.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits entry of the impurities into transistor MTCK. The insulating layer 574 also preferably has a function of inhibiting diffusion of oxygen (e.g., one or both of an oxygen atom and an oxygen molecule). For example, the insulating layer 574 preferably has lower oxygen permeability than the insulating layer IS2 and the insulating layer IS3. As the insulating layer IS2, the insulating layer 280 described in the above embodiments can be used.

Thus, the insulating layer 574 preferably functions as a barrier insulating film that inhibits diffusion of impurities such as water and hydrogen. Accordingly, the insulating layer 574 is preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the above impurities are less likely to pass). Alternatively, it is preferable to use an insulating material having a function of inhibiting diffusion of oxygen (e.g., one or both of an oxygen atom and an oxygen molecule) (an insulating material through which the above oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities described in Embodiment 1.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, oxygen contained in the insulating layer IS3 and the like can be inhibited from diffusing above the insulating layer 574.

The insulating layer 581 is preferably a film functioning as an interlayer film and having a lower permittivity than the insulating layer 574. When a material with a low dielectric constant is used for an interlayer film, the parasitic capacitance generated between wirings can be reduced. For example, the dielectric constant of the insulating layer 581 is preferably lower than 4, further preferably lower than 3. For example, the dielectric constant of the insulating layer 581 is preferably less than or equal to 0.7 times that of the insulating layer 574, further preferably less than or equal to 0.6 times that of the insulating layer 574. When the insulating layer 581 is an interlayer film with a low dielectric constant, the parasitic capacitance generated between wirings can be reduced.

The concentration of impurities such as water and hydrogen in the insulating layer 581 is preferably reduced. In that case, materials such as silicon oxide, silicon oxynitride, silicon nitride oxide, or silicon nitride can be used for the insulating layer 581. For example, silicon oxide to which fluorine is added, silicon oxide to which carbon is added, silicon oxide to which carbon and nitrogen are added, or porous silicon oxide can be used for the insulating layer 581. In particular, silicon oxide and silicon oxynitride are preferable because they are thermally stable. In particular, materials such as silicon oxide, silicon oxynitride, and porous silicon oxide are preferably used, in which case a region containing oxygen released by heating can be easily formed. Moreover, the insulating layer 581 can be formed using a resin. A material combined with any of the above materials as appropriate may be used for the insulating layer 581.

The insulating layer 592 and the insulating layer 594 are stacked in this order over the insulating layer 574 and the insulating layer 581.

For the insulating layer 592, it is preferable to use an insulating film having a barrier property (referred to as a barrier insulating film) which prevents diffusion of impurities such as water and hydrogen from the substrate 410 and the transistor MTCK into a region above the insulating layer 592 (e.g., the region including the light-emitting elements 650R, 650G, and 650B, and the like). Accordingly, the insulating layer 592 is preferably formed using an insulating material having a function of inhibiting diffusion of impurities such as a hydrogen atom, a hydrogen molecule, and a water molecule (an insulating material through which the above impurities are less likely to pass). Alternatively, depending on circumstances, the insulating layer 592 is preferably formed using an insulating material having a function of inhibiting diffusion of impurities such as a nitrogen atom, a nitrogen molecule, a nitrogen oxide molecule (e.g., N₂O, NO, or NO₂), and a copper atom (an insulating material through which the above impurities are less likely to pass). The insulating layer 592 preferably has a function of inhibiting diffusion of oxygen (e.g., at least one of an oxygen atom and an oxygen molecule).

For the film having a barrier property against hydrogen, for example, silicon nitride deposited by a CVD method can be used.

The amount of released hydrogen can be measured by thermal desorption spectrometry (TDS), for example. For example, the amount of hydrogen released from the insulating layer 424 that is converted into hydrogen atoms per unit area of the insulating layer 424 is preferably less than or equal to 10×10¹⁵ atoms/cm², further preferably less than or equal to 5×10¹⁵ atoms/cm² in TDS analysis in a film-surface temperature range of 50° C. to 500° C.

Like the insulating layer 581, the insulating layer 594 is preferably an interlayer film with a low permittivity. Thus, the insulating layer 594 can be formed using any of the materials that can be used for the insulating layer 581.

Note that the insulating layer 594 preferably has a lower permittivity than the insulating layer 592. For example, the dielectric constant of the insulating layer 594 is preferably lower than 4, further preferably lower than 3. For example, the dielectric constant of the insulating layer 594 is preferably less than or equal to 0.7 times that of the insulating layer 592, further preferably less than or equal to 0.6 times that of the insulating layer 592. When the insulating layer 594 is an interlayer film with a low dielectric constant, the parasitic capacitance generated between wirings can be reduced.

The conductive layer MPG functioning as a plug or a wiring is embedded in an insulating layer GI1 and the insulating layer IS3, and a conductive layer 596 functioning as a plug or a wiring is embedded in the insulating layer 592 and the insulating layer 594. In particular, the conductive layer MPG and the conductive layer 596 are electrically connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug. As the insulating layer GI1, the insulating layer 250 described in the above embodiments can be used.

As a material of each of plugs and wirings (the conductors MPG, 428, 430, 456, 514, and 596), one or more conductive materials selected from a metal material, an alloy material, a metal nitride material, and a metal oxide material can be used in a single-layer structure or a stacked-layer structure. It is preferable to use a high-melting-point material that has both heat resistance and conductivity, such as tungsten or molybdenum, and it is particularly preferable to use tungsten. A low-resistance conductive material such as aluminum or copper is preferably used. The use of a low-resistance conductive material can reduce wiring resistance.

An insulating layer 598 and an insulating layer 599 are sequentially formed over the insulating layer 594 and the conductive layer 596.

For example, the insulating layer 598 is preferably formed using an insulating layer having a barrier property against one or more of hydrogen, oxygen, and water, like the insulating layer 592. The insulating layer 599 is preferably formed using an insulating layer having a relatively low dielectric constant to reduce the parasitic capacitance generated between wirings, like the insulating layer 594. The insulating layer 599 has functions of an interlayer insulating film and a planarization film.

The light-emitting element 650 and a connection portion 640 are formed over the insulating layer 599.

The connection portion 640 is referred to as a cathode contact portion in some cases, and is electrically connected to cathodes of the light-emitting element 650R, the light-emitting element 650G, and the light-emitting element 650B. In the connection portion 640 illustrated in FIG. 26, a conductive layer formed using the same material in the same step as a conductive layer 611a to a conductive layer 611c is electrically connected to a common electrode 615 described later. Although FIG. 26 illustrates an example where the conductive layer is electrically connected to the common electrode 615 through a common layer 614 described later, the conductive layer and the common electrode 615 may be in direct contact with each other.

Note that the connection portion 640 may be provided to surround four sides of the display portion in a plan view or may be provided in the display portion (e.g., between adjacent light-emitting elements 650) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layer 611a, the conductive layer 611b, and the conductive layer 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

For the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (also referred to as In—Sn oxide or ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure. The SBS structure can optimize materials and structures of light-emitting elements and thus can extend freedom of choice of materials and structures, whereby the luminance and the reliability can be easily improved.

The display device 600A has a top-emission structure. The aperture ratio of pixels in a top-emission structure can be higher than that of pixels in a bottom-emission structure because a transistor and the like can be provided to overlap with a light-emitting region of a light-emitting element in the top-emission structure.

Note that the layer 613a is formed to cover the top and side surfaces of the conductive layer 611a. Similarly, the layer 613b is formed to cover the top and side surfaces of the conductive layer 611b. Similarly, the layer 613c is formed to cover the top and side surfaces of the conductive layer 611c. Accordingly, regions provided with the conductive layers 611a, 611b, and 611c can be entirely used as the light-emitting regions of the light-emitting elements 650R, 650G, and 650B, thereby increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer contains one or more kinds of light-emitting substances. As the light-emitting substance, a substance emitting light of blue, violet, bluish violet, green, yellowish green, yellow, orange, red, or the like is appropriately used. Alternatively, as the light-emitting substance, a substance emitting near-infrared light can be used.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material).

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. The tandem structure enables a light-emitting element capable of high-luminance light emission. Furthermore, the amount of current needed for obtaining a predetermined luminance can be smaller in the tandem structure than in the single structure; thus, the tandem structure enables higher reliability. The tandem structure may be referred to as a stack structure.

When the light-emitting element has a microcavity structure, higher color purity can be achieved.

The layers 613a, 613b, and 613c are each processed into an island shape by a photolithography method. At each of end portions of the layers 613a, 613b, and 613c, the angle between the top surface and the side surface is approximately 90°. By contrast, for example, an organic film formed using a fine metal mask (FMM) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top and side surfaces of each of the layers 613a, 613b, and 613c are clearly distinguished from each other. Accordingly, as for the layers 613a and 613b which are adjacent to each other, one of the side surfaces of the layer 613a and one of the side surfaces of the layer 613b face each other. This applies to a combination of any two of the layers 613a, 613b, and 613c.

The layers 613a, 613b, and 613c each include at least a light-emitting layer. Preferably, the layer 613a, the layer 613b, and the layer 613c include a red-light-emitting layer, a green-light-emitting layer, and a blue-light-emitting layer, respectively, for example. Other than the above colors, cyan, magenta, yellow, or white can be employed as colors of light emitted from the light-emitting layers.

The layers 613a, 613b, and 613c each preferably include a light-emitting layer and a carrier-transport layer (an electron-transport layer or a hole-transport layer) over the light-emitting layer. Since the surfaces of the layers 613a, 613b, and 613c are exposed in the manufacturing process of the display device in some cases, providing the carrier-transport layer over the light-emitting layer inhibits the light-emitting layer from being exposed on the outermost surface, so that damage to the light-emitting layer can be reduced. Thus, the reliability of the light-emitting element can be increased.

The common layer 614 includes, for example, an electron-injection layer or a hole-injection layer. Alternatively, the common layer 614 may be a stack of an electron-transport layer and an electron-injection layer, or may be a stack of a hole-transport layer and a hole-injection layer. The common layer 614 is shared by the light-emitting elements 650R, 650G, and 650B. Note that the common layer 614 is not necessarily provided, and the whole EL layer included in the light-emitting element may be provided in an island shape like the layer 613a, the layer 613b, and the layer 613c.

The common electrode 615 is shared by the light-emitting element 650R, the light-emitting element 650G, and the light-emitting element 650B. As illustrated in FIG. 26, the common electrode 615 shared by the plurality of light-emitting elements is electrically connected to the conductive layer included in the connection portion 640.

The insulating layer 625 preferably has a function of a barrier insulating layer against at least one of water and oxygen. Alternatively, the insulating layer 625 preferably has a function of inhibiting diffusion of at least one of water and oxygen. Alternatively, the insulating layer 625 preferably has a function of capturing or fixing (also referred to as gettering) at least one of water and oxygen. When the insulating layer 625 has a function of a barrier insulating layer or a gettering function, entry of impurities (typically, one or both of water and oxygen) that would diffuse into the light-emitting elements from the outside can be inhibited. With this structure, a highly reliable light-emitting element and a highly reliable display device can be provided.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against at least one of water and oxygen can be increased. For example, the insulating layer 625 preferably has a sufficiently low hydrogen concentration or a sufficiently low carbon concentration, and further preferably has both a sufficiently low hydrogen concentration and a sufficiently low carbon concentration.

As the insulating layer 627, an insulating layer containing an organic material can be favorably used. As the organic material, a photosensitive organic resin is preferably used, and for example, a photosensitive resin composite containing an acrylic resin is used. Note that in this specification and the like, an acrylic resin refers to not only a polymethacrylic acid ester or a methacrylic resin, but also all the acrylic polymer in a broad sense in some cases.

An organic material that can be used for the insulating layer 627 is not limited to the above. For example, for the insulating layer 627, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. A photoresist, which is a photosensitive resin, can be used for the insulating layer 627 in some cases. Examples of the photosensitive resin include positive-type materials and negative-type materials.

The insulating layer 627 may be formed using a material absorbing visible light. When the insulating layer 627 absorbs light emitted from the light-emitting element, light leakage (stray light) from the light-emitting element to an adjacent light-emitting element through the insulating layer 627 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

For example, the insulating layer 627 can be formed by a wet process such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 627 is preferably formed by spin coating.

The insulating layer 627 is formed at a temperature lower than the upper temperature limit of the EL layer. The typical substrate temperature in formation of layer 627 is lower than or equal to 200° C., preferably lower than or equal to 180° C., further preferably lower than or equal to 160° C., still further preferably lower than or equal to 150° C., yet still further preferably lower than or equal to 140° C.

Note that the side surface of the insulating layer 627 preferably has a tapered shape. When the end portion of the side surface of the insulating layer 627 has a forward tapered shape (with an angle less than 90°, preferably less than or equal to 60°, further preferably less than or equal to) 45°, the common layer 614 and the common electrode 615 that are provided over the end portion of the side surface of the insulating layer 627 can be formed with good coverage without disconnection, local thinning, or the like. Consequently, the in-plane uniformity of the common layer 614 and the common electrode 615 can be increased, so that the display quality of the display device can be improved.

In a cross-sectional view of the display device, the top surface of the insulating layer 627 preferably has a convex shape. The convex top surface of the insulating layer 627 preferably has a shape that expands gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layer 613a and the layer 613b). In that case, part of the insulating layer 627 is positioned between the side end portion of one of the two EL layers (e.g., the layer 613a) and the side end portion of the other of the two EL layers (e.g., the layer 613b).

One end portion of the insulating layer 627 preferably overlaps with the conductive layer 611a functioning as a pixel electrode, and the other end portion of the insulating layer 627 preferably overlaps with the conductive layer 611b functioning as a pixel electrode. Such a structure enables the end portion of the insulating layer 627 to be formed over a flat or substantially flat region of the layer 613a (the layer 613b). This makes it relatively easy to process the insulating layer 627 to have a tapered shape as described above.

By providing the insulating layer 627 and the like in the above manner, a disconnected portion and a locally thinned portion can be prevented from being formed in the common layer 614 and the common electrode 615 from a flat or substantially flat region of the layer 613a to a flat or substantially flat region of the layer 613b. Thus, a connection defect due to a disconnected portion and an increase in electrical resistance due to a locally thinned portion can be inhibited from occurring in the common layer 614 and the common electrode 615 between the light-emitting elements.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device in this embodiment includes a region where a distance between two adjacent island-shaped EL layers is less than or equal to 1 μm, preferably less than or equal to 0.5 μm (500 nm), further preferably less than or equal to 100 nm. Shortening the distance between the light-emitting elements in this manner enables a display device with a high definition and a high aperture ratio to be provided.

A protective layer 631 is provided over the light-emitting element 650. The protective layer 631 functions as a passivation film for protecting the light-emitting element 650. Providing the protective layer 631 that covers the light-emitting element can prevent entry of impurities such as water and oxygen into the light-emitting element and increase the reliability of the light-emitting element 650. The protective layer 631 preferably has, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as an indium gallium oxide or an indium gallium zinc oxide (IGZO) may be used for the protective layer 631. The protective layer 631 can be formed by an ALD method, a CVD method, a sputtering method, or the like. Although the protective layer 631 includes an inorganic insulating film in this example, the present invention is not limited thereto. For example, the protective layer 631 may have a stacked-layer structure of an inorganic insulating film and an organic insulating film.

The protective layer 631 and the substrate 610 are bonded to each other with an adhesive layer 607. A solid sealing structure, a hollow sealing structure, or the like can be employed to seal the light-emitting elements. In FIG. 26, a solid sealing structure is employed, in which a space between the substrate 410 and the substrate 610 is filled with the adhesive layer 607. Alternatively, a hollow sealing structure may be employed, in which the space is filled with an inert gas (e.g., nitrogen or argon). In that case, the adhesive layer 607 may be provided not to overlap with the light-emitting element. Alternatively, the space may be filled with a resin other than the frame-like adhesive layer 607.

As the adhesive layer 607, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet may be used.

The display device 600A is a top-emission display device. Light from the light-emitting element is emitted to the substrate 610 side. For this reason, a material having a high visible-light-transmitting property is preferably used for the substrate 610. For example, a substrate having a high visible-light-transmitting property is selected as the substrate 610 among substrates usable as the substrate 410. The pixel electrode contains a material reflecting visible light, and the counter electrode (the common electrode 615) contains a material transmitting visible light.

Note that the display device of one embodiment of the present invention may be not a top-emission display device but a bottom-emission display device where light from the light-emitting element is emitted to the substrate 410 side. In that case, a substrate having a high visible-light-transmitting property is selected as the substrate 410.

### Structure Example 2 of Display Device

FIG. 27 is a cross-sectional view of the display device 600B. The element layer 660 of the display device 600B is different from the element layer 660 of the display device 600A in that the layer 613a, the layer 613b, and the layer 613c have the same structure and that a coloring layer 628R, a coloring layer 628G, and a coloring layer 628B are provided. Furthermore, the display device 600B is different from the display device 600A in not including the element layer 620 and in including an element layer 635. The element layer 635 has a structure similar to that of the element layer 630.

The display device 600B can be a flexible display device when a flexible substrate is used as each of a substrate 541 and the substrate 610. The substrate 541 is bonded to an insulating layer 545 with an adhesive layer 543. The substrate 610 is bonded to the protective layer 631 with the adhesive layer 607.

In the element layer 660 of the display device 600B, the layer 613a, the layer 613b, and the layer 613c have the same structure and the coloring layer 628R, the coloring layer 628G, and the coloring layer 628B are included.

The layer 613a, the layer 613b, and the layer 613c are formed using the same material in the same step. The layer 613a, the layer 613b, and the layer 613c are isolated from each other. When the EL layer is provided in an island shape for each light-emitting element, a leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 650R, 650G, and 650B illustrated in FIG. 27 emit white light, for example. White light emitted from the light-emitting elements 650R, 650G, and 650B passes through the coloring layers 628R, 628G, and 628B, whereby light of a desired color can be obtained.

In the case where the light-emitting element configured to emit white light has a microcavity structure, light with a specific wavelength (e.g., red, green, or blue) is sometimes intensified and emitted.

Light emitted from the light-emitting element 650R is extracted as red light to the outside of the display device 600B through the coloring layer 628R. Similarly, light emitted from the light-emitting element 650G is extracted as green light to the outside of the display device 600B through the coloring layer 628G. Light emitted from the light-emitting element 650B is extracted as blue light to the outside of the display device 600B through the coloring layer 628B.

A light-emitting element emitting white light preferably has a tandem structure.

Alternatively, the light-emitting elements 650R, 650G, and 650B illustrated in FIG. 27 emit blue light, for example. In this case, the layers 613a, 613b, and 613c each include one or more light-emitting layers emitting blue light. In a subpixel emitting blue light, blue light emitted from the light-emitting element 650B can be extracted as it is. In each of the subpixel emitting red light and the subpixel emitting green light, a color conversion layer is provided between the light-emitting element 650R and the coloring layer 628R and between the light-emitting element 650G and the coloring layer 628G, so that blue light emitted from the light-emitting element 650R or 650G is converted into light with a longer wavelength, whereby red light or green light can be extracted. When light passing through the color conversion layer is extracted through the coloring layer, light other than light of a desired color can be absorbed by the coloring layer, and color purity of light emitted from a subpixel can be improved.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

The element layer 630 of the display device 600B has a structure similar to that of the element layer 630 of the display device 600A; thus, the detailed description thereof is omitted.

The display device 600B includes the element layer 635 and the element layer 630 over the element layer 635. The element layer 635 has a structure similar to that of the element layer 630.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display device are preferably provided in the element layer 635.

Although FIG. 27 illustrates an example where two element layers (the element layer 630 and the element layer 635) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and one or more layers between them be used for the pixel circuit or the driver circuit.

A Si transistor is typically formed over a single crystal Si wafer, and thus is difficult to have flexibility. Meanwhile, as illustrated in FIG. 27, in the case where the display device is formed using only OS transistors without using a Si transistor, the display device can have flexibility through a relatively simple manufacturing process.

### Structure Example of Light-Emitting Element

Next, light-emitting elements that can be used for the display device of one embodiment of the present invention are described. Structure examples of a light-emitting element, which are different from the structures illustrated in FIG. 26 and FIG. 27, are mainly described below.

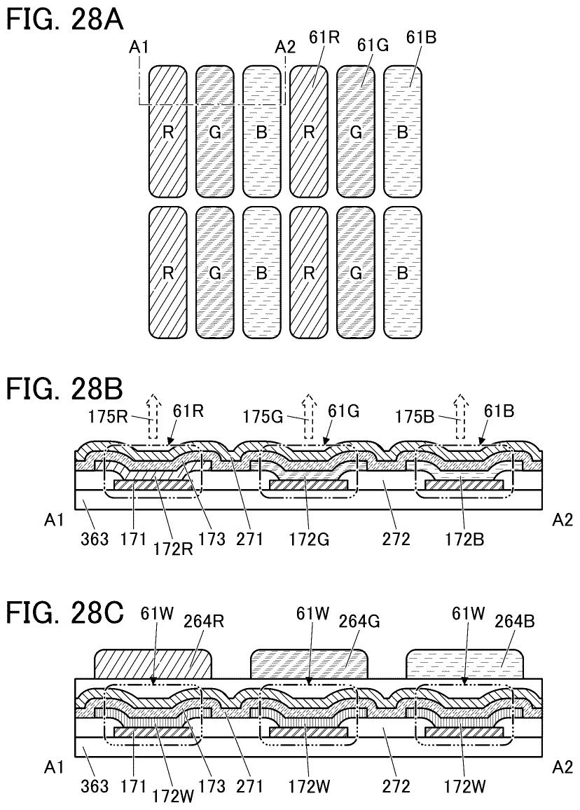

FIG. 28A is a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 28A, light-emitting regions of the light-emitting elements are denoted by R, G, and B to easily differentiate the light-emitting elements. Although the structure illustrated in FIG. 28A has three emission colors of red (R), green (G), and blue (B), one embodiment of the present invention is not limited thereto. For example, the structure may have four or more colors.

FIG. 28B is a cross-sectional view taken along dashed-dotted line A1-A2 in FIG. 28A. The light-emitting elements 61R, 61G, and 61B illustrated in FIG. 28B are provided over an insulating layer 363, and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as a pixel electrode and the conductive layer 173 functions as a common electrode. The EL layer 172R contains at least a light-emitting compound that emits light having a peak in a red wavelength range. An EL layer 172G included in the light-emitting element 61G contains at least a light-emitting compound that emits light having a peak in a green wavelength range. An EL layer 172B included in the light-emitting element 61B contains at least a light-emitting compound that emits light having a peak in a blue wavelength range.

The conductive layer 171 functioning as a pixel electrode is provided for each light-emitting element. The conductive layer 173 functioning as a common electrode is provided as a continuous layer shared by the light-emitting elements. A conductive film having a visible-light-transmitting property is used for either the conductive layer 171 functioning as a pixel electrode or the conductive layer 173 functioning as a common electrode, and a reflective conductive film is used for the other.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulating layer 272 is provided to cover an end portion of the conductive layer 171 functioning as a pixel electrode. An end portion of the insulating layer 272 is preferably tapered. For the insulating layer 272, one or both of an inorganic insulating film and an organic insulating film can be used.

The insulating layer 272 is provided to prevent an unintentional electric short-circuit between adjacent light-emitting elements and unintended light emission therefrom. The insulating layer 272 also has a function of preventing the contact of a metal mask with the conductive layer 171 in the case where the metal mask is used to form the EL layer.

The EL layers 172R, 172G, and 172B each include a region in contact with the top surface of the conductive layer 171 functioning as a pixel electrode and a region in contact with a surface of the insulating layer 272. End portions of the EL layers 172R, 172G, and 172B are positioned over the insulating layer 272.

As illustrated in FIG. 28B, there is a gap between the EL layers of two light-emitting elements with different emission colors. The EL layers 172R, 172G, and 172B are thus preferably provided not to be in contact with each other. This suitably prevents unintentional light emission (also referred to as crosstalk) from being caused by a current flowing through two adjacent EL layers. As a result, the contrast can be increased to achieve a display device with high display quality.

The EL layers 172R, 172G, and 172B can be formed separately by a vacuum evaporation method or the like using a shadow mask such as a metal mask. These layers may be formed separately by a photolithography method. The photolithography method achieves a display device with a high resolution, which is difficult to obtain in the case of using a metal mask.

A protective layer 271 is provided over the conductive layer 173 functioning as a common electrode to cover the light-emitting elements 61R, 61G, and 61B. The protective layer 271 has a function of preventing diffusion of impurities such as water into each light-emitting element from the above. For the material of the protective layer 271, the above-described material of the protective layer 631 can be referred to.

FIG. 28C illustrates a light-emitting element 61W emitting white light. The light-emitting element 61W includes an EL layer 172W emitting white light between the conductive layer 171 functioning as a pixel electrode and the conductive layer 173 functioning as a common electrode.

The EL layer 172W can have, for example, a stacked structure of two or more light-emitting layers that are selected so as to emit light of complementary colors. It is also possible to use a tandem EL layer in which a charge-generation layer is provided between light-emitting layers.

FIG. 28C illustrates three light-emitting elements 61W side by side. A coloring layer 264R is provided above the left light-emitting element 61W. The coloring layer 264R functions as a band path filter transmitting red light. Similarly, a coloring layer 264G transmitting green light is provided above the middle light-emitting element 61W, and a coloring layer 264B transmitting blue light is provided above the right light-emitting element 61W. This enables the display device to display a color image.

Here, the EL layer 172W is separated between two adjacent light-emitting elements 61W. This suitably prevents unintentional light emission from being caused by a current flowing through the EL layers 172W in the two adjacent light-emitting elements 61W. Particularly when the EL layer 172W is a stacked EL layer in which a charge-generation layer is provided between two light-emitting layers, the effect of crosstalk is more significant as the resolution increases, i.e., as the distance between adjacent pixels decreases, leading to lower contrast. Thus, the above structure can achieve a display device having both a high resolution and high contrast.

The EL layers 172W are preferably separated by a photolithography method. This can reduce the distance between light-emitting elements, achieving a display device with a higher aperture ratio than that formed using, for example, a shadow mask such as a metal mask.

This embodiment can be combined with any of the other embodiments as appropriate.

### Embodiment 6

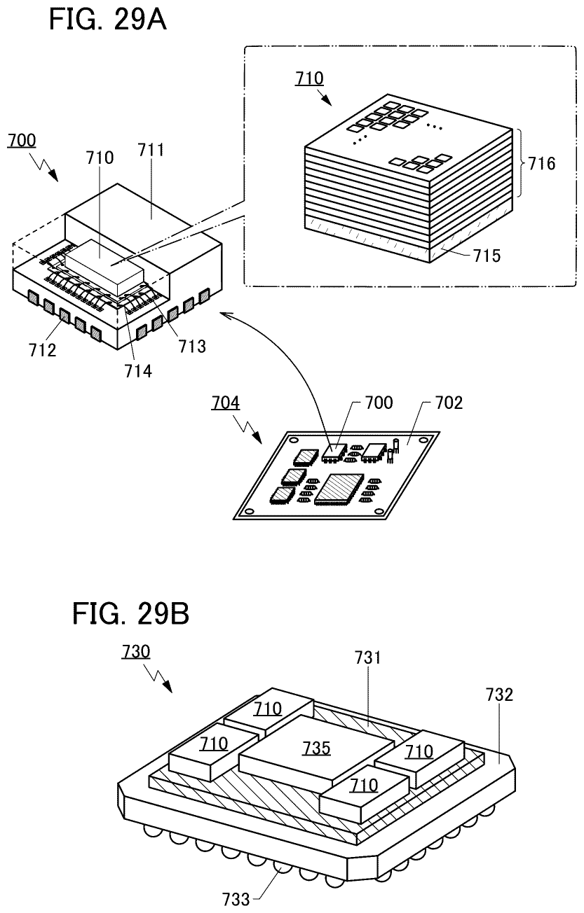

In this embodiment, application examples of the semiconductor device of one embodiment of the present invention are described with reference to FIGS. 29A and 29B, FIGS. 30A to 30E, FIGS. 31A to 31F, FIGS. 32A to 32G, and FIGS. 33A to 33F.

The semiconductor device of one embodiment of the present invention can be used for an electronic component, a large computer, a device for space, a data center (also referred to as DC), and a variety of electronic devices, for example. With the use of the semiconductor device of one embodiment of the present invention, an electronic component, a large computer, a device for space, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 29A is a perspective view of a substrate (a circuit board 704) provided with an electronic component 700. The electronic component 700 illustrated in FIG. 29A includes a semiconductor device 710 in a mold 711. FIG. 29A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. Monolithically stacking the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 29B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 29B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

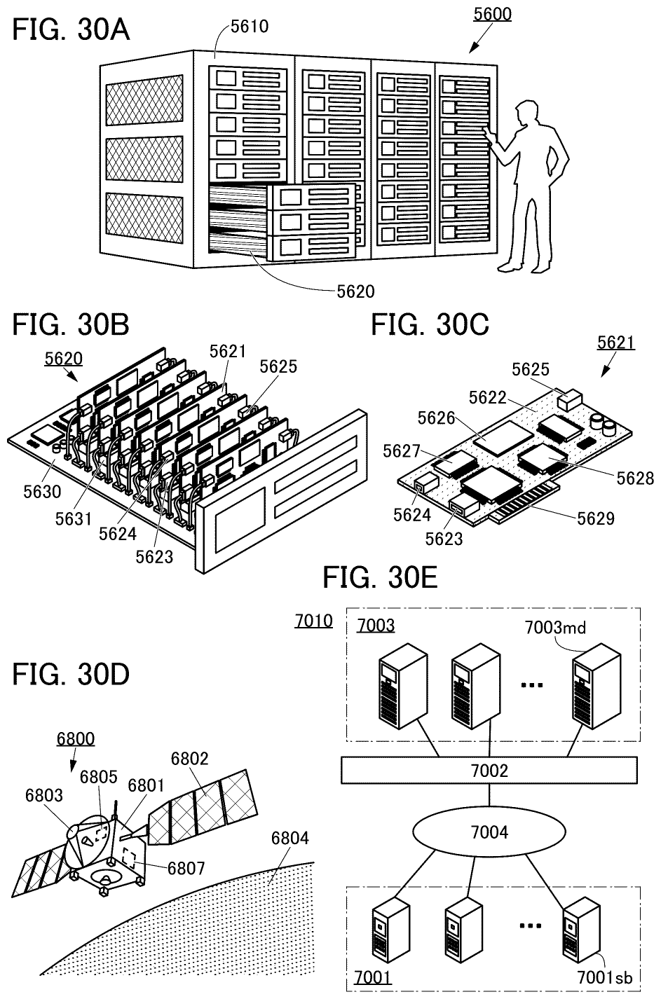

FIG. 30A is a perspective view of a large computer 5600. In the large computer 5600 illustrated in FIG. 30A, a plurality of rack mount computers 5620 are stored in a rack 5610. Note that the large computer 5600 may be referred to as a supercomputer.

The computer 5620 can have a structure illustrated in a perspective view in FIG. 30B, for example. In FIG. 30B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 30C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 30C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that although outer space refers to, for example, space at an altitude greater than or equal to 100 km, outer space described in this specification may include one or more of thermosphere, mesosphere, and stratosphere.

FIG. 30D illustrates an artificial satellite 6800 as an example of a device for space. The artificial satellite 6800 includes a body 6801, a solar panel 6802, an antenna 6803, a secondary battery 6805, and a control device 6807. In FIG. 30D, a planet 6804 in outer space is illustrated as an example.

Although not illustrated in FIG. 30D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 30E illustrates a storage system that can be used in a data center. A storage system 7010 illustrated in FIG. 30E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

### [Electronic Device]

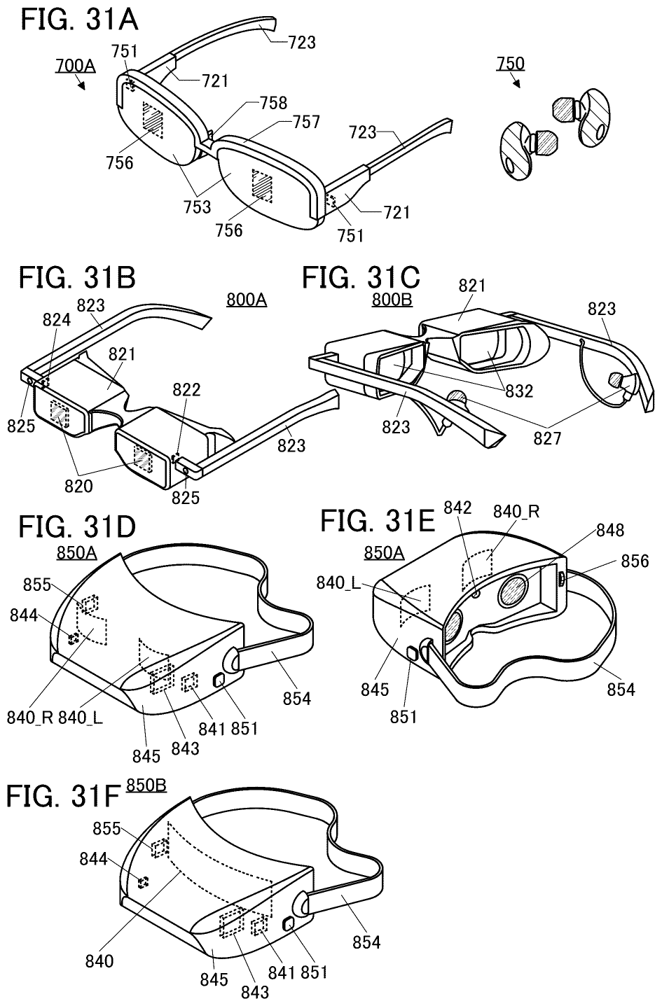

Examples of head-mounted wearable devices are described with reference to FIGS. 31A to 31F. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 31A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display. The semiconductor device of one embodiment of the present invention can be used for the control portion (not illustrated). In that case, power consumption of the electronic device can be reduced.

The electronic device 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A is an electronic device capable of AR display.

In the electronic device 700A, a camera capable of capturing images of the front side may be provided as the image capturing portion. Furthermore, when the electronic device 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A is provided with a battery so that charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

An electronic device 800A illustrated in FIG. 31B and an electronic device 800B illustrated in FIG. 31C each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic devices are capable of performing ultrahigh-resolution display. Such electronic devices provide a high sense of immersion to the user. The semiconductor device of one embodiment of the present invention can be used for the control portion 824. In that case, power consumption of the electronic devices can be reduced.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user wearing the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 31B and the like illustrate examples where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 31A has a function of transmitting information to the earphones 750 with the wireless communication function.

The electronic device may include an earphone portion. The electronic device 800B in FIG. 31C includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 31D and 31E are perspective views of a goggle-type electronic device 850A for VR. FIGS. 31D and 31E illustrate an example where a housing 845 includes a pair of curved display devices 840 (a display device 840_R and a display device 840_L). The electronic device 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display devices 840 are provided, the user's eyes can see the respective display devices. This allows a high-resolution image to be displayed even when three-dimensional display using parallax or the like is performed. In addition, the display device 840 is curved around an arc with an approximate center at the user's eye. This keeps a certain distance between the user's eye and the display surface of the display device 840, enabling the user to see a more natural image. Even when having what is called viewing angle dependence where the luminance or chromaticity of light changes depending on the viewing angle, the display device 840 can have a structure where the user's eye is positioned in the normal direction of the display surface of the display device 840; accordingly, the influence of the viewing angle dependence particularly in the horizontal direction can be practically ignored, enabling display of a more realistic video.

As illustrated in FIG. 31E, the lenses 848 are positioned between the display devices 840 and the user's eyes. FIG. 31E illustrates an example where the dial 856 for changing the positions of the lenses for visibility adjustment is provided. Note that in the case where the electronic device 850A has an autofocus function, the dial 856 for visibility adjustment is not necessarily provided.

FIG. 31F illustrates a goggles-type electronic device 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image which can be seen with both eyes may be displayed on the entire display device 840. Thus, a panorama image can be displayed from end to end of the field of view, which can provide a higher sense of reality.

The display device of one embodiment of the present invention can be used as the display device 840. Since the display device of one embodiment of the present invention has an extremely high resolution, even when an image is magnified using the lenses 848, the pixels are not perceived by the user, and thus a more realistic image can be displayed.

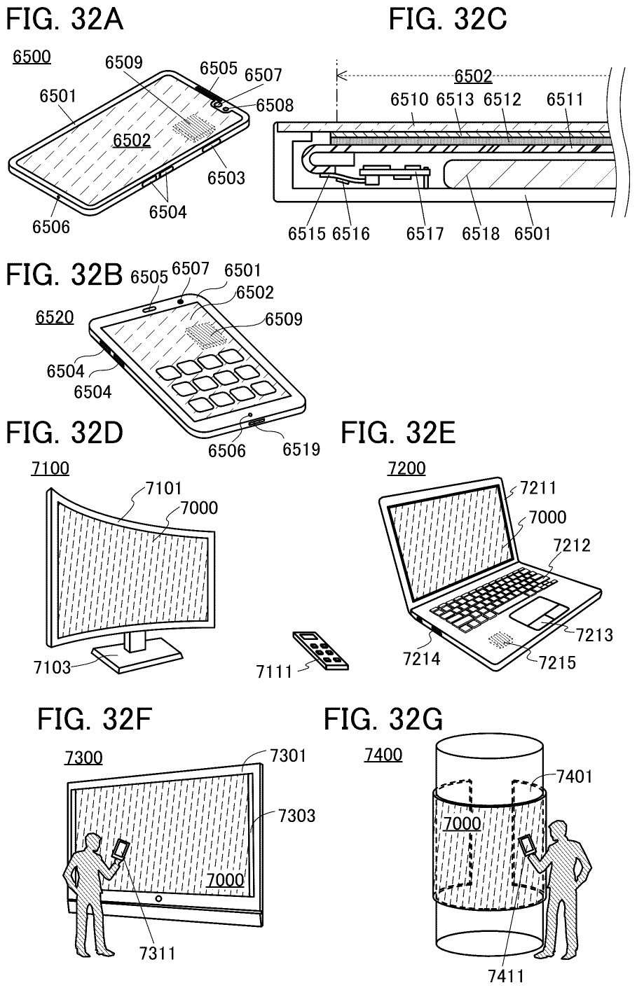

An electronic device 6500 in FIG. 32A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 in FIG. 32B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. Note that the control device 6509 includes, for example, one or more selected from a CPU, a GPU, and a memory device. The semiconductor device of one embodiment of the present invention can be used for one or both of the display portion 6502 and the control device 6509.

FIG. 32C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic appliance. An electronic device with a narrow bezel can be obtained when part of the display panel 6511 is folded back so that the portion connected to the FPC 6515 is provided on the back side of a pixel portion.

FIG. 32D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 32D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 32E illustrates an example of a laptop personal computer. The laptop personal computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIGS. 32F and 32G illustrate examples of digital signage.

Digital signage 7300 illustrated in FIG. 32F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 32G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIGS. 32F and 32G.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 32F and 32G, it is preferable that the digital signage 7300 or the digital signage 7400 can work with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device and the display device of one embodiment of the present invention can be used around a driver's seat in a car, which is a vehicle.

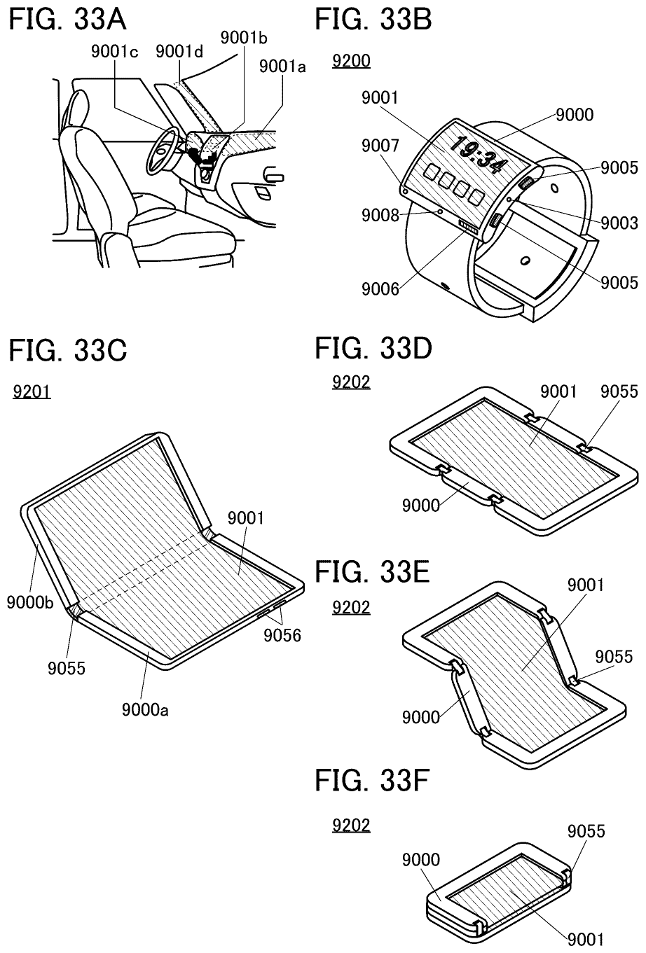

FIG. 33A illustrates the vicinity of a windshield inside a car. FIG. 33A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panel, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying an image taken by an imaging unit provided for the car body. That is, displaying an image taken by the imaging unit provided on the outside of the car body leads to elimination of blind areas and enhancement of safety. Moreover, showing an image to compensate for the area that a driver cannot see makes it possible for the driver to confirm safety more easily and comfortably. The display panel 9001d can also be used as a lighting device.

FIG. 33B is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 33B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

FIG. 33C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housing 9000a and the housing 9000b) joined together with the hinge 9055.

FIGS. 33D to 33F are perspective views illustrating a foldable portable information terminal 9202. FIG. 33D is a perspective view of an opened state of the portable information terminal 9202, FIG. 33F is a perspective view of a folded state thereof, and FIG. 33E is a perspective view of a state in the middle of change from one of FIG. 33D and FIG. 33F to the other. In this manner, the portable information terminal 9202 can be folded in three.

The display portion 9001 of the portable information terminal 9202 is supported by three housings 9000 joined together with the hinges 9055.

In FIGS. 33C to 33F, the display device of one embodiment of the present invention can be used for the display portion 9001. The display portion 9001 can be folded with a radius of curvature greater than or equal to 0.1 mm and less than or equal to 150 mm, for example.

The portable information terminals 9201 and 9202 are highly portable when folded. When the portable information terminals 9201 and 9202 are opened, a seamless large display region is highly browsable.

The use of the semiconductor device of one embodiment of the present invention for one or more selected from an electronic component, a large computer, a device for space, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate.

### Example 1

In this example, a semiconductor device including a transistor was fabricated, and electrical characteristics of the transistor were evaluated.

### <Fabrication of Semiconductor Device>

The semiconductor device was fabricated with reference to the structure of the transistor included in the semiconductor device illustrated in FIG. 7A.

The conductive layer 220 was provided over a silicon oxide film. The conductive layer 220a was formed using a 5-nm-thick titanium nitride film deposited by a sputtering method. The conductive layer 220b was formed using a 20-nm-thick tungsten film deposited by a sputtering method. The conductive layer 220c was formed using a 20-nm-thick ITSO film deposited by a sputtering method.

Next, the insulating layer 280 was formed.

As the insulating layer 280a, a 5-nm-thick silicon nitride film deposited by an ALD method was used. Next, as an insulating layer to be the insulating layer 280b, a 135-nm-thick silicon oxide film deposited by a sputtering method was used. Then, a 100-nm-thick silicon nitride film was formed over the 135-nm-thick silicon oxide film. After that, the silicon nitride film was removed by CMP treatment, so that the top surface of the silicon oxide film was planarized. By the CMP treatment, a 80-nm-thick silicon oxide film was formed as the insulating layer 280b over the conductive layer 220.

As the insulating layer 280c, a 10-nm-thick silicon nitride film deposited by a sputtering method was used.

Next, the conductive layer 240a was formed using tungsten that was deposited to a thickness of 15 nm by a sputtering method. Next, the conductive layer 240b was formed using a 10 nm-thick ITSO film deposited by a sputtering method.

Next, the opening portion 290 was formed by a dry etching method or the like.

An SOC film, an SOG film, and a resist film were formed in this order by a coating method. Then, a resist pattern was formed by photolithography, and the SOG film and the SOC film were processed using the resist pattern, whereby a mask pattern was formed.

The opening portion 290 was formed by dry etching using the formed mask pattern. As a dry etching gas for etching the conductive layer 240b, CH₄ and Ar were used. Then, washing was performed using dilute hydrofluoric acid. Then, Cl₂, O₂, and CF₄ were used as a dry etching gas for etching the conductive layer 240a. For etching of the insulating layer 280, after etching using C₄F₈, C₄F₆, O₂, and Ar as a dry etching gas was performed, plasma treatment using Ar and O₂ was performed and plasma treatment using O₂ was performed. Then, washing was performed using dilute hydrofluoric acid.

Next, the oxide semiconductor layer 230 was formed. Note that as the oxide semiconductor layer 230, a first oxide semiconductor layer and a second oxide semiconductor layer were formed.

The first oxide semiconductor layer was formed using an In—Ga—Zn oxide film deposited by an RF sputtering method. Note that the oxide film to be the first oxide semiconductor layer was deposited using an oxide target having an atomic ratio of In:Ga:Zn=1:1:1.2. The oxide film was deposited so that a portion formed over the top surface of the conductive layer 240 has a thickness of 2 nm.

The second oxide semiconductor layer was formed using a 5-nm-thick In—Ga—Zn oxide film deposited by an ALD method. Note that precursors used for depositing the oxide film to be the second oxide semiconductor layer are triethylindium (TEI), triethylgallium (TEG), and diethylzinc (DEZ). As an oxidizer, ozone (O₃) and oxygen (O₂) were used. The process consisting of the introduction of TEI, the introduction of O₃ and O₂, the introduction of TEG, the introduction of O₃ and O₂, the introduction of DEZ, and the introduction of O₃ and O₂ is one cycle, and the process was repeatedly performed so that the oxide film has an atomic ratio of In:Ga:Zn=1:1:1.

Next, the insulating layer 250 was formed. The insulating layer 250 had a four-layer structure.

The first layer was formed using a 1-nm-thick aluminum oxide film deposited by an ALD method. The second layer over the first layer was formed using a 2-nm-thick silicon oxide film deposited by an ALD method. The third layer over the second layer was formed using a 2-nm-thick hafnium oxide film deposited by an ALD method. The fourth layer over the third layer was formed using a 1-nm-thick silicon nitride film deposited by an ALD method.

Next, the conductive layer 260 was formed.

The conductor 260a was formed using a 5-nm-thick titanium nitride film deposited by a metal CVD method. The conductive layer 260b was formed using a 20-nm-thick tungsten film deposited by a metal CVD method.

In the above-described manner, the transistor included in the semiconductor device was fabricated.

### <Evaluation of Electrical Characteristics of Transistor>

Electrical characteristics of the transistor included in the fabricated semiconductor device were evaluated. Here, electrical characteristics of the transistor in the case where a width of the opening portion 290 of 60 nm were evaluated. As the electrical characteristics, I_{d}-V_{g} characteristics and I_{d}-V_{g} characteristics were each measured. The I_{d}-V_{g} characteristics were measured in such a manner that the drain voltage V_{g} was set to four conditions, 0.1 V, 0.4 V, 0.8 V, and 1.2 V; the source voltage Vₛ was set at 0 V; and the gate voltage V_{g} was swept from −2.5 V to +3.5 V in increments of 0.05 V. The measurement was performed under two temperature conditions of 110° C. and −40° C. The I_{d}-V_{g} characteristics were measured in such a manner that the gate voltage V_{g} was set to three conditions, 1.0 V, 2.0 V, and 3.0 V; the source voltage Vₛ was set at 0 V; and the drain voltage V_{d} was swept from 0 V to +1.2 V in increments of 0.05 V. The measurement was performed under two temperature conditions of 110° C. and −40° C.

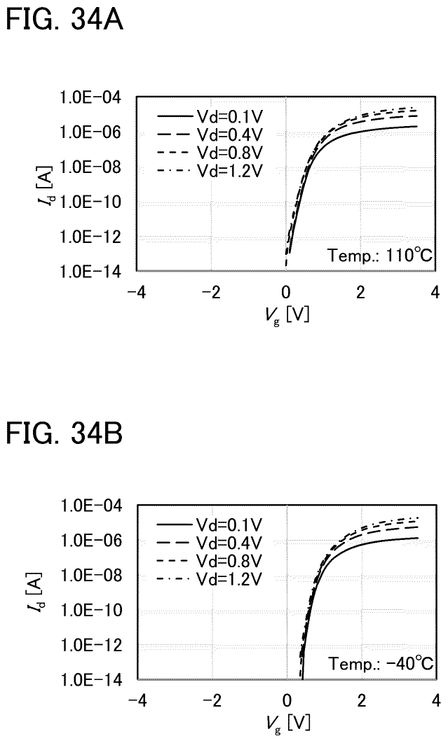

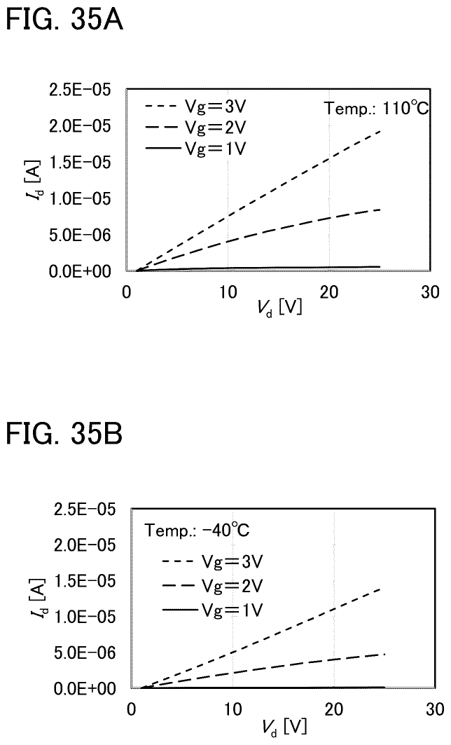

FIG. 34A shows I_{d}-V_{g} characteristics at 110° C., and FIG. 34B shows I_{d}-V_{g} characteristics at −40° C. Note that in FIGS. 34A and 34B, measurement results at drain voltages V_{d} of 0.1 V, 0.4 V, 0.8 V, and 1.2 V are displayed overlapping with each other. FIG. 35A shows I_{d}-V_{d} characteristics at 110° C., and FIG. 35B shows I_{d}-V_{d} characteristics at −40° C. In each of the graphs showing the I_{d}-V_{g} characteristics, the vertical axis represents a drain current I_{d} [A], and the horizontal axis represents gate-source voltage (V_{g}) [V]. Furthermore, in each of the graphs showing the I_{d}-V_{d} characteristics, the vertical axis represents a drain current I_{d} [A], and the horizontal axis represents drain-source voltage (V_{d}) [V]. As shown in FIGS. 34A and 34B and FIGS. 35A and 35B, the semiconductor device fabricated in this example was confirmed to include the transistor having favorable characteristics.

### <Evaluation 2 of Electrical Characteristics of Transistor>

Electrical characteristics of the transistor included in the fabricated semiconductor device were evaluated. Here, electrical characteristics of the transistor in the case where a width of the opening portion 290 of 60 nm were evaluated. As the electrical characteristics, I_{d}-V_{gs} characteristics were measured. The I_{d}-V_{gs} characteristics were measured in such a manner that the drain voltage V_{d} was set at 0.4 V, the source voltage Vₛ was set at 0 V, and the gate voltage V_{g} was swept from −2.5 V to +3.5 V in increments of 0.05 V. The measurement was performed under three temperature conditions of 110° C., 27° C., and −40° C.

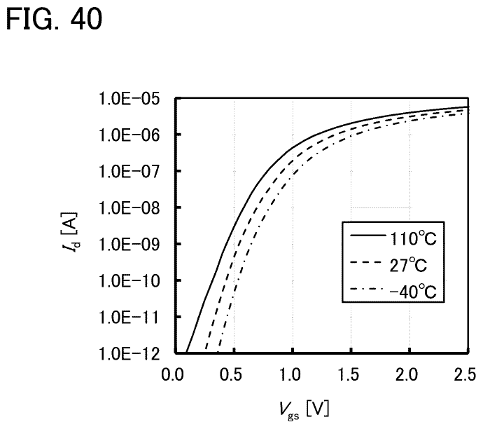

FIG. 40 shows I_{d}-V_{gs} characteristics. In each of the graphs showing the I_{d}-V_{gs} characteristics, the vertical axis represents a drain current (drain-source current) I_{d} [A], and the horizontal axis represents gate-source voltage (V_{gs}) [V].

The gate-source voltage V_{gs} at a drain current I_{d} of 1×10⁻¹² [A] is Vₛₕ. As shown in FIG. 40, the semiconductor device fabricated in this example with L/W=95/(60×π)=0.5, where L is the channel length and W is the channel width, showed excellent Vₛₕ values lower than 0.5 V. The Vₛₕ values were higher than 0 V, showing the operation of the normally-off transistor. Here, the channel length L was the thickness of the insulating layer 280, and the shape of the opening portion 290 in a plan view was circular.

It is preferable that Vₛₕ be higher than 0 V. Moreover, Vₛₕ is further preferably higher than 0 V and lower than 0.5 V. The value L/W obtained by dividing the channel length L by the channel width W can be, for example, larger than or equal to 0.1 and less than or equal to 1.5, or larger than or equal to 0.2 and less than or equal to 1 and can be, for example, 0.5 or a value in the vicinity thereof. In some cases, Vₛₕ is higher than or equal to 0.1 V. Specifically, Vₛₕ is higher than or equal to 0.1 V, or higher than or equal to 0.1 V and lower than 0.5 V at a temperature lower than or equal to 27° C., for example. Note that Vₛₕ is preferably calculated from the I_{d}-V_{gs} characteristics measured when the drain-source voltage is higher than or equal to 0.05 V and lower than or equal to 1 V, for example.

### Example 2

In this example, data for simulation was extracted by measurement using the transistor fabricated in Example 1 and circuit simulation was performed.

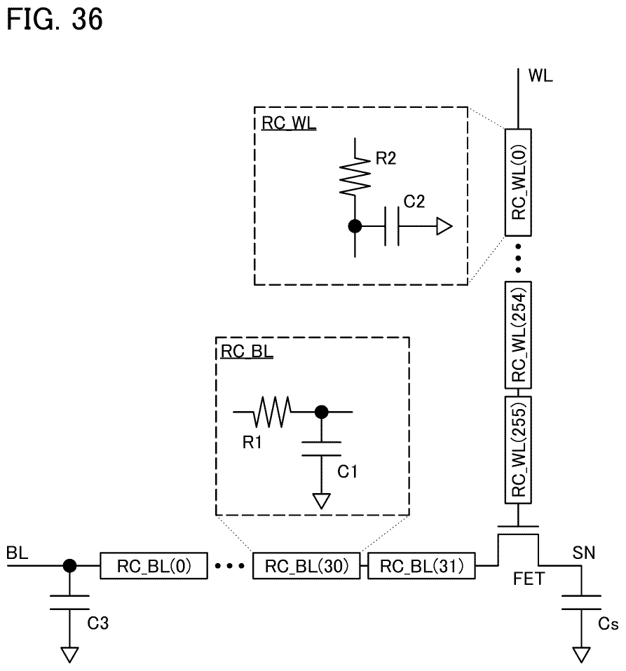

FIG. 36 is a circuit diagram which was used for the circuit simulation. A case where 32 memory cells each having a structure similar to that of the memory cell 951 illustrated in FIG. 19A in the above embodiment were connected to one wiring BL was assumed. The characteristics of the transistor fabricated in Example 1 were used for circuit simulation. Note that the actually measured threshold of the I_{d}-V_{g} characteristics of the transistor was shifted to a threshold suitable for circuit operation, and the threshold suitable for circuit operation was used in simulation.

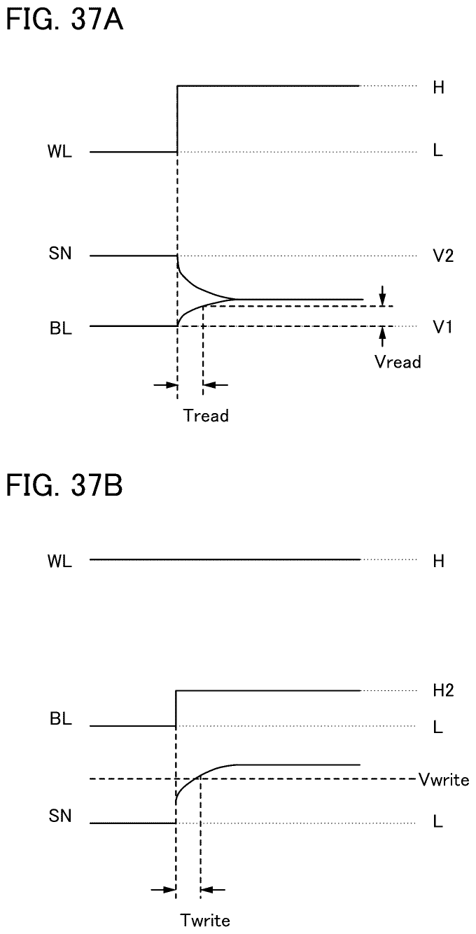

FIGS. 37A and 37B are timing charts showing the operation of the circuit illustrated in FIG. 36. In FIG. 37A, the high voltage potential H of a wiring WL had three conditions: 3.3 V, 2.5 V, and 1.8 V, and the low voltage potential L was set at 0 V. A potential V2 of a node SN was set at 0.52 V. A potential V1 of the wiring BL was set at 0.26 V. Furthermore, V_{read} was set at 80 mV. In FIG. 37B, the high voltage potential H of the wiring WL had three conditions: 3.3 V, 2.5 V, and 1.8 V. The high voltage potential H2 of the wiring BL was set at 0.8 V, and the low voltage potential L was set at 0 V. The low voltage potential L of the node SN was set at 0 V. Furthermore, V_{write} was set at 0.52 V. Note that in order to obtain a current value corresponding to 0.64-second retention under the conditions where the wiring WL and the wiring BL were at the low voltage potential L and the potential of the node SN was the potential V2, the threshold voltage was shifted from the threshold voltage of the actually measured electrical characteristics in the model used in the circuit simulation, and write and read operations at −40° C. were simulated.

Table 1 shows parameters used for the circuit simulation. Two kinds of conditions, that is, Conditions Cir1 and Conditions Cir2, are shown in Table 1. In Conditions Cir1, the parameters that assume a structure where the insulating layer 250 is positioned between the conductive layer 260 and the conductive layer 240 as in the transistor illustrated in FIG. 9A or the like were used. In Conditions Cir2, the parameters that assume a structure where the overlap between the conductive layer 260 and the conductive layer 240 is small and an interlayer film is provided between the conductive layer 265 and the conductive layer 240 to reduce capacitance between the wirings as in FIG. 10B were used.

TABLE 1

| | |
|---|---|
| Cir1 | Cir2 |

| | | | | |
|---|---|---|---|---|
| Cs | 3.0 | fF | 1.77 | fF |
| C1 | 0.15 | fF | 0.073 | fF |
| R1 | 32.2 | Ω | 32.2 | Ω |
| C2 | 0.15 | fF | 0.079 | fF |
| R2 | 45 | Ω | 45 | Ω |
| C3 | 1.2 | fF | 1.2 | fF |

Table 2 shows the calculation results of write time T_{write}, and Table 3 shows the calculation results of read time T_{read}. In the tables, the column of μFE×1 shows results of calculation using, as the transistor mobility, the mobility of the evaluation result of the transistor obtained in Example 1; and the column of μFE×3 shows results of calculation using, as the transistor mobility, the value that is three times the mobility obtained in Example 1.

TABLE 2
T_{write} [ns]

| | |
|---|---|
| Cir1 | Cir2 |

| WL | μFE × 1 | μFE × 3 | μFE × 1 | μFE × 3 |
|---|---|---|---|---|
| 3.3 V | 1.61 | 0.56 | 0.96 | 0.35 |
| 2.5 V | 15.15 | 5.17 | 10.15 | 3.51 |
| 1.8 V | 2.4 × 10⁶ | 8.1 × 10⁵ | 2.3 × 10⁶ | 7.7 × 10⁵ |

TABLE 3
T_{read} [ns]

| | |
|---|---|
| Cir1 | Cir2 |

| WL | μFE × 1 | μFE × 3 | μFE × 1 | μFE × 3 |
|---|---|---|---|---|
| 3.3 V | 0.88 | 0.48 | 0.43 | 0.23 |
| 2.5 V | 3.53 | 1.26 | 1.94 | 0.63 |
| 1.8 V | 5.0 × 10³ | 1.6 × 10³ | 5.1 × 10³ | 1.7 × 10³ |

When the wiring WL was at 3.3 V, write time and read time were each shorter than several nanoseconds.

### Example 3

In this example, samples (Sample H1 to Sample H3) in each of which a metal oxide layer was formed were fabricated, and crystal orientations of the metal oxides were evaluated.

### <Fabrication of Sample>

First, a 100-nm-thick silicon oxide layer was formed over a silicon substrate by thermal oxidation treatment. Next, a metal oxide layer (corresponding to the oxide semiconductor layer 230) was formed over the silicon oxide layer. Note that the metal oxide layer of Sample H1 had a single-layer structure of a 5-nm-thick first oxide semiconductor layer. The metal oxide layers of Sample H2 and Sample H3 each had a stacked-layer structure of a 5-nm-thick first oxide semiconductor layer and a 5-nm-thick second oxide semiconductor layer over the first oxide semiconductor layer.

The first oxide semiconductor layer was formed by a sputtering method using an IGZO sputtering target with an atomic ratio of metal elements of In:Ga:Zn=1:1:1.2. The second oxide semiconductor layer was formed by an ALD method to have an atomic ratio of In:Ga:Zn=1:1:1. Precursors used for formation of the second oxide semiconductor layer are triethylindium (TEI), triethylgallium (TEG), and diethylzinc (DEZ). As an oxidizer, ozone (O₃) and oxygen (O₂) were used.

Next, heat treatment was performed on Sample H3. The heat treatment was performed in a mixed atmosphere of N₂ gas at a flow rate of 4 slm and O₂ gas at a flow rate of 1 slm at 400° C. under atmospheric pressure for one hour.

Note that as a protective film for TEM observation, a carbon film was formed over the metal oxide layer.

### <TEM Observation and Evaluation of Crystal Orientation>

Samples H1 to H3 were thinned by a focused ion beam (FIB), and the cross sections were observed by scanning transmission electron microscopy (STEM). The TEM images were obtained using an atomic resolution analytical electron microscope JEM-ARM200F manufactured by JEOL Ltd. at an acceleration voltage of 200 kV by the irradiation with an electron beam having a diameter of approximately 0.2 nm.

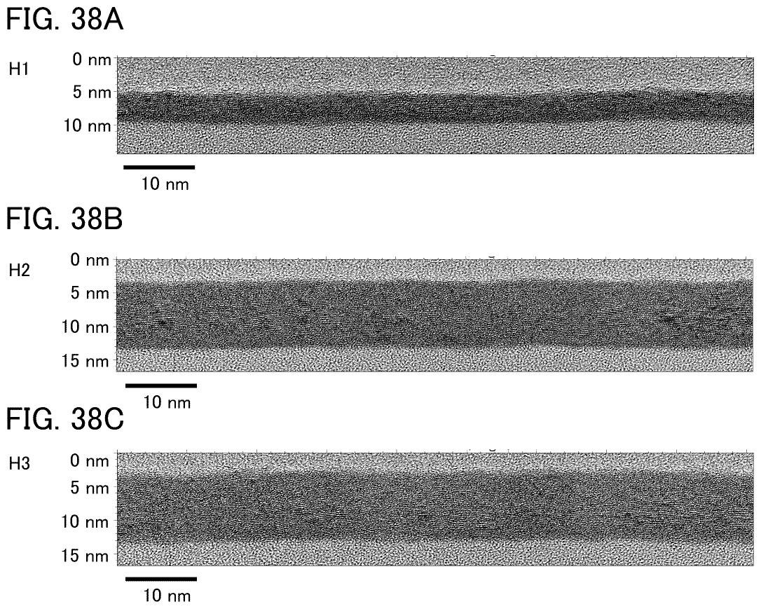

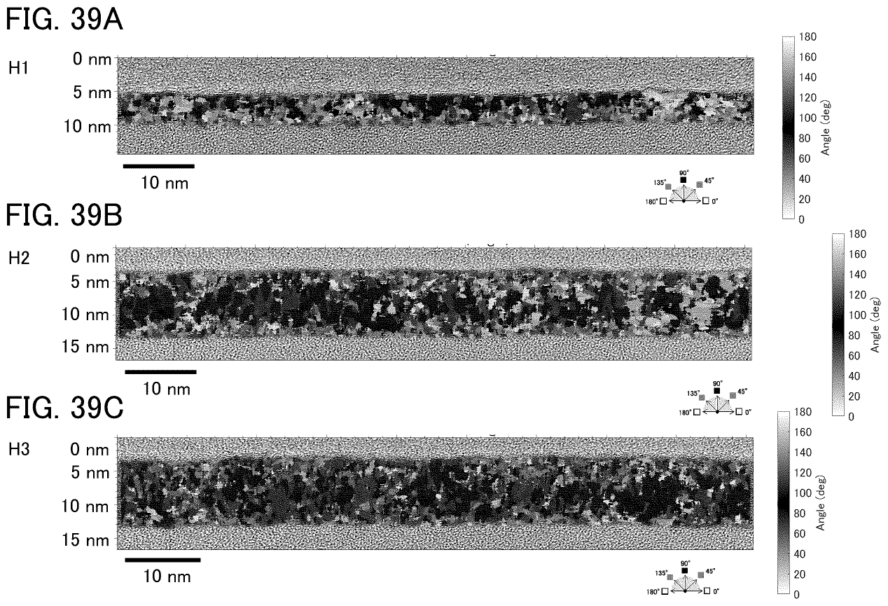

The cross-sectional TEM image and crystal orientation of Sample H1 are shown in FIG. 38A and FIG. 39A, respectively. The cross-sectional TEM image and crystal orientation of Sample H2 are shown in FIG. 38B and FIG. 39B, respectively. The cross-sectional TEM image and crystal orientation of Sample H3 are shown in FIG. 38C and FIG. 39C, respectively.

FIGS. 38A, 38B, and 38C are cross-sectional TEM images of Samples H1, H2, and H3, respectively. In each of Sample H1 to Sample H3, a layered lattice image was observed. Sample H1 to Sample H3 were found to have crystallinity.

FIGS. 39A to 39C show crystal orientations obtained from the cross-sectional TEM images. The cross-sectional TEM images were subjected to fast Fourier transform (FFT) processing on the region basis to obtain FFT patterns, and the directions of crystal axes in each region were obtained; thus, the diagrams showing crystal orientations (also referred to as maps showing crystal orientations) were obtained. Note that a region where FFT was performed (also referred to as an FFT window) was circular with a diameter of 1.0 nm. The FFT pattern obtained by the FFT processing reflects reciprocal lattice space information like an electron diffraction pattern.

In FIGS. 39A to 39C, the directions of the crystal axes with respect to the formation surface of the metal oxide layer (the top surface of the silicon oxide layer) are represented by grayscale; black (a deep color) represents 90° and white (a light color) represents 0° and 180°. That is, the black (deep-color) region is a region where the c-axes of crystals are aligned in a direction perpendicular to the formation surface of the metal oxide layer (the top surface of the silicon oxide layer). In other words, the black (deep-color) region is a c-axis-aligned crystal region.

As shown in FIG. 39A, Sample H1 had c-axis-aligned crystals on the surface of the metal oxide layer. As shown in FIG. 39B, owing to the deposition by an ALD method of the second oxide semiconductor layer over the first oxide semiconductor layer formed by a sputtering method, the crystal region having c-axis alignment of the first oxide semiconductor layer expanded. Furthermore, as shown in FIG. 39C, the heat treatment performed after the deposition of the second oxide semiconductor layer further expanded the crystal region having c-axis alignment of the first oxide semiconductor layer.

Accordingly, it was found that the first oxide semiconductor layer formed by a sputtering method included a region having a CAAC structure. Thus, it was found that the first oxide semiconductor layer included the regions 372a described in Embodiment 1. It was also found that when the second oxide semiconductor layer was deposited over the first oxide semiconductor layer or when the second oxide semiconductor layer was deposited and heat treatment was performed thereon, the region having a CAAC structure expanded. Accordingly, it was found that the regions 372a included in the first oxide semiconductor layer was able to serve as a seed to promote crystal growth.

### Example 4

In this example, data for simulation was extracted by measurement using the transistor fabricated in Example 1 and circuit simulation was performed.

FIG. 36 is a circuit diagram which is used for the circuit simulation. FIG. 36 illustrates a circuit that verifies the operation of one memory cell in a memory cell array. In FIG. 36, a case where 32 memory cells each having a structure similar to that of the memory cell 951 illustrated in FIG. 19A in the above embodiment are connected to one wiring BL and 256 memory cells each having a structure similar to that of the memory cell 951 illustrated in FIG. 19A in the above embodiment are connected to one wiring WL was assumed. It can be said that FIG. 36 illustrates a circuit that verifies the operation of one memory cell in a 1-KB DOSRAM. FIG. 36 illustrates a memory cell including a transistor FET and a capacitor Cs; 32 circuits RC_BL corresponding to a load supplied to the wiring BL from another memory cell included in the memory cell array are connected to the wiring BL; and 256 circuits RC_WL corresponding to a load supplied from another memory cell included in the memory cell array are connected to the wiring WL. The wiring BL corresponds to the wiring BIL in FIG. 19A, and the wiring WL corresponds to the wiring WOL in FIG. 19A. The characteristics of the transistor fabricated in Example 1 were used for circuit simulation. The operation temperature of the circuit was assumed to be higher than or equal to −40° C. and lower than or equal to 110° C.

For data retention for 0.64 seconds in the circuit simulation, the I_{d}-V_{gs} curve obtained by shifting the I_{d}-V_{gs} curve of the transistor characteristics of FIG. 40 along the V_{g} direction (in the horizontal direction) were used. The required shift amount was calculated by the following method.

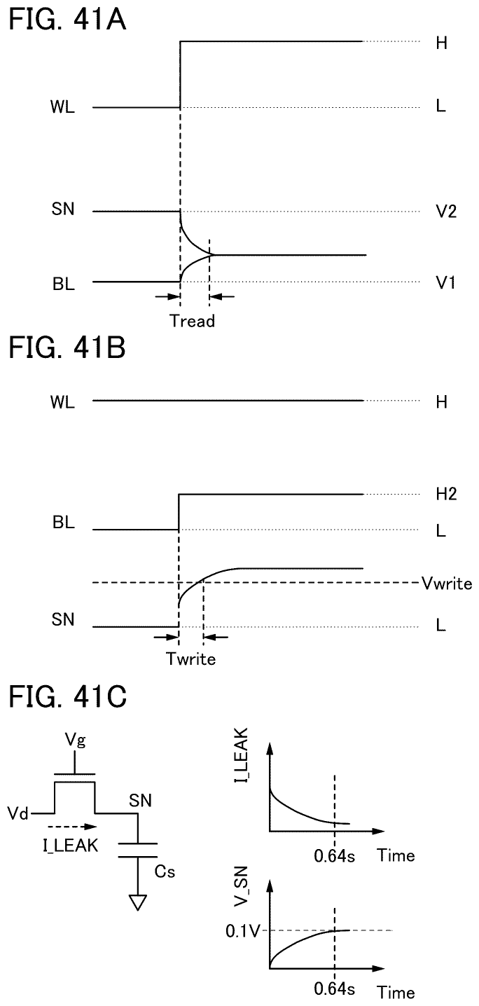

The shift amount was determined so that the change in the voltage V_SN of the node SN was 0.1 V in the case where an off-state leakage current I_LEAK kept flowing for 0.64 seconds at 110° C. as illustrated in FIG. 41C. A precharge voltage of 0.4 V was applied to the drain of the transistor FET (here, the terminal connected to the wiring BL), and a voltage of 0 V corresponding to data 0 was applied to the node SN. Here, the initial value of the off-state leakage current I_LEAK is the drain current I_{d} at V_{g}=0 V, V_{d}=0.4 V, and Vₛ=0 V in the I_{d}-V_{g} characteristics. Note that the voltage difference between the gate voltage V_{g} and the source voltage Vₛ of the transistor (here, the voltage V_SN of the node SN) changes with the change in the voltage V_SN of the node SN, and accordingly the off-state leakage current I_LEAK also changes. In consideration of this, the voltage V_SN of the node SN is changed in increments of 0.1 mV, the amount of change in current caused by the 0.1 mV change in the voltage V_SN of the node SN is determined using the S value calculated from the I_{d}-V_{g} characteristics, and the amount of change is subtracted from the off-state leakage current I_LEAK. In this manner, the amount of change in the off-state leakage current caused by the change in the voltage V_SN of the node SN can be considered.

The necessary shift amount was estimated by the above-described method to be −0.04 V.

The memory device of one embodiment of the present invention has a capacity more than or equal to 1 KB, and each memory cell included in the memory device preferably has a retention time longer than or equal to 0.64 seconds.

When a gate and a source of the transistor of one embodiment of the present invention are each set at 0 V and a first voltage V1 is applied to a drain of the transistor, the amount of accumulated charges flowing through the transistor for 0.64 seconds is preferably less than or equal to 3×10⁻¹⁵ [F]×0.1 [V]. The first voltage V1 is preferably higher than or equal to 0.05 V and lower than or equal to 1 V.

Next, the write time and the read time of the circuit illustrated in FIG. 36 were calculated. In the circuit simulation, the I_{d}-V_{g} transistor characteristics obtained in Example 1 were used with the threshold shifted by −0.04 V.

FIGS. 41A and 41B are timing charts showing the operation of the circuit illustrated in FIG. 36. In FIG. 41A, the high voltage potential H of the wiring WL was set at 1.8 V, and the low voltage potential L was set at 0 V. The potential V2 of the node SN was set at 0.52 V. In addition, the read time T_{read} was the time until the potentials of the wiring BL and the node SN matched 95%. In FIG. 41B, the high voltage potential H of the wiring WL was set at 1.8 V, and the high voltage potential H2 and the low voltage potential L of the wiring BL were set at 0.8 V and 0 V, respectively. The low voltage potential L of the node SN was set at 0 V. Furthermore, V_{write} was set at 0.64 V, which is a 80% voltage of the high voltage potential H2, and the write time T_{write} was the time taken until V_{write} was reached.

A resistance value R1 is determined corresponding to the resistance value of the wiring BL per memory cell, and a resistance value R2 is determined corresponding to the resistance value of the wiring WL per memory cell. Because a small resistance value can reduce circuit delay, the resistance value R1 and the resistance value R2 are preferably small. The resistance value R1 and the resistance value R2 are each, for example, less than or equal to 100Ω, or greater than or equal to 1Ω and less than or equal to 100Ω, for example. A capacitance value C1 and a capacitance value C2 are each a capacitance value per memory cell, and determined corresponding to the capacitance value derived from a conductive layer such as an electrode or a wiring included in the memory cell. A reduction in the parasitic capacitance of the circuit can increase the operating speed of the circuit. The capacitance value C1 and the capacitance value C2 are, for example, less than or equal to 0.5 fF (f: femto=10⁻¹⁵), or greater than or equal to 1 aF (a: atto=10⁻¹⁸) and less than or equal to 0.5 fF.

Table 4 shows parameters used for the circuit simulation.

TABLE 4

| | | |
|---|---|---|
| Cs | 3.0 | fF |
| C1 | 0.15 | fF |
| R1 | 32.2 | Ω |
| C2 | 0.15 | fF |
| R2 | 45 | Ω |
| C3 | 1.2 | fF |

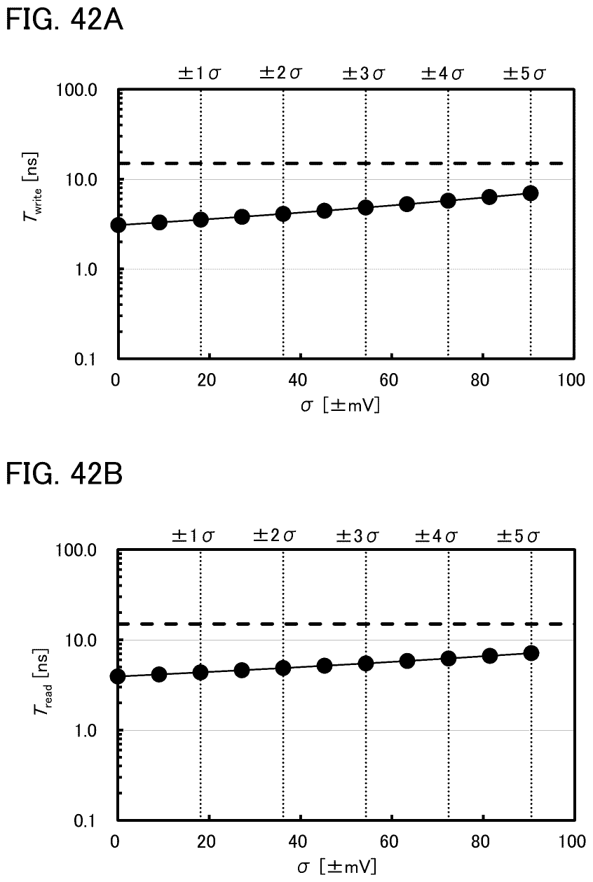

FIG. 42A shows the calculation results of the write time T_{write}, and FIG. 42B shows the calculation results of the read time T_{read}. Note that the horizontal axis in FIGS. 42A and 42B shows a variation σ of the threshold voltage taken into consideration when the simulation was performed. Here, 1σ is 18.1 mV. In FIGS. 42A and 42B, a dashed line indicates 15 ns as a guideline of the read time or write time with which the memory cell of one embodiment of the present invention can be favorably operated.

As shown in FIGS. 42A and 42B, both the write time and the read time were shorter than 10 ns, which was significantly shorter than 15 ns shown in the graphs.

As described above, it was found that the memory cell of one embodiment of the present invention operates at high speed. In particular, it was suggested that the memory cell of one embodiment of the present invention sufficiently satisfies a write time and a read time shorter than or equal to 15 ns, which is a preferable operating speed for a DOSRAM used as the main memory described with reference to FIG. 24A.

As described above, it was suggested that the memory cell of one embodiment of the present invention can achieve excellent retention characteristics since the shift amount of threshold necessary to satisfy a retention time of 0.64 s was as extremely small as −0.04 V. Since the memory cell of one embodiment of the present invention has both excellent operating speed and excellent retention characteristics, it is suggested that the memory cell is particularly suitable as the DOSRAM used as the main memory described with reference to FIG. 24A.

The use of the transistor structure illustrated in FIGS. 1A to 1C, FIGS. 2A to 2C, or the like and the use of the metal oxide of one embodiment of the present invention for the oxide semiconductor layer made it possible to inhibit a threshold shift of the transistor and provide normally-off characteristics. With the use of an OS transistor having normally-off characteristics, a drastically long retention time was able to be achieved compared with the case of using a DRAM that is formed using a silicon transistor. Furthermore, by using the transistor structure illustrated in FIGS. 1A to 1C, FIGS. 2A to 2C, or the like and the metal oxide of one embodiment of the present invention for the oxide semiconductor layer, excellent on-state characteristics were achieved and an enough operating speed that bears comparison with a DRAM using a silicon transistor was achieved.

The memory device of one embodiment of the present invention has a capacity more than or equal to 1 KB, and each memory cell included in the memory device preferably has a write speed lower than or equal to 15 ns.

Each memory cell included in the memory device of one embodiment of the present invention having a capacity more than or equal to 1 KB preferably has a read speed lower than or equal to 15 ns.

The memory cell of one embodiment of the present invention includes a transistor and a capacitor connected to the source of the transistor. The write speed and the read speed of the memory cell can each be calculated with a circuit having a first load connected to the gate of the transistor and a second load connected to the drain of the transistor. The first load includes 256 first circuits, and the second load includes 32 second circuits. The first circuit includes a first resistor and a first capacitor connected to one electrode of the first resistor. The 256 first resistors included in the first load are serially connected. The second circuit includes a second resistor and a capacitor connected to one electrode of the second resistor. The 256 second resistors included in the second load are serially connected.

### Example 5

In this example, the cross section of the transistor fabricated in Example 1 was observed.

The sample including the fabricated transistor was thinned by a focused ion beam (FIB) and the cross section was observed by scanning transmission electron microscopy (STEM). The STEM observation was performed at an acceleration voltage of 200 kV using a scanning transmission electron microscope HD-2700 manufactured by Hitachi High-Technologies Corporation.

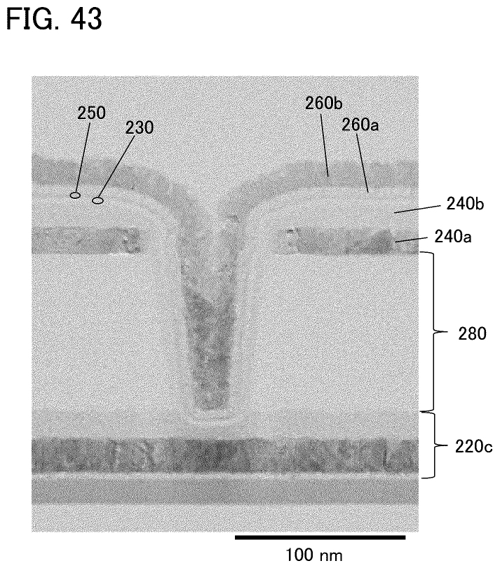

A STEM image showing the cross section of the sample is shown in FIG. 43. FIG. 43 is a transmission electron image (TE image) at a magnification of 300000 times. As shown in FIG. 43, an opening portion is formed in the insulating layer 280 and the conductive layer 240, and the oxide semiconductor layer 230, the insulating layer 250, the conductive layer 260a, and the conductive layer 260b are positioned to cover the opening portion.

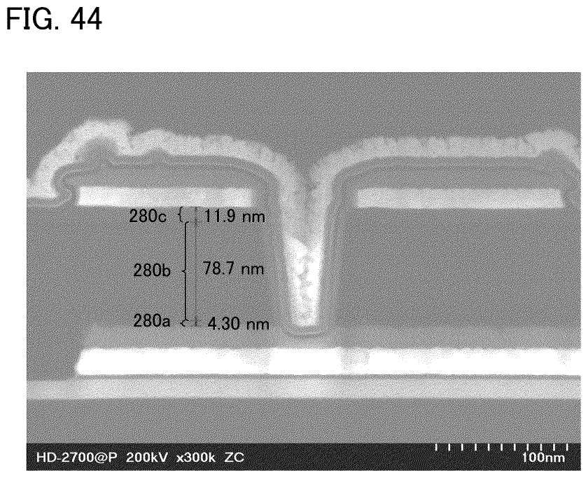

FIG. 44 shows a Z contrast image (ZC image) at a magnification of 300000 times. The acceleration voltage at the time of observation was set at 200 kV. From FIG. 44, the thicknesses of the insulating layer 280a (silicon nitride), the insulating layer 280b (silicon oxide), and the insulating layer 280c (silicon nitride) were estimated at 4.30 nm, 78.7 nm, and 11.9 nm, respectively. In the insulating layer 280a, the difference from the target thickness of 5 nm was approximately 14%. In the insulating layer 280b, the difference from the target thickness of 80 nm was approximately 2%. In the insulating layer 280c, the difference from the target thickness of 10 nm was approximately 19%.

### Example 6

In this example, the semiconductor device fabricated in Example 1 was evaluated.

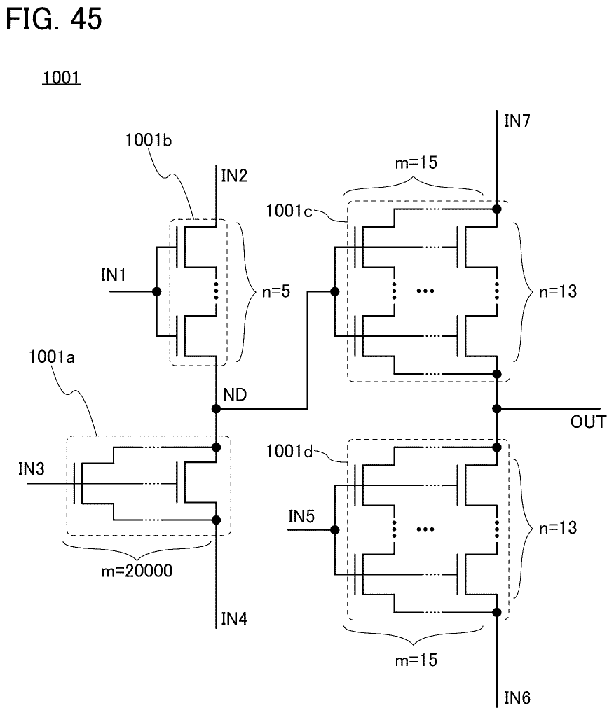

The leakage current in the off state of the transistor was evaluated using a circuit 1001 illustrated in FIG. 45. The transistor fabricated in Example 1 was used as each of the transistors illustrated in FIG. 45. With the circuit 1001, it is possible to evaluate a change in the potential of the node ND due to the leakage current of the transistors included in a circuit block 1001a. Since the leakage current of a transistor including an oxide semiconductor in its channel formation region is low, 20000 transistors (m=20000) are connected in parallel in the circuit block 1001a to increase the current value. In this way, the leakage current of the circuit 1001 can be detected more easily. A terminal IN3 is connected to a gate of each of the transistors included in the circuit block 1001a.

A circuit block 1001b is connected in series to the circuit block 1001a. In the circuit block 1001b, five transistors (n=5) are connected in series. A terminal IN1 is connected to a gate of each of the transistors included in the circuit block 1001b.

One terminal of the circuit block 1001b is connected to a terminal IN2, and the other terminal thereof is connected to the node ND. One terminal of the circuit block 1001a is connected to the node ND, and the other terminal thereof is connected to a terminal IN4.

In each of a circuit block 1001c and a circuit block 1001d, 15 sets (m=15) of serially connected 13 transistors (n=13) are connected in parallel. The gates of the transistors included in the circuit block 1001c are each connected to the node ND. The gates of the transistors included in the circuit block 1001c are each connected to the terminal IN5.

One terminal of the circuit block 1001c is connected to a terminal IN7, and the other terminal thereof is connected to an output terminal OUT. One terminal of the circuit block 1001d is connected to the output terminal OUT, and the other terminal thereof is connected to a terminal IN6.

First, writing to the node ND was performed. In the circuit 1001 illustrated in FIG. 45, the voltages shown in Table 5 were applied to the terminals IN1, IN2, IN3, and IN4 to turn on the transistors in the circuit block 1001b, whereby a voltage of 0.8 V applied to the terminal IN2 was written to the node ND. The write time was set long enough for the voltage at the node ND to reach 0.8 V.

TABLE 5

| | [V] |
|---|---|
| IN1 | 2.0 |
| IN2 | 0.8 |
| IN3 | −1.0 |
| IN4 | 0 |

Next, in the circuit 1001 illustrated in FIG. 45, the voltages shown in Table 6 were applied to the terminals IN1, IN2, IN3, IN4, IN5, IN6, and IN7 to turn off each of the transistors in the circuit block 1001a and the circuit block 1001b, whereby retention was performed. By measuring a change in the voltage of the output terminal OUT, a change in the voltage of the node ND can be estimated. From the change in the voltage of the node ND, the leakage current of the transistors included in the circuit block 1001a can be estimated.

TABLE 6

| | [V] |
|---|---|
| IN1 | −1.5 |
| IN2 | 0.8 |
| IN3 | −1.0 |
| IN4 | 0 |
| IN5 | −1.0 |
| IN6 | −2.0 |
| IN7 | 2.0 |

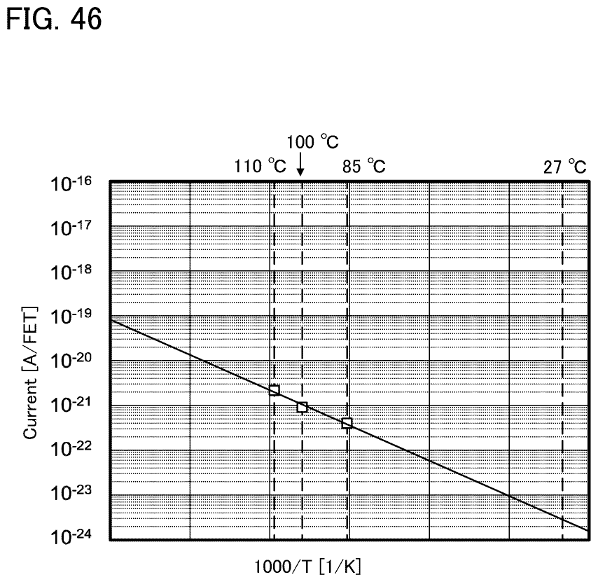

FIG. 46 shows the leakage current estimated using the circuit 1001 in FIG. 45. FIG. 46 shows measurement results at measurement temperatures of 110° C., 100° C., and 85° C. The vertical axis of the graph represents the leakage current per transistor, and the horizontal axis represents 1000/T. Here, T is the absolute temperature of the measurement.

As shown in FIG. 46, the leakage current per transistor was estimated at 2.17×10⁻²¹ [A/FET] at 110° C. The leakage current at 27° C. obtained by extrapolation was lower than 1×10⁻²³ [A/FET]. Accordingly, the extremely low leakage current of the transistor in the off state was suggested.

This application is based on Japanese Patent Application Serial No. 2023-086420 filed with Japan Patent Office on May 25, 2023, Japanese Patent Application Serial No. 2024-005509 filed with Japan Patent Office on Jan. 17, 2024, and Japanese Patent Application Serial No. 2024-030892 filed with Japan Patent Office on Mar. 1, 2024, the entire contents of which are hereby incorporated by reference.

What is claimed is:

1. A semiconductor device comprising:
a transistor over a first insulating layer; and
a second insulating layer,
wherein the transistor comprises, over the first insulating layer, a first conductive layer, a second conductive layer, a semiconductor layer, a gate insulating layer, and a gate electrode,
wherein the second insulating layer is between the first conductive layer and the second conductive layer,
wherein the second conductive layer is over the second insulating layer,
wherein the second insulating layer and the second conductive layer comprise an opening portion reaching the first conductive layer,
wherein the semiconductor layer is in contact with a side surface of the second insulating layer in the opening portion and a side surface of the second conductive layer in the opening portion,
wherein the gate insulating layer is over the semiconductor layer,
wherein the gate electrode comprises a region overlapping with the semiconductor layer with the gate insulating layer therebetween in the opening portion,
wherein the semiconductor layer comprises a first oxide layer and a second oxide layer,
wherein the first oxide layer comprises a first region and a second region,
wherein the first region and the second region each comprise a plurality of crystal parts, and
wherein the second oxide layer is between the first region and the second region.

2. The semiconductor device according to claim 1, wherein the plurality of crystal parts has c-axis alignment.

3. The semiconductor device according to claim 1, wherein the second oxide layer comprises a crystal part having the same crystal structure as the plurality of crystal parts.

4. The semiconductor device according to claim 1, wherein the second oxide layer comprises a crystal part connected with one of the plurality of crystal parts.

5. The semiconductor device according to claim 1, wherein a boundary is not observed between the first oxide layer and the second oxide layer in a cross-sectional TEM image.

6. The semiconductor device according to claim 1,
wherein the first conductive layer comprises a depressed portion overlapping with the opening portion, and
wherein the semiconductor layer comprises a region embedded in the depressed portion.

7. The semiconductor device according to claim 1,
wherein the opening portion comprises an eighth region having a sidewall with a tapered shape and a ninth region having a steeper sidewall than the eighth region,
wherein the eighth region comprises an upper edge of the opening portion,
wherein the ninth region is below the eighth region,
wherein the eighth region comprises the side surface of the second conductive layer, and
wherein the ninth region comprises the side surface of the second insulating layer.

8. The semiconductor device according to claim 7,
wherein an angle formed between the sidewall of the eighth region and a top surface of the first insulating layer is greater than or equal to 20 degrees and less than or equal to 75 degrees, and
wherein an angle formed between the sidewall of the ninth region and the top surface of the first insulating layer is greater than 75 degrees and less than or equal to 90 degrees.

9. A method for manufacturing a semiconductor device, comprising the steps of:
forming a first insulating layer over a first conductive layer;
forming a second conductive layer over the first insulating layer;
removing part of the second conductive layer and part of the first insulating layer to form a first opening portion reaching the first conductive layer and expose a top surface of the first conductive layer; and
forming a semiconductor layer in contact with each of the top surface of the first conductive layer, a side surface of the first insulating layer in the first opening portion, a side surface of the second conductive layer in the first opening portion, and a top surface of the second conductive layer;
wherein the semiconductor layer is formed through a first step of forming a first oxide layer, a second step of forming a second oxide layer, and a third step of performing heat treatment,
wherein the first oxide layer is formed by a sputtering method,
wherein the second oxide layer is formed by an atomic layer deposition method,
wherein a second insulating layer is formed so as to be in contact with a top surface of the semiconductor layer and a top surface of the first insulating layer, and
wherein a third conductive layer is formed over the second insulating layer.

10. A memory device comprising:
a first insulating layer;
a capacitor; and
a transistor over the capacitor,
wherein the transistor comprises a first conductive layer, a second conductive layer, a semiconductor layer, a gate insulating layer, and a gate electrode,
wherein the capacitor comprises a third conductive layer, a second insulating layer over the third conductive layer, and the first conductive layer over the second insulating layer,
wherein the first insulating layer is between the first conductive layer and the second conductive layer,
wherein the second conductive layer is over the first insulating layer,
wherein the first insulating layer and the second conductive layer comprise an opening portion reaching the first conductive layer,
wherein the semiconductor layer is in contact with a side surface of the first insulating layer in the opening portion and a side surface of the second conductive layer in the opening portion,
wherein the gate insulating layer is over the semiconductor layer,
wherein the gate electrode comprises a region overlapping with the semiconductor layer with the gate insulating layer therebetween in the opening portion,
wherein the semiconductor layer comprises a metal oxide,
wherein I_{d}-V_{gs} characteristics of the transistor are measured at a drain-source voltage higher than or equal to 0.05 V and lower than or equal to 1 V,
wherein I_{d} is a drain current and V_{gs} is a gate-source voltage, and
wherein in the I_{d}-V_{gs} characteristics, V_{gs} is higher than 0 V and lower than 0.5 V when I_{d} is 1×10⁻¹² [A].

11. The memory device according to claim 10,
wherein the metal oxide is an In-M-Zn oxide, and
wherein the element M is one or more elements selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

12. The memory device according to claim 10, wherein a retention time of the memory device is longer than or equal to 0.64 seconds.

13. The memory device according to claim 10, wherein when the gate of the transistor is set at 0 V, the source of the transistor is set at 0 V, and a voltage higher than or equal to 0.05 V and lower than or equal to 1 V is applied to the drain of the transistor, an amount of accumulated charges flowing through the transistor for 0.64 seconds is less than or equal to 3×10⁻¹⁵ [F]×0.1 [V].

14. The memory device according to claim 10, wherein the memory device has a write time shorter than or equal to 15 ns.

15. The memory device according to claim 10, wherein the memory device has a read time shorter than or equal to 15 ns.

16. The memory device according to claim 14,
wherein a circuit comprising a first load connected to the gate of the transistor and a second load connected to the drain of the transistor is used to calculate the write time,
wherein the first load comprises 256 first circuits,
wherein each of the plurality of first circuits comprises a first resistor and a second capacitor,
wherein the second load comprises 32 second circuits,
wherein each of the plurality of second circuits comprises a second resistor and a third capacitor,
wherein a plurality of the first resistors included in the first circuits are serially connected,
wherein a plurality of the second resistors included in the second circuit are serially connected,
wherein a resistance value of the first resistor is greater than or equal to 1Ω and less than or equal to 100 Ω,
wherein a resistance value of the second resistor is greater than or equal to 1Ω and less than or equal to 100 Ω,
wherein a capacitance value of the second capacitor is greater than or equal to 1 aF and less than or equal to 0.5 fF, and
wherein a capacitance value of the third capacitor is greater than or equal to 1 aF and less than or equal to 0.5 fF.

17. The memory device according to claim 15,
wherein a circuit comprising a first load connected to the gate of the transistor and a second load connected to the drain of the transistor is used to calculate the read time,
wherein the first load comprises 256 first circuits,
wherein each of the plurality of first circuits comprises a first resistor and a second capacitor,
wherein the second load comprises 32 second circuits,
wherein each of the plurality of second circuits comprises a second resistor and a third capacitor,
wherein a plurality of the first resistors included in the first circuits are serially connected,
wherein a plurality of the second resistors included in the second circuit are serially connected,
wherein a resistance value of the first resistor is greater than or equal to 1Ω and less than or equal to 100 Ω,
wherein a resistance value of the second resistor is greater than or equal to 1Ω and less than or equal to 100 Ω,
wherein a capacitance value of the second capacitor is greater than or equal to 1 aF and less than or equal to 0.5 fF, and
wherein a capacitance value of the third capacitor is greater than or equal to 1 aF and less than or equal to 0.5 fF.
